(19) United States
(12) Patent Application Publication
(10) Pub. No.: US 2023/0337439 A1
(43) Pub. Date: Oct. 19, 2023

(54) SEMICONDUCTOR DEVICE AND ELECTRONIC DEVICE

(71) Applicant: Semiconductor Energy Laboratory Co., Ltd., Atsugi-shi, Kanagawa-ken (JP)

(72) Inventors: Yuki OKAMOTO, Ebina (JP); Tatsuya ONUKI, Atsugi (JP); Kousuke SASAKI, Atsugi (JP)

(21) Appl. No.: 18/028,812

(22) PCT Filed: Oct. 12, 2021
(86) PCT No.: PCT/IB2021/059303

§ 371 Date: Mar. 28, 2023

(30) Foreign Application Priority Data
Oct. 20, 2020 (JP) 2020-176312

(51) Int. Cl. H10B 53/30; H10B 53/40; G11C 11/22

(52) U.S. Cl. CPC H10B 53/30; H10B 53/40; G11C 11/221; G11C 11/2273

(57) ABSTRACT

Provided is a semiconductor device capable of reading data with high accuracy. The semiconductor device includes first and second memory cells and a switch. The first memory cell includes first and second transistors and a first capacitor, and the second memory cell includes third and fourth transistors and a second capacitor. The first and second capacitors each include a ferroelectric layer between a pair of electrodes. One of a source and a drain of the first transistor is electrically connected to a gate of the second transistor, and the gate of the second transistor is electrically connected to one of the electrodes of the first capacitor. One of a source and a drain of the third transistor is electrically connected to a gate of the fourth transistor, and the gate of the fourth transistor is electrically connected to one of the electrodes of the second capacitor. The other of the source and the drain of the first transistor is electrically connected to the other of the source and the drain of the third transistor via the switch.

### TECHNICAL FIELD

One embodiment of the present invention relates to a semiconductor device and a driving method thereof, for example. One embodiment of the present invention relates to an electronic device.

Note that one embodiment of the present invention is not limited to the above technical field. Examples of the technical field of one embodiment of the present invention disclosed in this specification and the like include a semiconductor device, an imaging device, a display device, a light-emitting device, a power storage device, a memory device, a display system, an electronic device, a lighting device, an input device, an input/output device, a driving method thereof, and a manufacturing method thereof. Note that a semiconductor device generally means a device that utilizes semiconductor characteristics, and a memory device is a semiconductor device.

### BACKGROUND ART

As a semiconductor applicable to a transistor, a metal oxide has been attracting attention. An In—Ga—Zn oxide called “IGZO” and the like is a typical multi-component metal oxide. From researches on IGZO, a CAAC (c-axis aligned crystalline) structure and an nc (nanocrystalline) structure, which are neither single crystal nor amorphous, have been found (e.g., Non-Patent Document 1).

It has been reported that a transistor containing a metal oxide semiconductor in its channel formation region (hereinafter referred to as an “oxide semiconductor transistor” or an “OS transistor” in some cases) has an extremely low off-state current (e.g., Non-Patent Documents 1 and 2). A variety of semiconductor devices using OS transistors have been manufactured (e.g., Non-Patent Documents 3 and 4).

A memory utilizing an extremely low off-state current of an OS transistor (also referred to as an OS memory in some cases) is proposed. For example, a circuit configuration of a NOSRAM is disclosed in Patent Document 1. Note that “NOSRAM (registered trademark)” is an abbreviation for “Nonvolatile Oxide Semiconductor RAM”. A NOSRAM is a memory in which its cell is a 2-transistor (2T) or 3-transistor (3T) gain cell, and its access transistor is an OS transistor. An OS transistor has an extremely low current that flows between a source and a drain in an off state, that is, leakage current. The NOSRAM can be used as a nonvolatile memory by retaining electric charge corresponding to data in the cell, using characteristics of an extremely low leakage current.

### REFERENCE

### Patent Document

[Patent Document 1] Specification of United States Patent Application Publication No. 2011/0176348

### Non-Patent Documents

[Non-Patent Document 1] S. Yamazaki et al., “Properties of crystalline In—Ga—Zn-oxide semiconductor and its transistor characteristics,” Jpn. J. Appl. Phys., vol. 53, 04ED18 (2014).
[Non-Patent Document 2] K. Kato et al., “Evaluation of Off-State Current Characteristics of Transistor Using Oxide Semiconductor Material, Indium-Gallium-Zinc Oxide,” Jpn. J. Appl. Phys., vol. 51, 021201 (2012).
[Non-Patent Document 3] S. Amano et al., “Low Power LC Display Using In—Ga—Zn-Oxide TFTs Based on Variable Frame Frequency,” SID Symp. Dig. Papers, vol. 41, pp. 626-629 (2010).
[Non-Patent Document 4] T. Ishizu et al., “Embedded Oxide Semiconductor Memories: A Key Enabler for Low-Power VLSI,” ECS Tran., vol. 79, pp. 149-156 (2017).

### SUMMARY OF THE INVENTION

### Problems to be Solved by the Invention

In order to read data with high accuracy in a memory such as a NOSRAM, it is important that, in the case where data read from a memory cell are different from each other, potentials output from the memory cell are significantly different from each other. In the case where the memory cell retains binary data, for example, it is preferred that the difference between a potential output from the memory cell when data with a value “0” is read and a potential output from the memory cell when data with a value “1” is read be large.

An object of one embodiment of the present invention is to provide a semiconductor device capable of reading data with high accuracy and a driving method thereof. Another object of one embodiment of the present invention is to provide a highly reliable semiconductor device and a driving method thereof. Another object of one embodiment of the present invention is to provide a semiconductor device with high design flexibility and a driving method thereof Another object of one embodiment of the present invention is to provide a semiconductor device capable of storing large-volume data and a driving method thereof. Another object of one embodiment of the present invention is to provide a semiconductor device that is driven at high speed and a driving method thereof. Another object of one embodiment of the present invention is to provide a semiconductor device with low power consumption and a driving method thereof. Another object of one embodiment of the present invention is to provide a novel semiconductor device and a driving method thereof.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a semiconductor device including a first memory cell, a second memory cell, and a switch; the first memory cell includes a first transistor, a second transistor, and a first capacitor; the second memory cell includes a third transistor, a fourth transistor, and a second capacitor; the first capacitor and the second capacitor each include a ferroelectric layer between a pair of electrodes; one of a source and a drain of the first transistor is electrically connected to a gate of the second transistor; the gate of the second transistor is electrically connected to one of the electrodes of the first capacitor; one of a source and a drain of the third transistor is electrically connected to a gate of the fourth transistor; the gate of the fourth transistor is electrically connected to one of the electrodes of the second capacitor; and the other of the source and the drain of the first transistor is electrically connected to the other of the source and the drain of the third transistor via the switch.

In the above embodiment, a first driver circuit may be included, the first driver circuit may have a function of bringing the first transistor into an on state when data is read from the first memory cell, and the first driver circuit may have a function of bringing the third transistor into an on state when data is read from the second memory cell.

In the above embodiment, a second driver circuit may be included, the second driver circuit may have a function of reading data from the first memory cell on the basis of a potential of one of a source and a drain of the second transistor, and the second driver circuit may have a function of reading data from the second memory cell on the basis of a potential of one of a source and a drain of the fourth transistor.

In the above embodiment, each of the first to fourth transistors may contain a metal oxide in a channel formation region.

In the above embodiment, the first memory cell may include a fifth transistor, the second memory cell may include a sixth transistor, one of a source and a drain of the fifth transistor may be electrically connected to the one of the source and the drain of the second transistor, and one of a source and a drain of the sixth transistor may be electrically connected to the one of the source and the drain of the fourth transistor.

In the above embodiment, a third driver circuit may be included, the third driver circuit may have a function of bringing the fifth transistor into an on state when data is read from the first memory cell, and the third driver circuit may have a function of bringing the sixth transistor into an on state when data is read from the second memory cell.

In the above embodiment, each of the fifth transistor and the sixth transistor may contain a metal oxide in a channel formation region.

Alternatively, one embodiment of the present invention is a semiconductor device including a memory cell, a first driver circuit, and a switch; the memory cell includes a first transistor, a second transistor, and a capacitor; the capacitor includes a ferroelectric layer between a pair of electrodes; one of a source and a drain of the first transistor is electrically connected to a gate of the second transistor; the gate of the second transistor is electrically connected to one of the electrodes of the capacitor; the other of the source and the drain of the first transistor is electrically connected to the first driver circuit via the switch; and the first driver circuit has a function of generating data to be written to the memory cell.

In the above embodiment, a second driver circuit may be included, and the second driver circuit may have a function of bringing the first transistor into an on state when data is read from the memory cell.

In the above embodiment, a third driver circuit may be included, and the third driver circuit may have a function of reading data from the memory cell on the basis of a potential of one of a source and a drain of the second transistor.

In the above embodiment, each of the first transistor and the second transistor may contain a metal oxide in a channel formation region.

In the above embodiment, the memory cell may include a third transistor, and one of a source and a drain of the third transistor may be electrically connected to the one of the source and the drain of the second transistor.

In the above embodiment, a fourth driver circuit may be included, and the fourth driver circuit may have a function of bringing the third transistor into an on state when data is read from the memory cell.

In the above embodiment, the third transistor may contain a metal oxide in a channel formation region.

Alternatively, one embodiment of the present invention is a semiconductor device including a first layer and a second layer having a region overlapping with the first layer; the first layer includes a first memory cell, a second memory cell, and a switch; the first memory cell includes a first transistor, a second transistor, and a first capacitor; the second memory cell includes a third transistor, a fourth transistor, and a second capacitor; the first capacitor and the second capacitor each include a ferroelectric layer between a pair of electrodes; the second layer includes a first arithmetic portion and a second arithmetic portion; one of a source and a drain of the first transistor is electrically connected to a gate of the second transistor; the gate of the second transistor is electrically connected to one of the electrodes of the first capacitor; one of a source and a drain of the third transistor is electrically connected to a gate of the fourth transistor; the gate of the fourth transistor is electrically connected to one of the electrodes of the second capacitor; the other of the source and the drain of the first transistor is electrically connected to the other of the source and the drain of the third transistor via the switch; the first arithmetic portion is electrically connected to a first power line; and the second arithmetic portion is electrically connected to a second power line.

In the above embodiment, the first power line is not necessarily electrically connected to the second power line.

In the above embodiment, a third layer may be included, the third layer may have a region overlapping with the first layer and the second layer, the third layer may include a first driver circuit, the first driver circuit may have a function of bringing the first transistor into an on state when data is read from the first memory cell, and the first driver circuit may have a function of bringing the third transistor into an on state when data is read from the second memory cell.

In the above embodiment, the third layer may include a second driver circuit, the second driver circuit may have a function of reading data from the first memory cell on the basis of a potential of one of a source and a drain of the second transistor, and the second driver circuit may have a function of reading data from the second memory cell on the basis of a potential of one of a source and a drain of the fourth transistor.

In the above embodiment, the ferroelectric layer may contain hafnium oxide and/or zirconium oxide.

An electronic device including the semiconductor device of one embodiment of the present invention and a housing is also one embodiment of the present invention.

### Effect of the Invention

According to one embodiment of the present invention, a semiconductor device capable of reading data with high accuracy and a driving method thereof can be provided. According to one embodiment of the present invention, a highly reliable semiconductor device and a driving method thereof can be provided. According to one embodiment of the present invention, a semiconductor device with high design flexibility and a driving method thereof can be provided. According to one embodiment of the present invention, a semiconductor device capable of storing large-volume data and a driving method thereof can be provided. According to one embodiment of the present invention, a semiconductor device that is driven at high speed and a driving method thereof can be provided. According to one embodiment of the present invention, a semiconductor device with low power consumption and a driving method thereof can be provided. According to one embodiment of the present invention, a novel semiconductor device and a driving method thereof can be provided.

Note that the effects of one embodiment of the present invention are not limited to the effects listed above. The effects listed above do not preclude the existence of other effects. Note that the other effects are effects that are not described in this section and will be described below. The effects that are not described in this section are derived from the description of the specification, the drawings, and the like and can be extracted as appropriate from the description by those skilled in the art. Note that one embodiment of the present invention has at least one of the effects listed above and/or the other effects. Accordingly, depending on the case, one embodiment of the present invention does not have the effects listed above in some cases.

### BRIEF DESCRIPTION OF THE DRAWINGS

FIG. 1 is a block diagram illustrating a structure example of a semiconductor device.

FIG. 2 is a circuit diagram illustrating a configuration example of a semiconductor device.

FIG. 3 is a block diagram illustrating a configuration example of a semiconductor device.

FIG. 4A is a circuit diagram illustrating a configuration example of a memory cell. FIG. 4B is a schematic diagram illustrating a structure example of a capacitor. FIG. 4C is a graph showing hysteresis characteristics of a ferroelectric.

FIG. 5A is a timing chart showing an example of a driving method of a semiconductor device.

FIG. 5B to FIG. 5E are circuit diagrams illustrating examples of a driving method of a semiconductor device.

FIG. 6 is a timing chart showing an example of a driving method of a semiconductor device.

FIG. 7A to FIG. 7C are circuit diagrams illustrating examples of a driving method of a semiconductor device.

FIG. 8A is a timing chart showing an example of a driving method of a semiconductor device.

FIG. 8B and FIG. 8C are circuit diagrams illustrating examples of a driving method of a semiconductor device.

FIG. 9A and FIG. 9B are circuit diagrams illustrating configuration examples of a memory cell.

FIG. 10A and FIG. 10B are perspective views illustrating structure examples of a semiconductor device.

FIG. 11 is a perspective view illustrating a structure example of a semiconductor device.

FIG. 12 is a diagram illustrating an example of a layout of a semiconductor device.

FIG. 13 is a schematic cross-sectional view illustrating a structure example of a semiconductor device.

FIG. 14A to FIG. 14C are schematic cross-sectional views illustrating a structure example of a transistor.

FIG. 15 is a schematic cross-sectional view illustrating a structure example of a semiconductor device.

FIG. 16A and FIG. 16B are schematic cross-sectional views illustrating structure examples of a transistor.

FIG. 17 is a schematic cross-sectional view illustrating a structure example of a transistor.

FIG. 18A to FIG. 18C are schematic cross-sectional views illustrating structure examples of a transistor.

FIG. 19 is a schematic cross-sectional view illustrating a structure example of a transistor.

FIG. 20A and FIG. 20B are schematic cross-sectional views illustrating structure examples of a transistor.

FIG. 21A and FIG. 21B are schematic cross-sectional views illustrating structure examples of a transistor.

FIG. 22A is a diagram showing the classification of crystal structures of IGZO. FIG. 22B is a diagram showing an XRD spectrum of crystalline IGZO. FIG. 22C is a diagram showing a nanobeam electron diffraction pattern of crystalline IGZO.

FIG. 23A is a perspective view illustrating an example of a semiconductor wafer. FIG. 23B is a perspective view illustrating an example of a chip. FIG. 23C and FIG. 23D are perspective views illustrating examples of electronic components.

FIG. 24A to FIG. 24J are diagrams illustrating examples of electronic devices.

FIG. 25A to FIG. 25E are diagrams illustrating examples of electronic devices.

FIG. 26A to FIG. 26C are diagrams illustrating an example of an electronic device.

FIG. 27A to FIG. 27F are diagrams showing measurement results of Id-Vg characteristics in Example.

FIG. 28A to FIG. 28F are diagrams showing results of drain withstand voltage tests in Example.

FIG. 29A to FIG. 29F are diagrams showing results of drain withstand voltage tests in Example.

FIG. 30A is a circuit diagram schematically illustrating a TEG for measuring off-state current.

FIG. 30B is a graph showing temperature dependence of leakage current.

FIG. 31A is a schematic diagram illustrating a structure of a prototyped transistor. FIG. 31B and FIG. 31C are cross-sectional STEM images of the prototyped transistor.

FIG. 32 FIG. 32A and FIG. 32B show top gate voltage-drain current characteristics of a prototyped transistor.

FIG. 33 is a diagram showing the maximum current gain in a prototyped transistor.

### MODE FOR CARRYING OUT THE INVENTION

Hereinafter, embodiments will be described with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the following description of the embodiments.

In addition, ordinal numbers such as “first”, “second”, and “third” in this specification and the like are used to avoid confusion among components. Thus, the ordinal numbers do not limit the number of components. Furthermore, the ordinal numbers do not limit the order of components. For example, a “first” component in one embodiment in this specification and the like can be referred to as a “second” component in other embodiments, or the scope of claims. For another example, a “first” component in one embodiment in this specification and the like can be omitted in other embodiments, or the scope of claims.

The same components, components having similar functions, components made of the same material, components formed at the same time, and the like in the drawings are denoted by the same reference numerals, and repeated description thereof is skipped in some cases.

In this specification and the like, when a plurality of components are denoted by the same reference numerals, and in particular need to be distinguished from each other, an identification sign such as “[ ]”, “< >”, or “_” is sometimes added to the reference numerals.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS FET or an OS transistor is mentioned, it can also be referred to as a transistor including a metal oxide or an oxide semiconductor.

### Embodiment 1

In this embodiment, a semiconductor device of one embodiment of the present invention and a driving method thereof will be described.

One embodiment of the present invention relates to a semiconductor device including a cell. The cell includes a first transistor, a second transistor, and a capacitor. One of a source and a drain of the first transistor is electrically connected to a gate of the second transistor. The gate of the second transistor is electrically connected to one electrode of the capacitor. In the cell with such a structure, the capacitor can retain data. Accordingly, the cell can be referred to as a memory cell and the semiconductor device can be referred to as a memory device.

The capacitor has a structure in which a ferroelectric layer is provided between a pair of electrodes. In this case, data written to the memory cell can be retained owing to polarization of the ferroelectric layer. In the case of reading data from the memory cell with such a structure, the one electrode of the capacitor is brought into an electrically floating state and the potential of the other electrode of the capacitor is changed. Accordingly, the potential of the one electrode of the capacitor is changed by capacitive coupling. The potential change range of the one electrode of the capacitor can be determined by the ratio between the capacitance value of the capacitor and parasitic capacitance of a node to which the one electrode of the capacitor is electrically connected.

Different data retained in the memory cell result in different polarization amounts of the ferroelectric layer. This makes the capacitor have different capacitance values. Thus, when the potential of the other electrode of the capacitor is changed, the potential of the one electrode of the capacitor can be made different depending on data retained in the memory cell. Data reading from the memory cell can be performed on the basis of the difference.

Here, in the case where data read from the memory cell are different from each other, a large difference between the potentials of the one electrode of the capacitor enables highly accurate data reading. For example, in the case where the memory cell retains binary data, a large difference between a potential output from the memory cell when data with a value “0” is read and a potential output from the memory cell when data with a value “1” is read enables highly accurate data reading. To achieve that, it is important to appropriately control the parasitic capacitance of the node to which the one electrode of the capacitor is electrically connected.

In the semiconductor device of one embodiment of the present invention, the parasitic capacitance of the node to which the one electrode of the capacitor is electrically connected can be controlled when data is read from the memory cell. Accordingly, the data can be read from the memory cell with high accuracy.

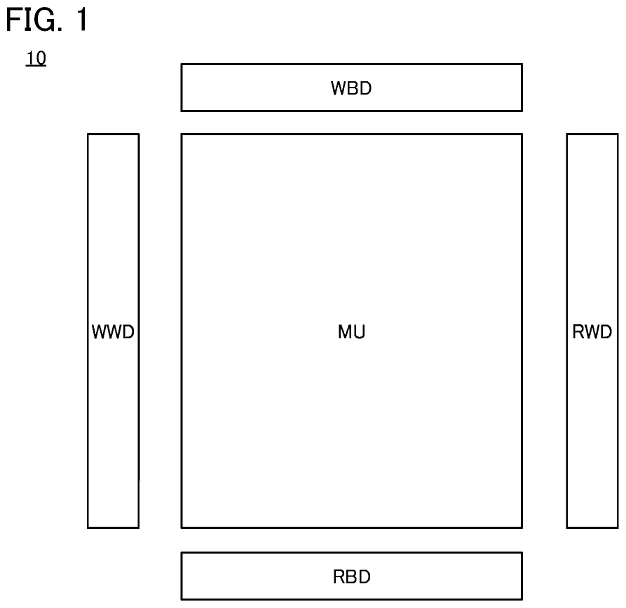

FIG. 1 is a block diagram illustrating a structure example of a semiconductor device 10 which is the semiconductor device of one embodiment of the present invention. The semiconductor device 10 includes a memory unit MU, a driver circuit WWD, a driver circuit RWD, a driver circuit WBD, and a driver circuit RBD.

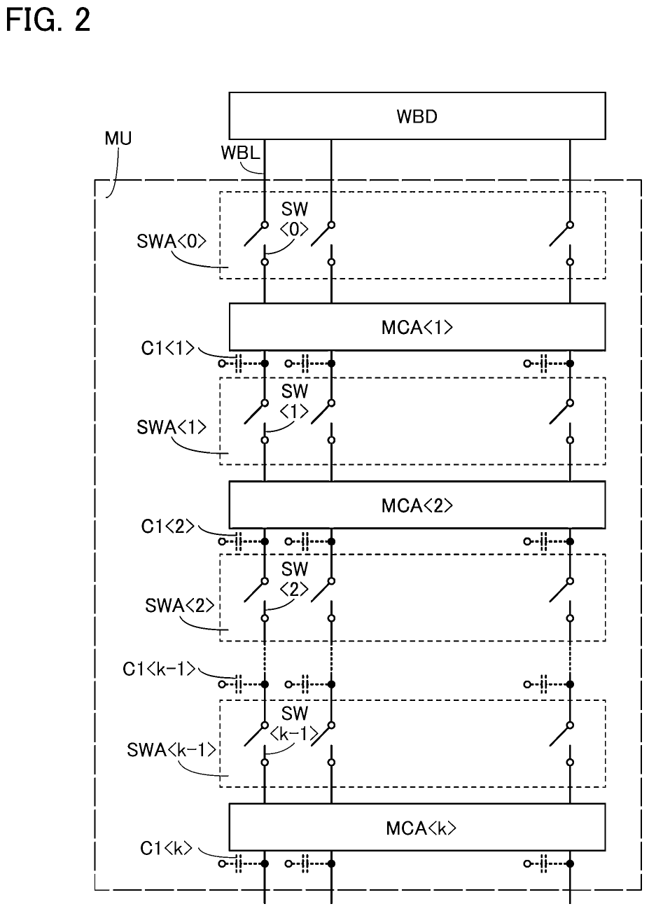

FIG. 2 is a circuit diagram illustrating a configuration example of the memory unit MU. Note that FIG. 2 also illustrates the driver circuit WBD.

The memory unit MU includes a memory cell array MCA<1> to a memory cell array MCA<k> (k is an integer greater than or equal to 1) and a switch array SWA<0> to a switch array SWA<k−1>.

For example, the switch array SWA<0> is provided between the driver circuit WBD and the memory cell array MCA<1>. The switch array SWA<1> is provided between the memory cell array MCA<1> and the memory cell array MCA<2>. Furthermore, the switch array SWA<k−1> is provided between the memory cell array MCA<k−1> and the memory cell array MCA<k>. That is, the switch arrays SWA and the memory cell arrays MCA are alternately provided in the memory unit MU. Note that the memory cell array MCA<k−1> is not illustrated in FIG. 2.

In the switch arrays SWA, switches SW are arranged. Specifically, a plurality of switches SW<0> are arranged in the switch array SWA<0>, a plurality of switches SW<1> are arranged in the switch array SWA<1>, a plurality of switches SW<2> are arranged in the switch array SWA<2>, and a plurality of switches SW<k−1> are arranged in the switch array SWA<k−1>, for example. The switches SW can be transistors, for example.

For example, one terminal of each of the switches SW<0> is electrically connected to the driver circuit WBD and the other terminal of each of the switches SW<0> is electrically connected to the memory cell array MCA<1>. One terminal of each of the switches SW<1> is electrically connected to the memory cell array MCA<1> and the other terminal of each of the switches SW<1> is electrically connected to the memory cell array MCA<2>. Furthermore, one terminal of each of the switches SW<k−1> is electrically connected to the memory cell array MCA<k−1> and the other terminal of each of the switches SW<k−1> is electrically connected to the memory cell array MCA<k>. That is, the driver circuit WBD is electrically connected to the memory cell arrays MCA via the switches SW. In addition, the memory cell arrays MCA are electrically connected to one another via the switches SW.

Specifically, the driver circuit WBD is electrically connected to the memory cell array MCA<1> to the memory cell array MCA<k> through wirings WBL via the switches SW. For example, the driver circuit WBD is electrically connected to the memory cell array MCA<1> via the switches SW<0>, electrically connected to the memory cell array MCA<2> via the switches SW<0> and the switches SW<1>, and electrically connected to the memory cell array MCA<k> via the switches SW<0> to the switches SW<k−1>.

The wirings WBL include capacitors C1 which are parasitic capacitances. Here, the capacitors C1 of the wirings WBL each of which is between the other terminal of the switch SW<0> and one terminal of the switch SW<1> are capacitors C1<1>, for example. The capacitors C1 of the wirings WBL each of which is between the other terminal of the switch SW<1> and one terminal of the switch SW<2> are capacitors C1<2>, for example. The capacitors C1 of the wirings WBL each of which is between the other terminal of the switch SW<k−2> and one terminal of the switch SW<k−1> are capacitors C1<k−1>. Furthermore, parasitic capacitances of the wirings WBL each of which is from the other terminal of the switch SW<k−1> to the memory cell array MCA<k> are capacitors C1<k>. Note that the switch array SWA<k−2> and the switches SW<k−2> are not illustrated in FIG. 2. Here, in the case where the lengths of the wirings WBL are the same in the memory cell array MCA<1> to the memory cell array MCA<k>, the capacitance values of the capacitors C1<1> to the capacitors C1<k> can be regarded as the same. Note that the parasitic capacitances are shown by dashed lines in FIG. 2. The same applies to the other diagrams in some cases.

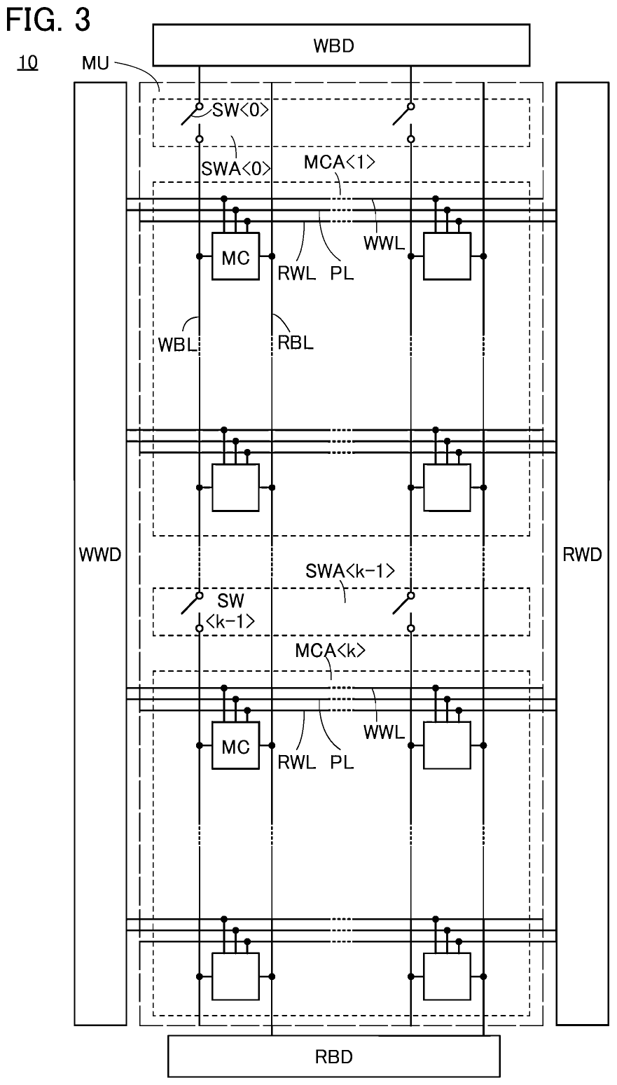

FIG. 3 is a block diagram illustrating a configuration example of the semiconductor device 10. FIG. 3 illustrates a specific example of the memory cell arrays MCA with the memory unit MU having the configuration illustrated in FIG. 2. In each of the memory cell arrays MCA, memory cells MC are arranged in a matrix.

The driver circuit WWD is electrically connected to the memory cells MC through wirings WWL. The driver circuit RWD is electrically connected to the memory cells MC through wirings RWL. The driver circuit WWD and the driver circuit RWD are electrically connected to the memory cells MC through wirings PL. The driver circuit RBD is electrically connected to the memory cells MC through wirings RBL. As described above, the driver circuit WBD is electrically connected to the memory cells MC through the wirings WBL via the switches SW. Here, the memory cells MC in the same row can be electrically connected to one another through the same wiring WWL, the same wiring PL, and the same wiring RWL, for example. In addition, the memory cells MC in the same column can be electrically connected to one another through the same wiring WBL and the same wiring RBL. Moreover, in each of the switch arrays SWA, a switch SW can be provided for each column of the memory cells MC.

The driver circuit WWD has a function of generating signals for controlling the selection of the memory cell MC to which data is to be written. The driver circuit WWD has a function of generating signals to be supplied to the wirings WWL and a function of generating signals to be supplied to the wirings PL. The driver circuit WWD can generate desired signals for selection control using a decoder circuit, a shift register circuit, or the like.

The driver circuit RWD has a function of generating signals for controlling the selection of the memory cell MC from which data is to be read. The driver circuit RWD has a function of generating signals to be supplied to the wirings RWL and a function of generating signals to be supplied to the wirings PL. The driver circuit RWD can generate desired signals for selection control using a decoder circuit, a shift register circuit, or the like.

Here, in the case where data is written to the memory cell MC, the driver circuit WWD can generate a signal to be supplied to the corresponding wiring PL. Meanwhile, in the case where data is read from the memory cell MC, the driver circuit RWD can generate a signal to be supplied to the corresponding wiring PL.

The driver circuit WBD has a function of outputting a data signal to be written to the memory cell MC. The driver circuit WBD has a function of outputting a data signal to be supplied to any of the wirings WBL. The driver circuit WBD includes a decoder circuit and a plurality of latch circuits. The driver circuit WBD has a function of outputting the data signal retained in the latch circuits at the timing of data writing to the memory cell MC.

The driver circuit RBD has a function of reading data from the memory cell MC. Specifically, the driver circuit RBD has a function of determining the data read from the memory cell MC on the basis of a potential output from the memory cell MC at the time of reading data from the memory cell MC. In the case where binary data is read from the memory cell MC, for example, the driver circuit RBD has a function of determining whether the value of the data read from the memory cell MC is “0” or “1” on the basis of the potential output from the memory cell MC. The driver circuit RBD has a function of determining the data read from the memory cell MC by, for example, comparing the levels of the potential of the corresponding wiring RBL and a reference potential. The driver circuit RBD also has a function of outputting a potential representing the data read from the memory cell MC to, for example, the outside of the semiconductor device 10. The driver circuit RBD can generate a desired potential to be output to the outside on the basis of the potential output from the memory cell MC using an amplifier circuit, a comparator, or the like, for example. The driver circuit RBD can include a precharge circuit. In that case, the driver circuit RBD can output a precharge potential to the wiring RBL.

Here, the wirings WWL can be referred to as write word lines or simply referred to as word lines, and the driver circuit WWD can be referred to as a write word line driver circuit or simply referred to as a word line driver circuit. The wirings RWL can be referred to as read word lines or simply referred to as word lines, and the driver circuit RWD can be referred to as a read word line driver circuit or simply referred to as a word line driver circuit. The wirings PL can be referred to as plate lines.

The wirings WBL can be referred to as write bit lines or simply referred to as bit lines, and the driver circuit WBD can be referred to as a write bit line driver circuit or simply referred to as a bit line driver circuit. The wirings RBL can be referred to as read bit lines or simply referred to as bit lines, and the driver circuit RBD can be referred to as a read bit line driver circuit or simply referred to as a bit line driver circuit.

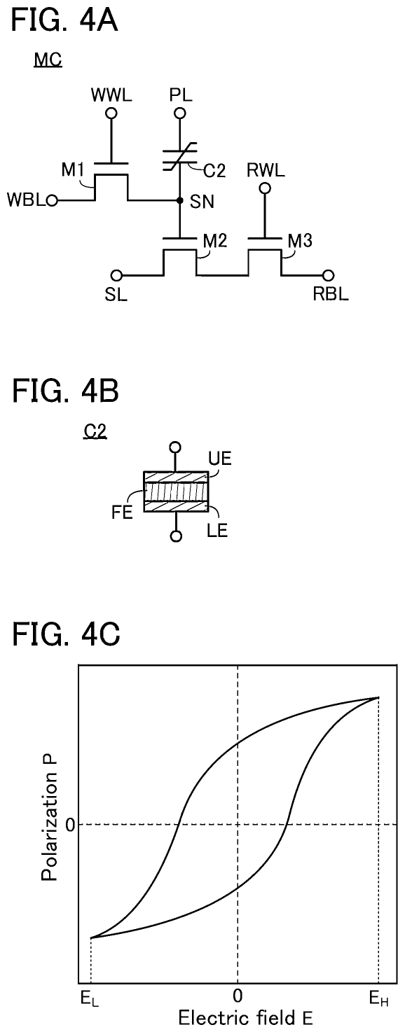

FIG. 4 is a circuit diagram illustrating a configuration example of each of the memory cells MC. The memory cell MC includes a transistor M1, a transistor M2, a transistor M3, and a capacitor C2. The capacitor C2 is a ferroelectric capacitor including a ferroelectric layer between a pair of electrodes. The capacitor C2 which is a ferroelectric capacitor including a ferroelectric layer is shown by a circuit symbol different from that of a capacitor including no ferroelectric layer.

Hereinafter, each of the transistors in the memory cell MC illustrated in FIG. 4A is described as an n-channel transistor. For example, in the case where the transistor M1 is an n-channel transistor, the transistor M1 can be brought into an on state (on) when the wiring WWL is set to have a high potential (also referred to as an H level potential or an H level). Furthermore, the transistor M1 can be brought into an off state (off) when the wiring WWL is set to have a low potential (also referred to as an L level potential or an L level). The same applies to the transistor M3. Note that the following description can also apply to the case where some or all of the transistors included in the memory cell MC are p-channel transistors when the magnitude relationship of the potentials is reversed as appropriate, for example.

One of a source and a drain of the transistor M1 is electrically connected to a gate of the transistor M2. The gate of the transistor M2 is electrically connected to one electrode of the capacitor C2. One of a source and a drain of the transistor M2 is electrically connected to one of a source and a drain of the transistor M3. Here, a node to which the one of a source and a drain of the transistor M1, the gate of the transistor M2, and the electrode of the capacitor C2 are electrically connected is referred to as a node SN.

The other of the source and the drain of the transistor M1 is electrically connected to a terminal through which the signal of the wiring WBL is transmitted. A gate of the transistor M1 is electrically connected to a terminal through which the signal of the wiring WWL is transmitted. The other of the source and the drain of the transistor M2 is electrically connected to a terminal through which the signal of a wiring SL is transmitted. The other of the source and the drain of the transistor M3 is electrically connected to a terminal through which the signal of the wiring RBL is transmitted. A gate of the transistor M3 is electrically connected to a terminal through which the signal of the wiring RWL is transmitted. The other electrode of the capacitor C2 is electrically connected to a terminal through which the signal of the wiring PL is transmitted.

The wiring SL is a wiring from which a constant potential used for reading data from the memory cell MC is supplied. At the time of reading data from the memory cell MC, current can be made to flow between the wiring RBL and the wiring SL in accordance with the data retained in the memory cell MC.

As the transistor M1 to the transistor M3, transistors whose channel formation regions contain silicon (hereinafter referred to as Si transistors) and/or transistors whose channel formation regions contain an oxide semiconductor (hereinafter referred to as OS transistors) can be used.

Note that silicon used for the channel formation regions of the Si transistors can be, for example, amorphous silicon (sometimes referred to as hydrogenated amorphous silicon), microcrystalline silicon, polycrystalline silicon, single crystal silicon, or the like. Other than OS transistors and Si transistors, transistors whose channel formation regions contain Ge or the like; transistors whose channel formation regions contain a compound semiconductor such as ZnSe, CdS, GaAs, InP, GaN, or SiGe; transistors whose channel formation regions contain a carbon nanotube; transistors whose channel formation regions contain an organic semiconductor; or the like can be used as the transistors M1 to M3.

An OS transistor can be freely placed by being stacked over a circuit using a Si transistor, for example; hence, integration can be easy. Furthermore, an OS transistor can be fabricated with a manufacturing apparatus similar to that for a Si transistor and thus can be fabricated at low cost.

Furthermore, an OS transistor has better electrical characteristics superior to those of a Si transistor in a high-temperature environment. Specifically, the ratio between on-state current and off-state current is high even at a high temperature higher than or equal to 100° C. and lower than or equal to 200° C., preferably higher than or equal to 125° C. and lower than or equal to 150° C.; hence, favorable switching operation can be performed.

FIG. 4B is a schematic diagram illustrating a structure example of the capacitor C2. The capacitor C2 includes a ferroelectric layer FE between an electrode UE and an electrode LE. The capacitor C2 including the ferroelectric layer as described above is referred to as a ferroelectric capacitor in some cases.

In the capacitor C2 including the ferroelectric layer, when voltage (electric field) is applied between the electrode UE and the electrode LE, the polarization direction and polarization amount of the ferroelectric layer FE change in accordance with the application direction and application amount of the voltage. A signal (data) is retained (written) between the electrode UE and the electrode LE by utilizing the change in the polarization state of the ferroelectric layer FE. In the capacitor C2, polarization remains in the ferroelectric layer FE even when the voltage between the electrode UE and the electrode LE is changed to zero. To renew the polarization, voltage for reversing the polarization (polarization reversal voltage) is applied.

FIG. 4C is a graph showing polarization magnitude of the ferroelectric layer FE corresponding to an electric field applied to the ferroelectric layer FE. In FIG. 4C, the horizontal axis represents an electric field E applied to the ferroelectric layer FE. The vertical axis represents polarization P of the ferroelectric layer FE.

The polarization of the ferroelectric layer FE increases as the electric field applied to the ferroelectric layer FE increases. When the electric field applied to the ferroelectric layer FE is decreased after an electric field E_{H} is applied to the ferroelectric layer FE, negative electric charges are pulled to the one electrode side of the capacitor C2 and positive electric charges are pulled to the other electrode side of the capacitor C2; thus, positive polarization remains when the electric field becomes 0. When the electric field applied to the ferroelectric layer FE is increased after an electric field E_{L} is applied to the ferroelectric layer FE, positive electric charges are pulled to the one electrode side of the capacitor C2 and negative electric charges are pulled to the other electrode side of the capacitor C2; thus, negative polarization remains when the electric field becomes 0. Voltage for applying the electric field E_{H} or the electric field E_{L} to the ferroelectric layer FE can be referred to as polarization reversal voltage. When the polarization reversal voltage is applied to the capacitor C2, data can be written to the memory cell MC.

Examples of a material that can show ferroelectricity and can be used for the ferroelectric layer FE include metal oxides such as hafnium oxide, zirconium oxide, and HfZrO_{X} (X is a real number greater than 0). Examples of the material that can show ferroelectricity also include a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide, and the like. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include metal nitrides such as scandium aluminum nitride (Al₁₋ₐScₐN_{b} (a is a real number greater than 0 and less than 0.5, and b is 1 or an approximate value thereof)), an Al—Ga—Sc nitride, and a Ga—Sc nitride. Examples of the material that can show ferroelectricity also include a metal nitride containing an element M1, an element M2, and nitrogen. Here, the element M1 is one or more selected from aluminum (Al), gallium (Ga), indium (In), and the like. The element M2 is one or more selected from boron (B), scandium (Sc), yttrium (Y), lanthanum (La), cerium (Ce), neodymium (Nd), europium (Eu), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include a material in which an element M3 is added to the above metal nitride. Note that the element M3 is one or more selected from magnesium (Mg), calcium (Ca), strontium (Sr), zinc (Zn), cadmium (Cd), and the like. Here, the atomic ratio of the element M1 to the element M2 and the element M3 can be set as appropriate. Since the above metal nitride contains at least a Group 13 element and nitrogen, which is a Group element, the metal nitride is referred to as a ferroelectric of Group III-V, a ferroelectric of a Group III nitride, or the like in some cases.

Examples of the material that can show ferroelectricity also include a perovskite-type oxynitride such as SrTaO₂N or BaTaO₂N, GaFeO₃ with a κ-alumina-type structure, and the like.

Note that although metal oxides and metal nitrides are shown as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, for example, a mixture or a compound formed of a plurality of materials selected from the above-listed materials can be used. Alternatively, the ferroelectric layer FE can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like. Furthermore, the ferroelectric includes not only a material that exhibits ferroelectricity but also a material that can show ferroelectricity.

Among the materials that can show ferroelectricity, a material containing hafnium oxide or hafnium oxide and zirconium oxide is preferable because the material can show ferroelectricity even when being processed into a thin film of several nanometers. Here, the thickness of the ferroelectric layer FE can be less than or equal to 100 nm, preferably less than or equal to 50 nm, further preferably less than or equal to 20 nm, still further preferably less than or equal to 10 nm (typified by greater than or equal to 2 nm and less than or equal to 9 nm). The thickness is preferably greater than or equal to 8 nm and less than or equal to 12 nm, for example. With the use of the ferroelectric layer that can have a small thickness, the capacitor C2 can be combined with a miniaturized semiconductor element such as a transistor to fabricate a semiconductor device. Note that in this specification and the like, the material that can show ferroelectricity processed into a layered shape is referred to as a ferroelectric layer, a metal oxide film, or a metal nitride film in some cases. Furthermore, a device including such a ferroelectric layer, metal oxide film, or metal nitride film is referred to as a ferroelectric device in this specification and the like, in some cases.

In the case where HfZrO_{X} is used as the material that can show ferroelectricity, deposition is preferably performed by an atomic layer deposition (ALD) method, particularly a thermal ALD method. In the case where deposition of the material that can show ferroelectricity is performed by a thermal ALD method, it is suitable to use a material that does not contain a hydrocarbon (also referred to as Hydro Carbon or HC) for a precursor. When the material that can show ferroelectricity contains one or both of hydrogen and carbon, crystallization of the material that can show ferroelectricity might be hindered. Thus, the precursor that does not contain a hydrocarbon is preferably used as described above to reduce the concentration(s) of one or both of hydrogen and carbon in the material that can show ferroelectricity. Examples of the precursor that does not contain a hydrocarbon include a chlorine-based material. In the case where a material containing hafnium oxide and zirconium oxide (HfZrOₓ) is used as the material that can show ferroelectricity, HfCl₄ and/or ZrCl₄ are/is used as the precursor.

In the case of depositing a film of the material that can show ferroelectricity, impurities in the film, at least one or more of hydrogen, a hydrocarbon, and carbon here, are thoroughly removed, whereby a highly purified intrinsic film having ferroelectricity can be formed. Note that the highly purified intrinsic film having ferroelectricity and a highly purified intrinsic oxide semiconductor described in a later embodiment are highly compatible with each other in the manufacturing process. Thus, a method for manufacturing a semiconductor device with high productivity can be provided.

Furthermore, in the case where HfZrO_{X} is used as the material that can show ferroelectricity, hafnium oxide and zirconium oxide are preferably deposited alternately by a thermal ALD method to have a composition of 1:1.

In the case where deposition of the material that can show ferroelectricity is performed by a thermal ALD method, H₂O or O₃ can be used as an oxidizer. However, the oxidizer in the thermal ALD method is not limited thereto. For example, the oxidizer in the thermal ALD method may contain any one or more selected from O₂, O₃, N₂O, NO₂, H₂O, and H₂O₂.

Note that the crystal structure of the material that can show ferroelectricity is not particularly limited. For example, the material that can show ferroelectricity may have any one or more selected from cubic, tetragonal, orthorhombic, and monoclinic crystal structures. The material that can show ferroelectricity especially preferably has an orthorhombic crystal structure to exhibit ferroelectricity. Alternatively, the material that can show ferroelectricity may have a composite structure of an amorphous structure and a crystal structure.

Data writing to the memory cell MC is performed in accordance with the direction of an electric field applied to the ferroelectric layer included in the capacitor C2 owing to the potential of the node SN and the potential of the wiring PL. Although the details will be described later, data is written to the memory cell MC by application of the polarization reversal voltage to the capacitor C2. The polarization state of the ferroelectric layer included in the capacitor C2 can be different depending on data to be written to the memory cell MC. Thus, data written to the memory cell MC can be retained owing to the polarization state of the ferroelectric layer included in the capacitor C2. The difference in polarization state is maintained even in a state where the electric field applied to the capacitor C2 is 0, for example. Accordingly, data can be continuously retained in the memory cell MC even when the electric field applied to the capacitor C2 becomes 0, for example.

Data reading from the memory cell MC is performed by utilizing capacitive coupling of the capacitor C2 that occurs when the potential of the wiring PL is changed. The node SN is brought into an electrically floating state when the potential of the wiring PL is changed, whereby capacitive coupling occurs in the capacitor C2. Accordingly, the potential of the node SN changes in accordance with the change in the potential of the wiring PL. The potential of the node SN changes in accordance with the capacitance value of the capacitor C2, and the capacitance value of the capacitor C2 depends on the polarization state of the ferroelectric layer included in the capacitor C2. Thus, the potential of the gate of the transistor M2 can be made different depending on the retained data. Different potentials of the gate of the transistor M2 result in different amounts of current flowing between the source and the drain of the transistor M2. Accordingly, different potentials of the wiring RBL are obtained. The difference in potential of the wiring RBL enables data reading from the memory cell MC.

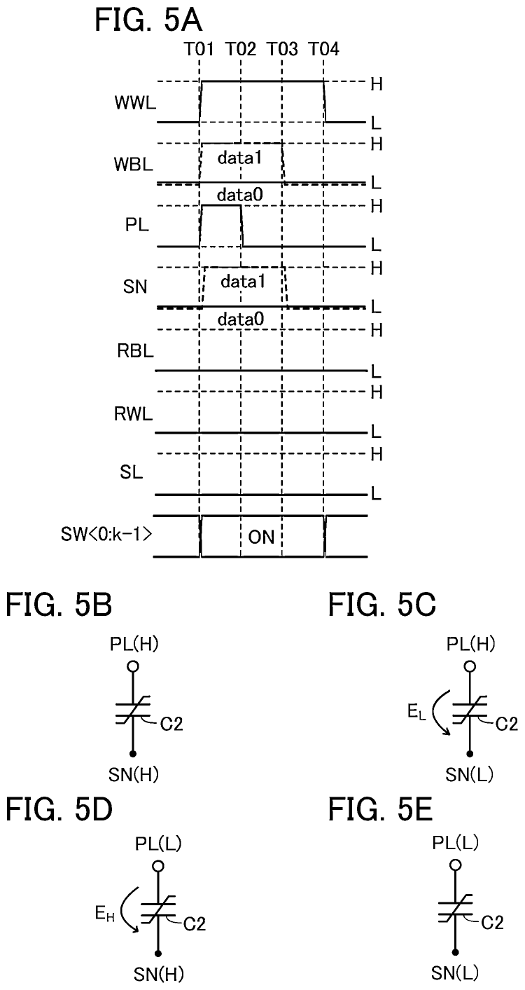

FIG. 5A is a timing chart showing a data writing operation of the memory cell MC. FIG. 5A shows the potentials of the wiring WWL, the wiring WBL, the wiring PL, the node SN, the wiring RBL, the wiring RWL, and the wiring SL. FIG. 5A also shows the states of the switch SW<0> to the switch SW<k−1>. Furthermore, FIG. 5A shows “data1” and “data0” as data written to the memory cell MC. Note that “data1” is shown as a high potential signal and “data0” is shown as a low potential signal.

In FIG. 5A, “H” means a high potential and “L” means a low potential. The same applies to the other diagrams.

Before Time T01, the potential of the wiring WWL, the potential of the wiring WBL, the potential of the wiring PL, the potential of the node SN, the potential of the wiring RBL, the potential of the wiring RWL, and the potential of the wiring SL are low potentials.

From Time T01 to Time T02, the switch SW<0> to the switch SW<k−1> are brought into on states (ON). In this state, the driver circuit WBD supplies the potential of a signal corresponding to data to be written to the memory cell MC, “data1” or “data0”, to the wiring WBL. In addition, the potential of the wiring WWL is set to a high potential. In the above manner, the potential of the wiring WBL is supplied to the node SN. From Time T01 to Time T02, the potential of the wiring PL is set to a high potential.

When the wiring PL is at a high potential and the node SN is at a high potential from Time T01 to Time T02, potentials illustrated in FIG. 5B are applied to the electrodes of the capacitor C2. Since the electrodes of the capacitor C2 are both at a high potential and have an equal potential as illustrated in FIG. 5B, voltage higher than reversal polarization voltage is not applied and an electric field does not occur in the ferroelectric layer. Meanwhile, when the wiring PL is at a high potential and the node SN is at a low potential from Time T01 to Time T02, potentials illustrated in FIG. 5C are applied to the electrodes of the capacitor C2. In this case, for example, the reversal polarization voltage is applied to the capacitor C2 and the electric field E_{L} occurs in the ferroelectric layer. Accordingly, the polarization state corresponding to “data0” is written to the capacitor C2.

In the case of applying voltage higher than the reversal polarization voltage to the capacitor C2, the transistor M1 to the transistor M3 are preferably transistors having excellent resistance to high voltages (withstand voltage). For example, the transistor M1 to the transistor M3 are preferably formed using OS transistors. OS transistors have characteristics of excellent withstand voltage as compared with Si transistors.

From Time T02 to Time T03, the potential of the wiring PL is set to a low potential. When the potential of the node SN is a high potential here, potentials illustrated in FIG. 5D are applied to the electrodes of the capacitor C2. As illustrated in FIG. 5D, reversal polarization voltage whose direction is opposite to that of the reversal polarization voltage in FIG. 5C is applied to the capacitor C2 and the electric field E_{H} occurs in the ferroelectric layer. Accordingly, the polarization state corresponding to “data1” is written to the capacitor C2. Meanwhile, when the potential of the node SN is at a low potential from Time T02 to Time T03, potentials illustrated in FIG. 5E are applied to the electrodes of the capacitor C2. Since the electrodes of the capacitor C2 are both at a low potential and have an equal potential as illustrated in FIG. 5E, voltage higher than the reversal polarization voltage is not applied and an electric field does not occur in the ferroelectric layer.

As described above, in the case of writing data0 to the memory cell MC, data0 is written to the memory cell MC from Time T01 to Time T02. Meanwhile, in the case of writing data1 to the memory cell MC, data1 is written to the memory cell MC from Time T02 to Time T03.

From Time T03 to Time T04, the potential of the wiring WBL is set to a low potential. Accordingly, the potential of the node SN becomes a low potential. Since the potential of the wiring PL is also a low potential here, voltage higher than the reversal polarization voltage is not applied to the ferroelectric layer of the capacitor C2. Thus, the polarization state of the ferroelectric layer is retained. Accordingly, data written to the memory cell MC from Time T01 to Time T03 is retained.

After Time T04, the potential of the wiring WWL is set to a low potential and the switch SW<0> to the switch SW<k−1> are brought into off states. Accordingly, the operation of writing data to the memory cell MC terminates.

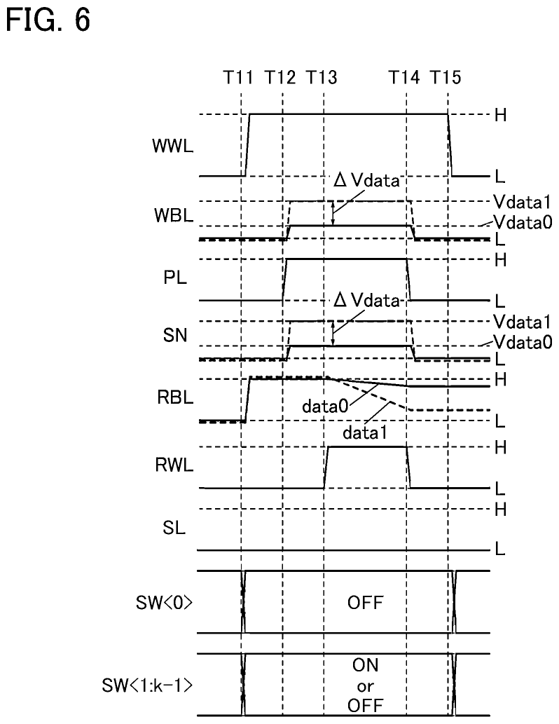

FIG. 6 is a timing chart showing a data reading operation of the memory cell MC. Like FIG. 5A, FIG. 6 shows the potentials of the wiring WWL, the wiring WBL, the wiring PL, the node SN, the wiring RBL, the wiring RWL, and the wiring SL. Furthermore, the states of the switch SW<0> to the switch SW<k−1> are shown. Moreover, “data1” and “data0” are shown as data written to the memory cell MC. In FIG. 6, “data1” and “data0” each correspond to data retained as the polarization state of the ferroelectric layer of the capacitor C2 in the data writing operation.

Before Time T11, the potential of the wiring WWL, the potential of the wiring WBL, the potential of the wiring PL, the potential of the node SN, the potential of the wiring RBL, the potential of the wiring RWL, and the potential of the wiring SL are low potentials.

From Time T11 to Time T12, the switch SW<0> is brought into an off state. Accordingly, an electrical connection between the driver circuit WBD and the memory cell MC is broken and the signal generated by the driver circuit WBD is not supplied to the memory cell MC, for example. After that, the potential of the wiring WWL is set to a high potential. Accordingly, the transistor M1 is brought into an on state and the node SN and the wiring WBL are brought into conduction. Since the electrical connection between the driver circuit WBD and the memory cell MC is broken at this time, the node SN is in an electrically floating state even when the node SN and the wiring WBL are brought into conduction. Furthermore, the potential of the wiring RBL is precharged to a high potential, for example. In addition, each of the switch SW<1> to the switch SW<k−1> is brought into an on state or an off state (ON or OFF). A method for determining which switch SW to be turned on will be described later.

From Time T12 to Time T13, the potential of the wiring PL is set to a high potential. As described above, the node SN is in an electrically floating state. Thus, the potential of the node SN changes owing to the capacitor C2 and capacitive coupling of the node SN.

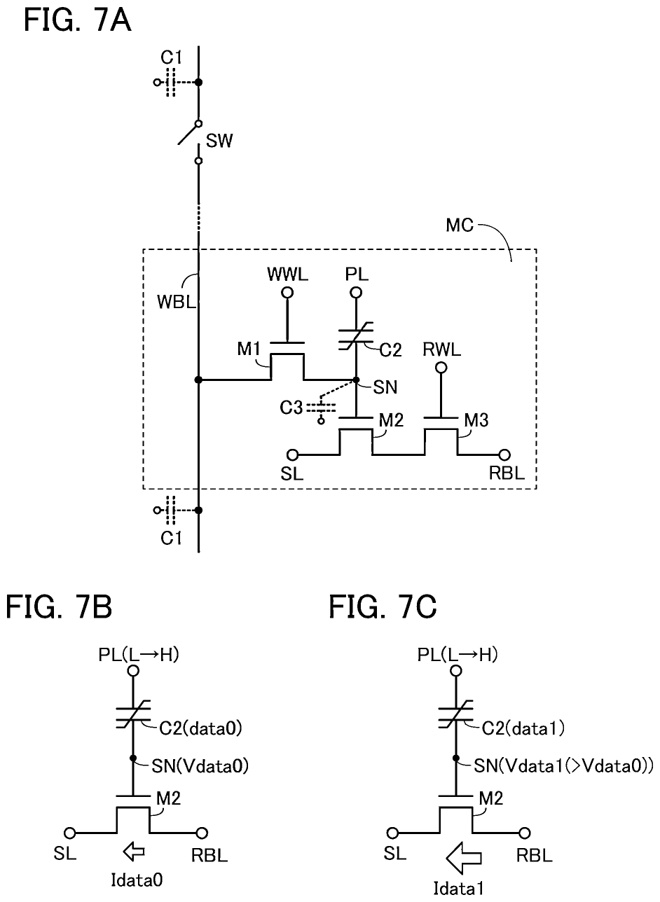

FIG. 7A is a circuit diagram illustrating parasitic capacitance and the like in addition to the memory cell MC illustrated in FIG. 4A. As illustrated in FIG. 7A, the node SN includes a capacitor C3 which is parasitic capacitance due to the gate capacitance of the transistor M2 or the like. As described above, the wiring WBL includes the capacitors C1 which are parasitic capacitances.

From Time T12 to Time T13, the node SN and the wiring WBL are in a conduction state. According to the above, a potential change range ΔV_{SN} of the node SN due to the change in the potential of the wiring PL is determined by a capacitance value C_{FE} of the capacitor C2, a capacitance value C_{S} of the capacitor C3 which is parasitic capacitance, and a capacitance value C_{WBL} obtained due to the capacitors C1 which are parasitic capacitances of the wiring WBL; when the potential change range of the wiring PL is ΔVPL, ΔV_{SN} can be expressed by Formula (1).

$$\begin{matrix}[ Formula 1 ] & \\ Δ {V}_{S N} = \frac{{C}_{FE}}{{C}_{FE} + {C}_{S} + {C}_{WBL}} \times Δ {V}_{P L} & ( 1 )\end{matrix}$$

The capacitance value C_{FE} of the capacitor C2 is determined by the polarization state of the ferroelectric layer included in the capacitor C2. The polarization state is different depending on whether the data retained in the memory cell MC is “data1” or “data0”. Thus, the potential change range ΔV_{SN} of the node SN can be made different depending on the data retained in the memory cell; accordingly, a potential V_{SN} of the node SN can be made different.

From Time T13 to Time T14, the potential of the wiring RWL is set to a high potential. Accordingly, the transistor M3 is brought into an on state and current corresponding to the potential of the node SN flows between the drain and the source of the transistor M2.

FIG. 7B is a diagram illustrating the potential of the node SN and the current flowing between the drain and the source of the transistor M2 when the potential of the wiring PL is changed from a low potential to a high potential in the case where “data0” is retained in the memory cell MC. In the case illustrated in FIG. 7B, the potential of the node SN is a potential Vdata0 and the current flowing between the drain and the source of the transistor M2 is current Idata0.

FIG. 7C is a diagram illustrating the potential of the node SN and the current flowing between the drain and the source of the transistor M2 when the potential of the wiring PL is changed from a low potential to a high potential in the case where “data1” is retained in the memory cell MC. In the case illustrated in FIG. 7C, the potential of the node SN is a potential Vdata1 and the current flowing between the drain and the source of the transistor M2 is current Idata1. The current Idata1 is assumed to be higher than the current Idata0.

The current Idata1 is higher than the current Idata0. Thus, on the assumption that the potential of the wiring RBL is higher than the potential of the wiring SL, the potential of the wiring RBL of the case where “data1” is retained in the memory cell MC is lower than the potential of the wiring RBL of the case where “data0” is retained in the memory cell MC. Accordingly, data can be read from the memory cell MC on the basis of the potential of the wiring RBL.

Here, the capacitance value of the capacitor C2 of the case where the data retained in the memory cell MC is “data1” is a capacitance value C_{FE1} and the capacitance value of the capacitor C2 of the case where the data retained in the memory cell MC is “data0” is a capacitance value C_{FE0}. When the difference between the potential Vdata1 and the potential Vdata0 is ΔVdata, ΔVdata can be expressed by Formula (2).

$$\begin{matrix}[ Formula 2 ] & \\ \begin{matrix}Δ Vdata = \frac{{C}_{FE 1}}{{C}_{F E 1} + {C}_{S} + {C}_{WBL}} \times Δ {V}_{PL} - \\ \frac{{C}_{FE 0}}{{C}_{FE 0} + {C}_{S} + {C}_{WBL}} \times Δ {V}_{P L} \\ = \frac{( {C}_{F E 1} - {C}_{FE 0} ) ( {S}_{S} + {C}_{WBL} )}{( {C}_{FE 1} + {C}_{S} + {C}_{WBL} ) ( {C}_{FE 0} + {C}_{S} + {C}_{WBL}} \times Δ {V}_{PL}\end{matrix} & ( 2 )\end{matrix}$$

Larger ΔVdata is preferable because the data retained in the memory cell MC can be read with higher accuracy. A value Cmax, which is the value of “Cₛ+C_{WBL}” leading to the maximum ΔVdata, is a value which makes a derivative obtained by partial differentiation of Formula (2) with respect to “Cₛ+C_{WBL}” 0, and can be expressed by Formula (3).

[Formula 3]

Cmax=\sqrt{C_{FE1}·C_{FE0}} (3)

Thus, the value of C_{WBL} is adjusted such that “Cₛ+C_{WBL}” becomes √(C_{FE1}·C_{FE0}), whereby large ΔVdata can be obtained.

The capacitance value C_{WBL} can be controlled by controlling the on/off of the switches SW. For example, when all of the switch SW<1> to the switch SW<k−1> are brought into off states, the node SN is electrically connected to one of the capacitors C1. Meanwhile, when one of the switch SW<1> to the switch SW<k−1> to which a memory cell from which data is to be read is electrically connected is brought into an on state, for example, the node SN is electrically connected to two of the capacitors C1. Accordingly, the capacitance value C_{WBL} can be larger than that of the case where all of the switch SW<1> to the switch SW<k−1> are brought into off states. An increase in the number of the switches SW to be brought into an on state can further increase the capacitance value C_{WBL}.

In the case where the capacitance value C_{FE1} and the capacitance value C_{FE0} are changed, it is preferred to adjust the number of the switches SW to be brought into an on state accordingly. The capacitance value C_{FE1} and the capacitance value C_{FE0} are changed by fatigue deterioration of the ferroelectric layer included in the capacitor C2 in some cases, for example. In that case, the value of C_{WBL} is adjusted by adjusting the number of the switches SW to be brought into an on state, whereby a decrease in ΔVdata can be inhibited. Accordingly, the semiconductor device 10 can be a highly reliable semiconductor device.

From Time T14 to Time T15, the potential of the wiring PL and the potential of the wiring RWL are set to low potentials. After Time T15, the potential of the wiring WWL is set to a low potential. In the above manner, data reading from the memory cell MC terminates.

The semiconductor device of one embodiment of the present invention includes a plurality of the memory cell arrays MCA, and each of the switch arrays SWA is provided between the memory cell arrays MCA. The write bit line driver circuit is electrically connected to each of the plurality of memory cell arrays MCA through the write bit lines via the switches SW provided in the switch arrays SWA.

In the semiconductor device of one embodiment of the present invention, when data is read from one of the memory cells MC provided in the corresponding memory cell array MCA, a high potential is applied to the corresponding wiring WWL, which is a write word line, to bring the transistor M1 into an on state. Furthermore, the on/off of each of the switches SW is controlled on the basis of the capacitance value C_{FE1} of the capacitor C2 of the case where the data retained in the memory cell MC is “data1” and the capacitance value C_{FE0} of the capacitor C2 of the case where data retained in the memory cell MC is “data0”. Accordingly, a difference between the potential of the wiring RBL at the time of reading “data0” from the memory cell MC and the potential of the wiring RBL at the time of reading “data1” from the memory cell MC can be large. Thus, the data can be read from the memory cell MC with high accuracy.

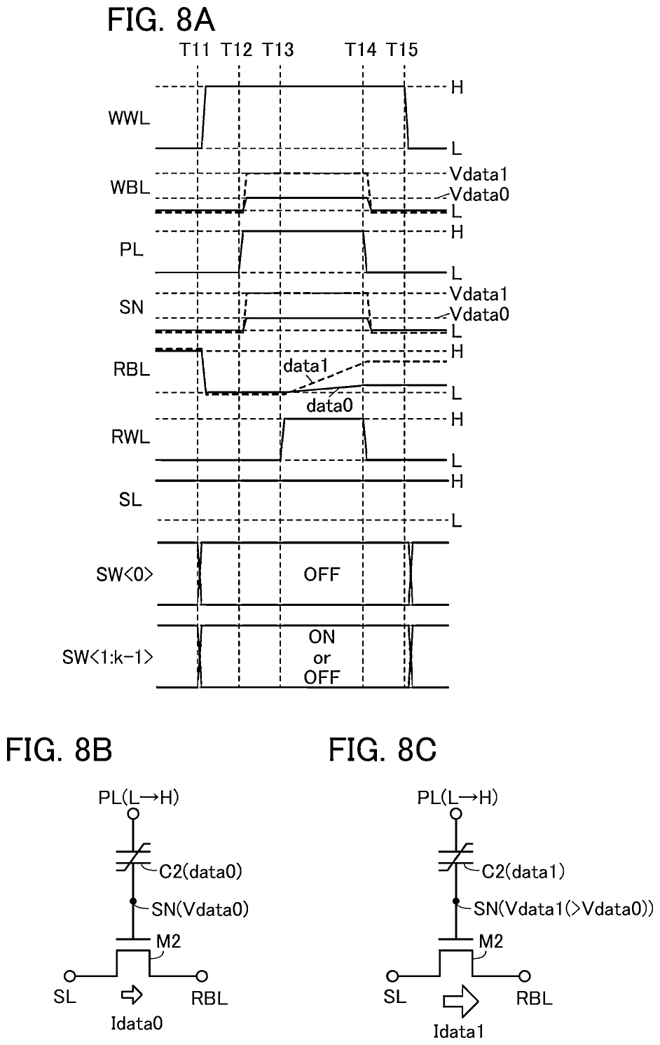

FIG. 8A is a timing chart showing a data reading operation of the memory cell MC, which is a modification example of the operation method shown in FIG. 6. In the operation method shown in FIG. 8A, the potential of the wiring SL is set to a high potential. Furthermore, the potential of the wiring RBL is precharged to a low potential from Time T11 to Time T12.

FIG. 8B and FIG. 8C are diagrams illustrating current flowing between the drain and the source of the transistor M2 and the like from Time T13 to Time T14, which are modification examples of FIG. 7B and FIG. 7C, respectively. In the case where the memory cell MC is driven by the method shown in FIG. 8A, from Time T13 to Time T14, the current Idata0 corresponding to the potential Vdata0 or the current Idata1 corresponding to the potential Vdata1 flows from the wiring SL to the wiring RBL as illustrated in FIG. 8B and FIG. 8C.

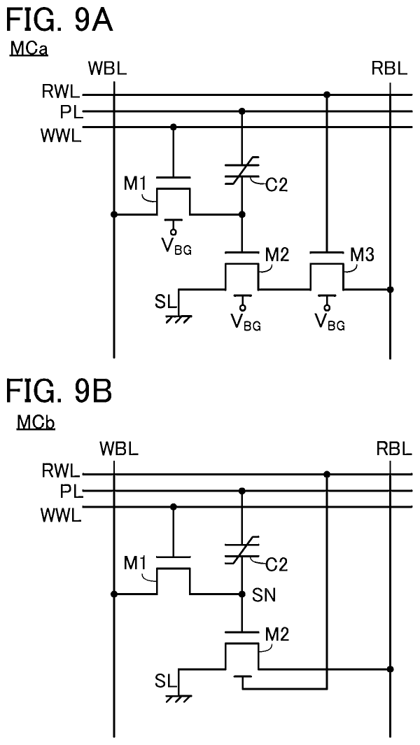

FIG. 9A and FIG. 9B are circuit diagrams illustrating configuration examples of the memory cell MC, which are modification examples of the memory cell MC illustrated in FIG. 4A. A memory cell MCa illustrated in FIG. 9A is different from the memory cell MC illustrated in FIG. 4A in that the transistor M1 to the transistor M3 include back gate electrodes. Back gate voltage V_{BG} is applied to each of the back gates of the transistor M1 to the transistor M3. In the memory cell MCa, each of the transistors can have a high on-state current.

A memory cell MCb illustrated in FIG. 9B is different from the memory cell MC illustrated in FIG. 4A in that the transistor M3 is not included and the wiring RWL is electrically connected to a back gate of the transistor M2. In the memory cell MCb, the threshold voltage of the transistor M2 can be controlled by a selection signal supplied to the wiring RWL. Accordingly, whether current is made to flow between the wiring RBL and the wiring SL can be determined.

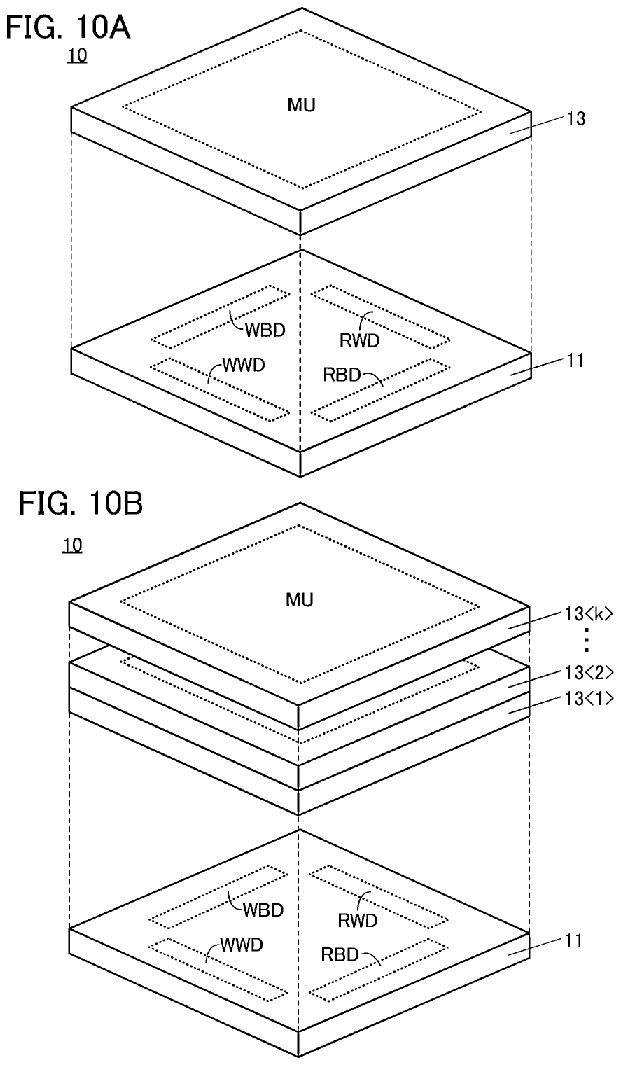

FIG. 10A is a perspective view illustrating a structure example of the semiconductor device 10. The semiconductor device 10 illustrated in FIG. 10A includes a layer 11 and a layer 13. The layer 11 and the layer 13 are stacked so as to include a region overlapping with each other. For easy understanding of the structure of the semiconductor device 10, the layer 11 and the layer 13 are separately illustrated in FIG. 10A. The same applies to the other diagrams.

The layer 11 can be provided with the driver circuit WWD, the driver circuit RWD, the driver circuit WBD, and the driver circuit RBD, and the layer 13 can be provided with the memory unit MU, for example. Accordingly, the semiconductor device 10 can be designed to have a region where the memory unit MU overlaps with the driver circuits.

When the semiconductor device 10 has the structure illustrated in FIG. 10A, the driver circuits and the memory cells provided in the memory unit MU can be formed using transistors having different electrical characteristics. For example, the driver circuits can be formed using Si transistors and the memory cells provided in the memory unit MU can be formed using OS transistors. Thus, the design flexibility of the semiconductor device 10 can be increased.

FIG. 10B is a perspective view illustrating a structure example of the semiconductor device 10, which is a modification example of the semiconductor device 10 illustrated in FIG. 10A. The semiconductor device 10 illustrated in FIG. 10B is provided with a plurality of the layers 13. FIG. 10B illustrates an example in which k layers 13 are provided.

In the semiconductor device 10 illustrated in FIG. 10B, for example, the memory cell array MCA<1> and the switch array SWA<0> are provided in a layer 13<1>. Furthermore, the memory cell array MCA<2> and the switch array SWA<1> are provided in a layer 13<2>. Moreover, the memory cell array MCA<k> and the switch array SWA<k−1> are provided in a layer 13<k>.

Providing the plurality of layers 13 can increase the total area of the memory unit MU while inhibiting an increase in size of the semiconductor device 10. Thus, the semiconductor device 10 can be a semiconductor device capable of storing large-volume data.

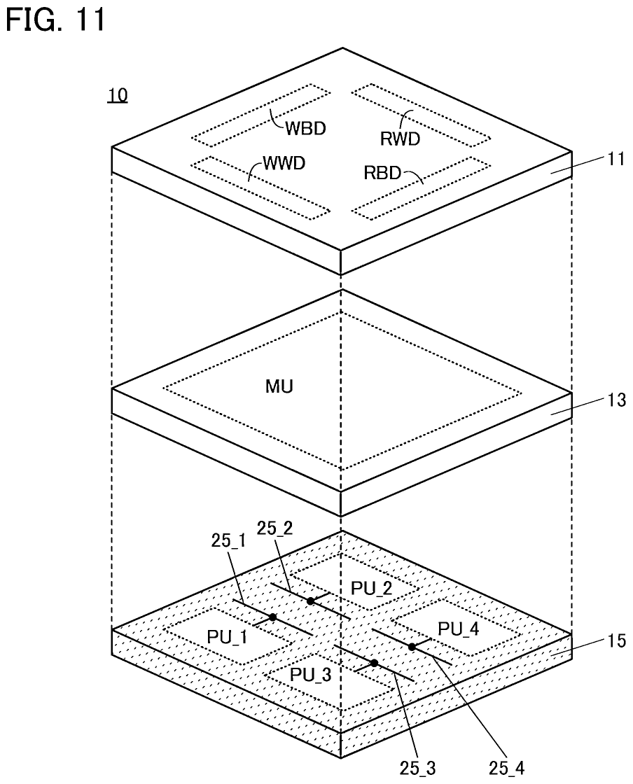

FIG. 11 is a perspective view illustrating a structure example of the semiconductor device 10, which is a modification example of the semiconductor device 10 illustrated in FIG. 10A. The semiconductor device 10 illustrated in FIG. 11 is different from the semiconductor device 10 illustrated in FIG. 10A in that a layer 15 is provided. The layer 15 is stacked so as to include a region overlapping with the layer 11 and the layer 13. For easy understanding of the structure of the semiconductor device 10, the layer 11, the layer 13, and the layer 15 are separately illustrated in FIG. 11.

The layer 15 includes an arithmetic portion PU. The arithmetic portion PU has a function of performing an arithmetic operation for adding a function to the semiconductor device 10. The arithmetic portion PU has a function of, for example, performing a product-sum operation; for example, a function of performing a product-sum operation of a neural network. In the case where the arithmetic portion PU has a function of performing a product-sum operation, the memory unit MU can retain data (weight data) corresponding to a weight parameter and data (bias data) corresponding to a bias value, which are used in the product-sum operation, for example.

A power line 25 is electrically connected to the arithmetic portion PU. A power supply potential necessary for driving the arithmetic portion PU is supplied to the arithmetic portion PU through the power line 25.

The layer 13 provided with the memory unit MU is preferably provided between the layer 15 provided with the arithmetic portion PU and the layer 11 provided with the driver circuits used for driving the memory cells provided in the memory unit MU as illustrated in FIG. 11. In that case, a wiring distance from the arithmetic portion PU to the memory unit MU can be shorter than that of the case where the layer 11 is provided between the layer 15 and the layer 13, for example. Thus, the communication speed of the case where data retained in the memory unit MU is read by the arithmetic portion PU can be increased, for example, leading to an increase in driving speed of the semiconductor device 10. In addition, the short wiring distance from the arithmetic portion PU to the memory unit MU enables the semiconductor device 10 to have low power consumption.

The layer 15 preferably includes a plurality of the arithmetic portions PU. FIG. 11 illustrates an example in which an arithmetic portion PU_1 to an arithmetic portion PU_4 are provided in the layer 15 as the arithmetic portions PU. The arithmetic portion PU_1 to the arithmetic portion PU_4 can be electrically connected to their respective power lines 25. FIG. 11 illustrates a structure example in which the arithmetic portion PU_1 is electrically connected to a power line 25_1, the arithmetic portion PU_2 is electrically connected to a power line 25_2, the arithmetic portion PU_3 is electrically connected to a power line 25_3, and the arithmetic portion PU_4 is electrically connected to a power line 25_4. A structure in which the power line 25_1 to the power line 25_4 are not electrically connected to one another can be employed, for example.

Providing the plurality of arithmetic portions PU electrically connected to their respective power lines 25 allows the arithmetic portions PU to perform an arithmetic operation continuously, even when some of the plurality of arithmetic portions PU are not driven normally, by driving the rest of the arithmetic portions PU continuously. Thus, the reliability of the semiconductor device 10 can be higher than that of the case where only one arithmetic portion PU is provided. Note that the driver circuits in the layer 11 may be provided for each of the arithmetic portions PU. That is, the layer 11 in the example illustrated in FIG. 11 may include four driver circuits WWD, four driver circuits RWD, four driver circuits WBD, and four driver circuits RBD, for example.

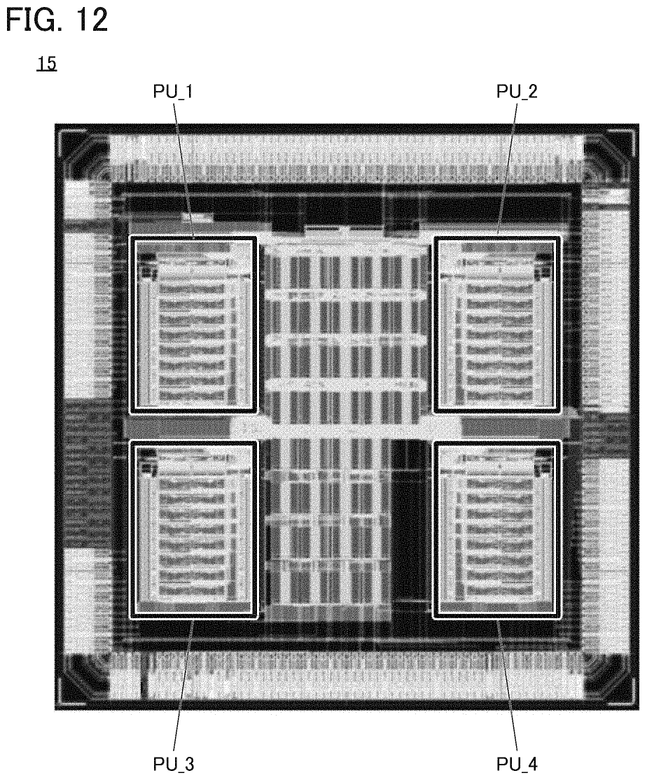

FIG. 12 is a diagram illustrating an example of a layout of the layer 15. FIG. 12 was drawn using an EDA system for semiconductor design, “SX-Meister”, manufactured by JEDAT Inc. The layer 15 can be provided with the arithmetic portion PU_1 to the arithmetic portion PU_4 as shown in FIG. 12.

Note that this embodiment can be combined with any of the other embodiments described in this specification as appropriate.

### Embodiment 2

In this embodiment, structure examples of transistors that can be used in the semiconductor device described in the above embodiment are described. As an example, a structure in which transistors having different electrical characteristics are stacked is described. With the structure, the flexibility in design of the semiconductor device can be increased. Stacking transistors having different electrical characteristics can increase the degree of integration of the semiconductor device.

### <Structure Example of Semiconductor Device>

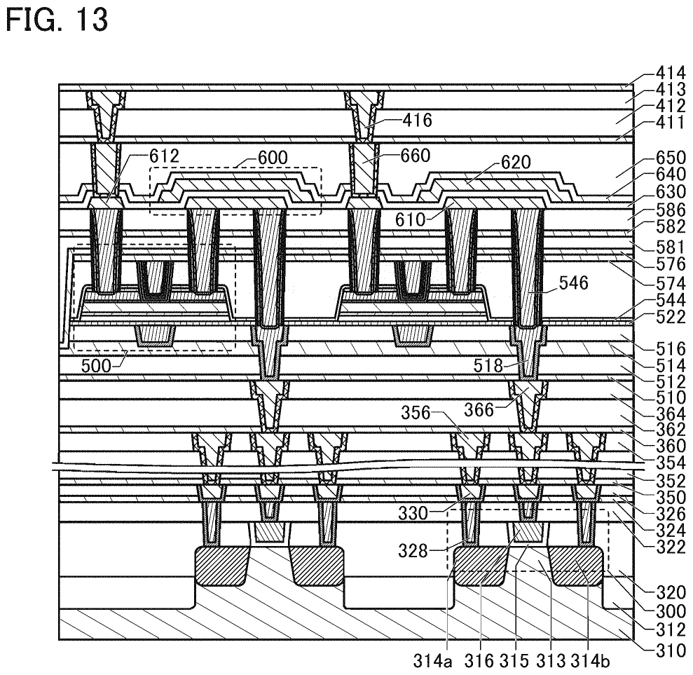

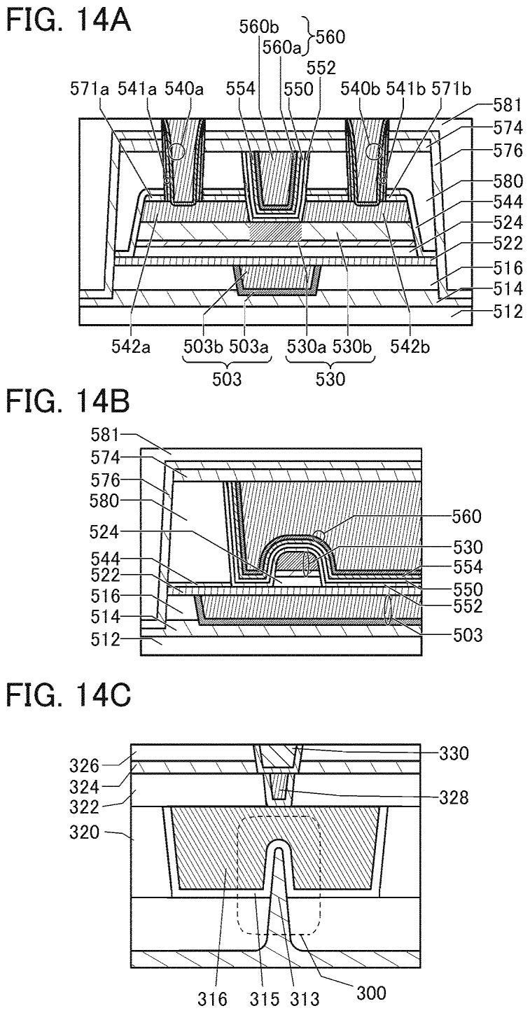

FIG. 13 illustrates the semiconductor device described in the above embodiment as an example, and the semiconductor device includes a transistor 300, a transistor 500, and a capacitor 600. FIG. 14A is a cross-sectional view of the transistor 500 in the channel length direction, FIG. 14B is a cross-sectional view of the transistor 500 in the channel width direction, and FIG. 14C is a cross-sectional view of the transistor 300 in the channel width direction.

The transistor 500 is a transistor containing a metal oxide in its channel formation region (an OS transistor). The transistor 500 has features that the off-state current is low and that the field-effect mobility hardly changes even at high temperatures. The transistor 500 is used as a semiconductor device, for example, the OS transistor described in the above embodiment, whereby a semiconductor device whose performance is less likely to degrade even at high temperatures can be obtained.

The transistor 500 is provided above the transistor 300, for example, and the capacitor 600 is provided above the transistor 300 and the transistor 500, for example. Note that the capacitor 600 can be the capacitor described in the above embodiment.

The transistor 300 is provided on a substrate 310 and includes an element isolation layer 312, a conductor 316, an insulator 315, a semiconductor region 313 that is part of the substrate 310, and a low-resistance region 314a and a low-resistance region 314b functioning as a source region and a drain region. Note that the transistor 300 can be used as, for example, the Si transistor described in the above embodiment. Note that FIG. 13 illustrates, as an example, a structure in which a gate of the transistor 300 is electrically connected to one of a source and a drain of the transistor 500 through a pair of electrodes of the capacitor 600.

A semiconductor substrate (e.g., a single crystal substrate or a silicon substrate) is preferably used as the substrate 310.

In the transistor 300, a top surface and a side surface in the channel width direction of the semiconductor region 313 are covered with the conductor 316 with the insulator 315 therebetween, as illustrated in FIG. 14C. Such a Fin-type transistor 300 can have an increased effective channel width, and thus the transistor 300 can have improved on-state characteristics. In addition, since contribution of an electric field of a gate electrode can be increased, the off-state characteristics of the transistor 300 can be improved.

Note that the transistor 300 may be either a p-channel transistor or an n-channel transistor.

A region of the semiconductor region 313 where a channel is formed, a region in the vicinity thereof, the low-resistance region 314a functioning as one of the source region and the drain region, the low-resistance region 314b functioning as the other of the source region and the drain region, and the like preferably contain a semiconductor such as a silicon-based semiconductor, and further preferably contain single crystal silicon. Alternatively, the regions may be formed using a material containing Ge (germanium), SiGe (silicon germanium), GaAs (gallium arsenide), GaAlAs (gallium aluminum arsenide), GaN (gallium nitride), or the like. A structure using silicon whose effective mass is controlled by applying stress to the crystal lattice and changing the lattice spacing may be employed. Alternatively, the transistor 300 may be an HEMT (High Electron Mobility Transistor) with GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used in the semiconductor region 313.

For the conductor 316 functioning as a gate electrode, a semiconductor material such as silicon containing an element that imparts n-type conductivity, such as arsenic or phosphorus, or an element that imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten or aluminum for the conductor, and it is particularly preferable to use tungsten in terms of heat resistance.

The element isolation layer 312 is provided to separate a plurality of transistors on the substrate 310 from each other. The element isolation layer can be formed by, for example, a LOCOS (LOCal Oxidation of Silicon) method, an STI (Shallow Trench Isolation) method, a mesa isolation method, or the like.

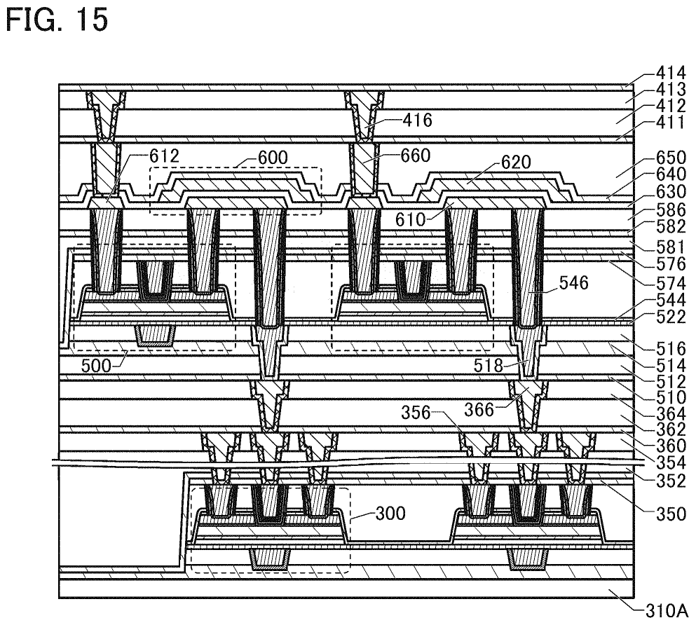

Note that the transistor 300 illustrated in FIG. 13 is an example and the structure is not limited thereto; a transistor appropriate for a circuit structure, a driving method, or the like is used. For example, the transistor 300 may have a planar structure instead of a FIN-type structure illustrated in FIG. 14C. For example, when a semiconductor device is a single-polarity circuit using only OS transistors, the transistor 300 has a structure similar to that of the transistor 500 using an oxide semiconductor, as illustrated in FIG. 15. Note that the details of the transistor 500 will be described later. In this specification and the like, a single-polarity circuit refers to a circuit including only either n-channel transistors or p-channel transistors.

Note that in FIG. 15, the transistor 300 is provided over a substrate 310A; in this case, a semiconductor substrate may be used as the substrate 310A, as in the case of the substrate 310 in the semiconductor device in FIG. 13. As the substrate 310A, for example, an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used. Examples of the glass substrate include barium borosilicate glass, aluminoborosilicate glass, and soda lime glass. As examples of the flexible substrate, the attachment film, the base material film, and the like, plastics typified by polyethylene terephthalate (PET), polyethylene naphthalate (PEN), polyether sulfone (PES), and polytetrafluoroethylene (PTFE) can be given. Furthermore, a synthetic resin such as acrylic and the like can be given. Furthermore, polypropylene, polyester, polyvinyl fluoride, polyvinyl chloride, and the like can be given. Furthermore, polyamide, polyimide, aramid, an epoxy resin, an inorganic vapor deposition film, paper, and the like can be given.

In the transistor 300 illustrated in FIG. 13, an insulator 320, an insulator 322, an insulator 324, and an insulator 326 are stacked in this order from the substrate 310 side.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride can be used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 300, for example. For example, the top surface of the insulator 322 may be planarized by planarization treatment using a chemical mechanical polishing (CMP) method or the like to improve planarity.

As the insulator 324, it is preferable to use a film having a barrier property that prevents diffusion of hydrogen, impurities, or the like from the substrate 310, the transistor 300, or the like into a region where the transistor 500 is provided.

For the film having a barrier property against hydrogen, silicon nitride formed by a chemical vapor deposition (CVD) method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 300. The film that inhibits hydrogen diffusion is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. The dielectric constant of the insulator 326 is, for example, preferably 0.7 times or less, further preferably 0.6 times or less the dielectric constant of the insulator 324. When a material with a low permittivity is used for an interlayer film, the parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 have a function of a plug or a wiring. A plurality of conductors having a function of a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material of each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 13, an insulator 350, an insulator 352, and an insulator 354 are provided to be stacked in this order above the insulator 326 and the conductor 330. Furthermore, a conductor 356 is formed in the insulator 350, the insulator 352, and the insulator 354. The conductor 356 has a function of a plug or a wiring that is connected to the transistor 300. Note that the conductor 356 can be provided using a material similar to those for the conductor 328 and the conductor 330.

For example, like the insulator 324, the insulator 350 is preferably formed using an insulator having a barrier property against impurities such as hydrogen or water. The insulator 352 and the insulator 354 are preferably formed using an insulator having a relatively low dielectric constant to reduce the parasitic capacitance generated between wirings, like the insulator 326. Furthermore, the conductor 356 preferably contains a conductor having a barrier property against impurities such as hydrogen or water. In particular, the conductor having a barrier property against hydrogen is formed in an opening portion included in the insulator 350 having a barrier property against hydrogen. With this structure, the transistor 300 and the transistor 500 can be separated by the barrier layer, so that diffusion of hydrogen from the transistor 300 into the transistor 500 can be inhibited.

For the conductor having a barrier property against hydrogen, tantalum nitride is preferably used, for example. In addition, the use of a stack including tantalum nitride and tungsten, which has high conductivity, can inhibit diffusion of hydrogen from the transistor 300 while the conductivity of a wiring is kept. In that case, a structure is preferable in which a tantalum nitride layer having a barrier property against hydrogen is in contact with the insulator 350 having a barrier property against hydrogen.

An insulator 360, an insulator 362, and an insulator 364 are stacked in this order over the insulator 354 and the conductor 356.

Like the insulator 324 or the like, the insulator 360 is preferably formed using an insulator having a barrier property against impurities such as water or hydrogen. Thus, the insulator 360 can be formed using any of the materials usable for the insulator 324 or the like, for example.

The insulator 362 and the insulator 364 have functions of an interlayer insulating film and a planarization film. Like the insulator 324, the insulator 362 and the insulator 364 are preferably formed using an insulator having a barrier property against impurities such as water or hydrogen. Thus, the insulator 362 and/or the insulator 364 can be formed using any of the materials usable for the insulator 324.

An opening portion is provided in regions of the insulator 360, the insulator 362, and the insulator 364 that overlap with part of the conductor 356, and the conductor 366 is provided to fill the opening portion. The conductor 366 is also formed over the insulator 362. The conductor 366 has a function of a plug or a wiring connected to the transistor 300, for example. Note that the conductor 366 can be provided using a material similar to those for the conductor 328 and the conductor 330.

An insulator 510, an insulator 512, an insulator 514, and an insulator 516 are stacked in this order over the insulator 364 and the conductor 366. A substance with a barrier property against oxygen and hydrogen is preferably used for any of the insulator 510, the insulator 512, the insulator 514, and the insulator 516.

For example, as the insulator 510 and the insulator 514, it is preferable to use a film having a barrier property that prevents diffusion of hydrogen or impurities from the substrate 310, a region where the transistor 300 is provided, or the like into the region where the transistor 500 is provided. Thus, a material similar to that for the insulator 324 can be used.

As described above, for the film having a barrier property against hydrogen, silicon nitride deposited by a CVD method can be used. For the film having a barrier property against hydrogen, a metal oxide such as aluminum oxide, hafnium oxide, or tantalum oxide is preferably used for the insulator 510 and the insulator 514, for example.

In particular, aluminum oxide has an excellent blocking effect that prevents passage of oxygen and impurities such as hydrogen and moisture that would cause a change in the electrical characteristics of the transistor. Accordingly, aluminum oxide can prevent entry of impurities such as hydrogen and moisture into the transistor 500 in and after the manufacturing process of the transistor. In addition, release of oxygen from the oxide included in the transistor 500 can be inhibited. Therefore, aluminum oxide is suitably used for a protective film of the transistor 500.

For the insulator 512 and the insulator 516, a material similar to that for the insulator 320 can be used, for example. Furthermore, when a material with a relatively low permittivity is used for these insulators, parasitic capacitance generated between wirings can be reduced. A silicon oxide film, a silicon oxynitride film, or the like can be used for the insulator 512 and the insulator 516, for example.

A conductor 518, a conductor included in the transistor 500 (e.g., a conductor 503 illustrated in FIG. 14A and FIG. 14B), and the like are embedded in the insulator 510, the insulator 512, the insulator 514, and the insulator 516. Note that the conductor 518 has a function of a plug or a wiring that is connected to the capacitor 600 or the transistor 300. The conductor 518 can be provided using a material similar to those for the conductor 328 and the conductor 330.

In particular, a region of the conductor 518 that is in contact with the insulator 510 and the insulator 514 is preferably a conductor having a barrier property against oxygen, hydrogen, and water. With this structure, the transistor 300 and the transistor 500 can be separated by the layer having a barrier property against oxygen, hydrogen, and water; hence, diffusion of hydrogen from the transistor 300 into the transistor 500 can be inhibited.

The transistor 500 is provided above the insulator 516.

As illustrated in FIG. 14A and FIG. 14B, the transistor 500 includes the insulator 516 over the insulator 514, the conductor 503 (a conductor 503a and a conductor 503b) provided to be embedded in the insulator 514 and the insulator 516, an insulator 522 over the insulator 516 and the conductor 503, an insulator 524 over the insulator 522, an oxide 530a over the insulator 524, an oxide 530b over the oxide 530a, a conductor 542a over the oxide 530b, an insulator 571a over the conductor 542a, a conductor 542b over the oxide 530b, an insulator 571b over the conductor 542b, an insulator 552 over the oxide 530b, an insulator 550 over the insulator 552, an insulator 554 over the insulator 550, a conductor 560 (a conductor 560a and a conductor 560b) that is over the insulator 554 and overlaps with part of the oxide 530b, and an insulator 544 provided over the insulator 522, the insulator 524, the oxide 530a, the oxide 530b, the conductor 542a, the conductor 542b, the insulator 571a, and insulator 571b. Here, as illustrated in FIG. 14A and FIG. 14B, the insulator 552 is in contact with the top surface of the insulator 522, a side surface of the insulator 524, a side surface of the oxide 530a, a side surface and the top surface of the oxide 530b, a side surface of the conductor 542, a side surface of the insulator 571, a side surface of the insulator 544, a side surface of an insulator 580, and the bottom surface of the insulator 550. The top surface of the conductor 560 is placed to be substantially level with the upper portion of the insulator 554, the upper portion of the insulator 550, the upper portion of the insulator 552, and the top surface of the insulator 580. An insulator 574 is in contact with part of at least one of the top surface of the conductor 560, the upper portion of the insulator 552, the upper portion of the insulator 550, the upper portion of the insulator 554, and the top surface of the insulator 580. Note that the conductor 542a and the conductor 542b are collectively referred to as the conductor 542, and the insulator 571a and the insulator 571b are collectively referred to as the insulator 571.

An opening reaching the oxide 530b is provided in the insulator 580 and the insulator 544. The insulator 552, the insulator 550, the insulator 554, and the conductor 560 are provided in the opening. The conductor 560, the insulator 552, the insulator 550, and the insulator 554 are provided between the conductor 542a and the conductor 542b and between the insulator 571a and the insulator 571b in the channel length direction of the transistor 500. The insulator 554 includes a region in contact with a side surface of the conductor 560 and a region in contact with the bottom surface of the conductor 560.

The oxide 530 preferably includes the oxide 530a provided over the insulator 524 and the oxide 530b provided over the oxide 530a. Including the oxide 530a under the oxide 530b makes it possible to inhibit diffusion of impurities into the oxide 530b from components formed below the oxide 530a.

Although a structure in which two layers, the oxide 530a and the oxide 530b, are stacked as the oxide 530 in the transistor 500 is described, the present invention is not limited thereto. For example, the transistor 500 can include a single-layer structure of the oxide 530b or a stacked-layer structure of three or more layers. Alternatively, the oxide 530a and the oxide 530b can each have a stacked-layer structure.

The conductor 560 functions as a first gate (also referred to as a top gate) electrode, and the conductor 503 functions as a second gate (also referred to as a back gate) electrode. The insulator 552, the insulator 550, and the insulator 554 function as a first gate insulator, and the insulator 522 and the insulator 524 function as a second gate insulator. Note that the gate insulator is also referred to as a gate insulating layer or a gate insulating film in some cases. The conductor 542a functions as one of a source and a drain, and the conductor 542b functions as the other of the source and the drain. At least part of a region of the oxide 530 that overlaps with the conductor 560 functions as a channel formation region.

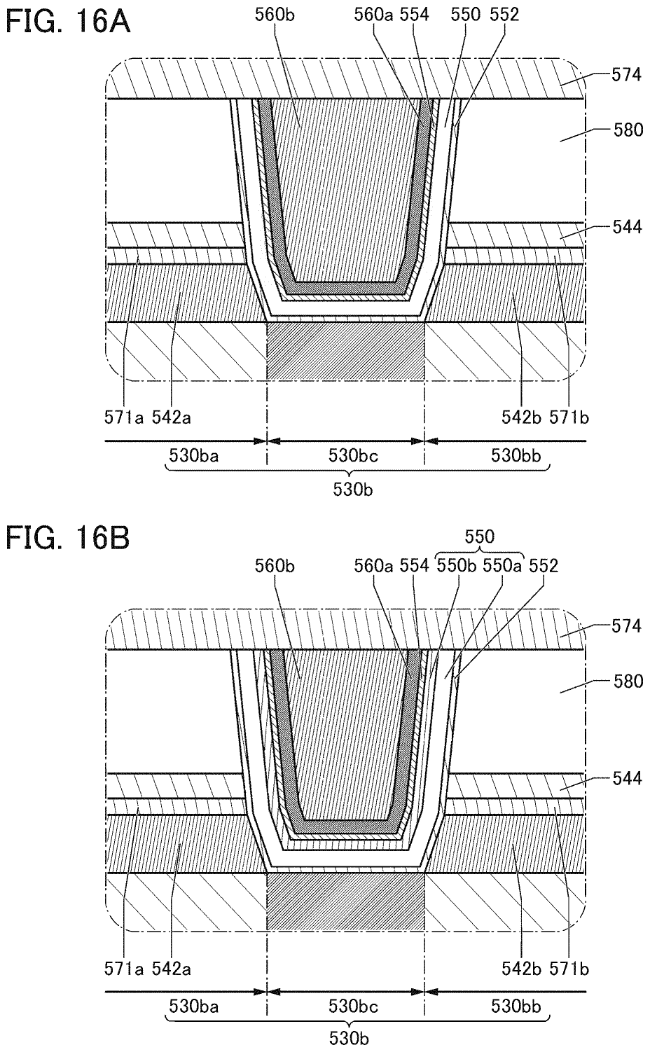

Here, FIG. 16A is an enlarged view of the vicinity of the channel formation region in FIG. 14A. Supply of oxygen to the oxide 530b forms the channel formation region in a region between the conductor 542a and the conductor 542b. As illustrated in FIG. 16A, the oxide 530b includes a region 530bc functioning as the channel formation region of the transistor 500 and a region 530ba and a region 530bb that are provided to sandwich the region 530bc and function as a source region and a drain region. At least part of the region 530bc overlaps with the conductor 560. In other words, the region 530bc is provided between the conductor 542a and the conductor 542b. The region 530ba is provided to overlap with the conductor 542a, and the region 530bb is provided to overlap with the conductor 542b.

The region 530bc functioning as the channel formation region has a smaller amount of oxygen vacancies (an oxygen vacancy in a metal oxide is sometimes referred to as V_{O} in this specification and the like) or a lower impurity concentration than the region 530ba and the region 530bb to be a high-resistance region having a low carrier concentration. Thus, the region 530bc can be regarded as being i-type (intrinsic) or substantially i-type.

A transistor using a metal oxide is likely to change its electrical characteristics when impurities or oxygen vacancies (V_{O}) exist in a region of the metal oxide where a channel is formed, which might degrade the reliability. In some cases, hydrogen in the vicinity of an oxygen vacancy (V_{O}) forms a defect that is an oxygen vacancy (V_{O}) into which hydrogen enters (hereinafter, sometimes referred to as V_{O}H), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and V_{O}H are preferably reduced as much as possible in the region of the oxide semiconductor where a channel is formed.

The region 530ba and the region 530bb functioning as the source region and the drain region are each a low-resistance region with an increased carrier concentration because they include a large amount of oxygen vacancies (V_{O}) or have a high concentration of an impurity such as hydrogen, nitrogen, or a metal element. In other words, the region 530ba and the region 530bb are each an n-type region having a higher carrier concentration and a lower resistance than the region 530bc.

The carrier concentration in the region 530bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration in the region 530bc functioning as the channel formation region is not particularly limited and can be, for example, 1×10⁹ cm⁻³.

Between the region 530bc and the region 530ba or the region 530bb, a region having a carrier concentration that is lower than or substantially equal to the carrier concentrations in the region 530ba and the region 530bb and higher than or substantially equal to the carrier concentration in the region 530bc may be formed. That is, the region functions as a junction region between the region 530bc and the region 530ba or the region 530bb. The hydrogen concentration in the junction region is lower than or substantially equal to the hydrogen concentrations in the region 530ba and the region 530bb and higher than or substantially equal to the hydrogen concentration in the region 530bc in some cases. The amount of oxygen vacancies in the junction region is smaller than or substantially equal to the amounts of oxygen vacancies in the region 530ba and the region 530bb and larger than or substantially equal to the amount of oxygen vacancies in the region 530bc in some cases.

Although FIG. 16A illustrates an example in which the region 530ba, the region 530bb, and the region 530bc are formed in the oxide 530b, the present invention is not limited thereto. For example, the above regions may be formed not only in the oxide 530b but also in the oxide 530a.

In the oxide 530, the boundaries between the regions are difficult to detect clearly in some cases. The concentration of a metal element and an impurity element such as hydrogen or nitrogen, which is detected in each region, may be gradually changed not only between the regions but also in each region. That is, the region closer to the channel formation region preferably has a lower concentration of a metal element and an impurity element such as hydrogen or nitrogen.

In the transistor 500, a metal oxide functioning as a semiconductor (such a metal oxide is hereinafter also referred to as an oxide semiconductor) is preferably used for the oxide 530 (the oxide 530a and the oxide 530b) including the channel formation region.

The metal oxide functioning as a semiconductor preferably has a band gap of 2 eV or more, further preferably 2.5 eV or more. With the use of a metal oxide having such a wide band gap, the off-state current of the transistor can be reduced.

As the oxide 530, it is preferable to use, for example, a metal oxide such as an In-M-Zn oxide containing indium, the element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like). Alternatively, an In—Ga oxide, an In—Zn oxide, or an indium oxide may be used as the oxide 530.

Here, the atomic ratio of In to the element Min the metal oxide used as the oxide 530b is preferably greater than the atomic ratio of In to the element M in the metal oxide used as the oxide 530a.

The oxide 530a is provided under the oxide 530b in the above manner, whereby impurities and oxygen can be inhibited from diffusing into the oxide 530b from components formed below the oxide 530a.

When the oxide 530a and the oxide 530b contain a common element (as the main component) besides oxygen, the density of defect states at an interface between the oxide 530a and the oxide 530b can be made low. Since the density of defect states at the interface between the oxide 530a and the oxide 530b can be made low, the influence of interface scattering on carrier conduction is small, and a high on-state current can be obtained.

The oxide 530b preferably has crystallinity. It is particularly preferable to use a CAAC-OS (c-axis aligned crystalline oxide semiconductor) as the oxide 530b.

The CAAC-OS is a metal oxide having a dense structure with high crystallinity and small amounts of impurities and defects (e.g., oxygen vacancies (V_{O})). In particular, after the formation of a metal oxide, heat treatment is performed at a temperature at which the metal oxide does not become a polycrystal (e.g., 400° C. to 600° C., inclusive), whereby a CAAC-OS having a dense structure with higher crystallinity can be obtained. When the density of the CAAC-OS is increased in such a manner, diffusion of impurities or oxygen in the CAAC-OS can be further reduced.

On the other hand, a clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

If impurities and oxygen vacancies exist in a region of an oxide semiconductor where a channel is formed, a transistor using the oxide semiconductor might have variable electrical characteristics and poor reliability. In some cases, hydrogen in the vicinity of an oxygen vacancy forms a defect that is the oxygen vacancy into which hydrogen enters (hereinafter, sometimes referred to as V_{O}H), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and V_{O}H are preferably reduced as much as possible in the region of the oxide semiconductor where a channel is formed. In other words, it is preferable that the region of the oxide semiconductor where a channel is formed have a reduced carrier concentration and be of an i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 500. Furthermore, a variation in the amount of oxygen supplied to the source region or the drain region in the substrate plane leads to a variation in characteristics of the semiconductor device including the transistor.

Therefore, the region 530bc functioning as the channel formation region in the oxide semiconductor is preferably an i-type or substantially i-type region with a reduced carrier concentration, whereas the region 530ba and the region 530bb functioning as the source region and the drain region are preferably n-type regions with high carrier concentrations. That is, it is preferable that oxygen vacancies and V_{O}H in the region 530bc of the oxide semiconductor be reduced and the region 530ba and the region 530bb not be supplied with an excess amount of oxygen.

Thus, in this embodiment, microwave treatment is performed in an oxygen-containing atmosphere in a state where the conductor 542a and the conductor 542b are provided over the oxide 530b so that oxygen vacancies and V_{O}H in the region 530bc can be reduced. Here, the microwave treatment refers to, for example, treatment using an apparatus including a power source that generates high-density plasma with the use of a microwave.

The microwave treatment in an oxygen-containing atmosphere converts an oxygen gas into plasma using a high-frequency wave such as a microwave or RF and activates the oxygen plasma. At this time, the region 530bc can be irradiated with the high-frequency wave such as a microwave or RF. By the effect of the plasma, a microwave, or the like, V_{O}H in the region 530bc can be cut; thus, hydrogen H can be removed from the region 530bc and an oxygen vacancy V_{O} can be filled with oxygen. That is, the reaction “V_{O}H→H+V_{O}” occurs in the region 530bc, so that the hydrogen concentration in the region 530bc can be reduced. As a result, oxygen vacancies and V_{O}H in the region 530bc can be reduced to lower the carrier concentration.

In the microwave treatment in an oxygen-containing atmosphere, the high-frequency wave such as the microwave or RF, the oxygen plasma, or the like is blocked by the conductor 542a and the conductor 542b and does not affect the region 530ba nor the region 530bb. In addition, the effect of the oxygen plasma can be reduced by the insulator 571 and the insulator 580 that are provided to cover the oxide 530b and the conductor 542. Hence, a reduction in V_{O}H and supply of an excess amount of oxygen do not occur in the region 530ba and the region 530bb in the microwave treatment, preventing a decrease in carrier concentration.

Microwave treatment is preferably performed in an oxygen-containing atmosphere after formation of an insulating film to be the insulator 552 or after formation of an insulating film to be the insulator 550. By performing the microwave treatment in an oxygen-containing atmosphere through the insulator 552 or the insulator 550 in such a manner, oxygen can be efficiently supplied into the region 530bc. In addition, the insulator 552 is provided to be in contact with the side surface of the conductor 542 and the surface of the region 530bc, thereby preventing oxygen more than necessary from being supplied to the region 530bc and preventing the side surface of the conductor 542 from being oxidized. Furthermore, the side surface of the conductor 542 can be inhibited from being oxidized when an insulating film to be the insulator 550 is formed.

The oxygen supplied into the region 530bc has any of a variety of forms such as an oxygen atom, an oxygen molecule, and an oxygen radical (an O radical, an atom or a molecule having an unpaired electron, or an ion). Note that the oxygen supplied into the region 530bc preferably has any one or more of the above forms, and is particularly preferably an oxygen radical. Furthermore, the film quality of the insulator 552 and the insulator 550 can be improved, leading to higher reliability of the transistor 500.

In the above manner, oxygen vacancies and V_{O}H can be selectively removed from the region 530bc in the oxide semiconductor, whereby the region 530bc can be an i-type or substantially i-type region. Furthermore, supply of an excess amount of oxygen to the region 530ba and the region 530bb functioning as the source region and the drain region can be inhibited and the conductivity can be maintained. As a result, a change in the electrical characteristics of the transistor 500 can be inhibited, and thus a variation in the electrical characteristics of the transistors 500 in the substrate plane can be reduced.

With the above structure, a semiconductor device with a small variation in transistor characteristics can be provided. A semiconductor device with favorable reliability can also be provided. A semiconductor device having favorable electrical characteristics can be provided.

As illustrated in FIG. 14B, a curved surface may be provided between the side surface of the oxide 530b and the top surface of the oxide 530b in a cross-sectional view of the transistor 500 in the channel width direction. In other words, an end portion of the side surface and an end portion of the top surface may be curved (hereinafter, also referred to as rounded).

The radius of curvature of the curved surface is preferably greater than 0 nm and less than the thickness of the oxide 530b in a region overlapping with the conductor 542, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 530b with the insulator 552, the insulator 550, the insulator 554, and the conductor 560.

The oxide 530 preferably has a stacked-layer structure of a plurality of oxide layers with different chemical compositions. Specifically, the atomic ratio of the element M to a metal element that is a main component of the metal oxide used as the oxide 530a is preferably greater than the atomic ratio of the element M to a metal element that is a main component of the metal oxide used as the oxide 530b. Moreover, the atomic ratio of the element M to In in the metal oxide used as the oxide 530a is preferably greater than the atomic ratio of the element M to In in the metal oxide used as the oxide 530b. Furthermore, the atomic ratio of In to the element Min the metal oxide used as the oxide 530b is preferably greater than the atomic ratio of In to the element M in the metal oxide used as the oxide 530a.

The oxide 530b is preferably an oxide having crystallinity, such as a CAAC-OS. An oxide having crystallinity, such as a CAAC-OS, has a dense structure with small amounts of impurities and defects (e.g., oxygen vacancies) and high crystallinity. This can inhibit oxygen extraction from the oxide 530b by the source electrode or the drain electrode. This can reduce oxygen extraction from the oxide 530b even when heat treatment is performed; thus, the transistor 500 is stable with respect to high temperatures in a manufacturing process (what is called thermal budget).

Here, the conduction band minimum gradually changes at a junction portion of the oxide 530a and the oxide 530b. In other words, the conduction band minimum at the junction portion of the oxide 530a and the oxide 530b continuously changes or is continuously connected. To achieve this, the density of defect states in a mixed layer formed at the interface between the oxide 530a and the oxide 530b is preferably made low.

Specifically, when the oxide 530a and the oxide 530b contain a common element as a main component besides oxygen, a mixed layer with a low density of defect states can be formed. For example, in the case where the oxide 530b is an In-M-Zn oxide, an In-M-Zn oxide, an M-Zn oxide, an oxide of the element M, an In—Zn oxide, an indium oxide, or the like may be used as the oxide 530a.

Specifically, as the oxide 530a, a metal oxide with a composition of In:M:Zn=1:3:4 [atomic ratio] or in the neighborhood thereof, or a composition of In:M:Zn=1:1:0.5 [atomic ratio] or in the neighborhood thereof is used. As the oxide 530b, a metal oxide with a composition of In:M:Zn=1:1:1 [atomic ratio] or in the neighborhood thereof, or a composition of In:M:Zn=4:2:3 [atomic ratio] or in the neighborhood thereof is used. Note that a composition in the neighborhood includes the range of ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

As illustrated in FIG. 14B or the like, the insulator 552 formed using aluminum oxide or the like is provided in contact with the top and side surfaces of the oxide 530, whereby indium contained in the oxide 530 is unevenly distributed, in some cases, at the interface between the oxide 530 and the insulator 552 and in its vicinity. Accordingly, the vicinity of the surface of the oxide 530 comes to have an atomic ratio close to that of an indium oxide or that of an In—Zn oxide. Such an increase in the atomic ratio of indium in the vicinity of the surface of the oxide 530, especially the vicinity of the surface of the oxide 530b, can increase the field-effect mobility of the transistor 500.

When the oxide 530a and the oxide 530b have the above structure, the density of defect states at the interface between the oxide 530a and the oxide 530b can be made low. Thus, the influence of interface scattering on carrier conduction is small, and the transistor 500 can have a high on-state current and excellent frequency characteristics.

At least one of the insulator 512, the insulator 514, the insulator 544, the insulator 571, the insulator 574, an insulator 576, and an insulator 581 preferably functions as a barrier insulating film, which inhibits diffusion of impurities such as water or hydrogen from the substrate side or above the transistor 500 into the transistor 500. Thus, for at least one of the insulator 512, the insulator 514, the insulator 544, the insulator 571, the insulator 574, the insulator 576, and the insulator 581, it is preferable to use an insulating material having a function of inhibiting diffusion of impurities such as hydrogen atoms, hydrogen molecules, water molecules, nitrogen atoms, nitrogen molecules, nitrogen oxide molecules (e.g., N₂O, NO, or NO₂), or copper atoms (an insulating material through which the impurities are less likely to pass). Alternatively, it is preferable to use an insulating material having a function of inhibiting diffusion of oxygen (e.g., at least one of oxygen atoms, oxygen molecules, and the like) (an insulating material through which the oxygen is less likely to pass).

Note that in this specification, a barrier insulating film refers to an insulating film having a barrier property. A barrier property in this specification means a function of inhibiting diffusion of a targeted substance (also referred to as having low permeability). In addition, a barrier property in this specification means a function of capturing and fixing (also referred to as gettering) a targeted substance.

An insulator having a function of inhibiting diffusion of oxygen and impurities such as water or hydrogen is preferably used as the insulator 512, the insulator 514, the insulator 544, the insulator 571, the insulator 574, the insulator 576, and the insulator 581; for example, aluminum oxide, magnesium oxide, hafnium oxide, gallium oxide, indium gallium zinc oxide, silicon nitride, or silicon nitride oxide can be used. For example, silicon nitride, which has a higher hydrogen barrier property, is preferably used for the insulator 512, the insulator 544, and the insulator 576. For example, aluminum oxide or magnesium oxide, which has a function of capturing or fixing hydrogen well, is preferably used for the insulator 514, the insulator 571, the insulator 574, and the insulator 581. In this case, impurities such as water or hydrogen can be inhibited from diffusing to the transistor 500 side from the substrate side through the insulator 512 and the insulator 514. Impurities such as water or hydrogen can be inhibited from diffusing to the transistor 500 side from an interlayer insulating film and the like which are provided outside the insulator 581. Alternatively, oxygen contained in the insulator 524 and the like can be inhibited from diffusing to the substrate side through the insulator 512 and the insulator 514. Alternatively, oxygen contained in the insulator 580 and the like can be inhibited from diffusing to above the transistor 500 through the insulator 574 and the like. In this manner, it is preferable that the transistor 500 be surrounded by the insulator 512, the insulator 514, the insulator 571, the insulator 544, the insulator 574, the insulator 576, and the insulator 581, which have a function of inhibiting diffusion of oxygen and impurities such as water or hydrogen.

Here, an oxide having an amorphous structure is preferably used for the insulator 512, the insulator 514, the insulator 544, the insulator 571, the insulator 574, the insulator 576, and the insulator 581. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 500 or provided around the transistor 500, hydrogen contained in the transistor 500 or hydrogen present around the transistor 500 can be captured or fixed. In particular, hydrogen contained in the channel formation region of the transistor 500 is preferably captured or fixed. The metal oxide having an amorphous structure is used as the component of the transistor 500 or provided around the transistor 500, whereby the transistor 500 and a semiconductor device, which have favorable characteristics and high reliability, can be manufactured.

Although each of the insulator 512, the insulator 514, the insulator 544, the insulator 571, the insulator 574, the insulator 576, and the insulator 581 preferably has an amorphous structure, a region having a polycrystalline structure may be partly formed. Alternatively, each of the insulator 512, the insulator 514, the insulator 544, the insulator 571, the insulator 574, the insulator 576, and the insulator 581 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 512, the insulator 514, the insulator 544, the insulator 571, the insulator 574, the insulator 576, and the insulator 581 can be deposited by a sputtering method, for example. Since a sputtering method does not need to use a molecule containing hydrogen as a deposition gas, the hydrogen concentrations in the insulator 512, the insulator 514, the insulator 544, the insulator 571, the insulator 574, the insulator 576, and the insulator 581 can be reduced. Note that the deposition method is not limited to a sputtering method, and a CVD method, a molecular beam epitaxy (MBE) method, a pulsed laser deposition (PLD) method, an ALD method, or the like may be used as appropriate.

The resistivities of the insulator 512, the insulator 544, and the insulator 576 are preferably low in some cases. For example, by setting the resistivities of the insulator 512, the insulator 544, and the insulator 576 to approximately 1×10¹³ Ωcm, the insulator 512, the insulator 544, and the insulator 576 can sometimes reduce charge up of the conductor 503, the conductor 542, the conductor 560, or the like in treatment using plasma or the like in the manufacturing process of a semiconductor device. The resistivities of the insulator 512, the insulator 544, and the insulator 576 are preferably higher than or equal to 1×10¹⁰ Ωcm and lower than or equal to 1×10¹⁵ Ωcm.

The insulator 516, the insulator 574, the insulator 580, and the insulator 581 each preferably have a lower permittivity than the insulator 514. When a material with a low permittivity is used for an interlayer film, parasitic capacitance generated between wirings can be reduced. For the insulator 516, the insulator 580, and the insulator 581, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The insulator 581 is preferably an insulator functioning as an interlayer film, a planarization film, or the like, for example.

The conductor 503 is provided to overlap with the oxide 530 and the conductor 560. Here, the conductor 503 is preferably provided to be embedded in an opening formed in the insulator 516. Part of the conductor 503 is embedded in the insulator 514 in some cases.

The conductor 503 includes the conductor 503a and the conductor 503b. The conductor 503a is provided in contact with a bottom surface and a sidewall of the opening. The conductor 503b is provided to be embedded in a recessed portion formed in the conductor 503a. Here, the upper portion of the conductor 503b is substantially level with the upper portion of the conductor 503a and the upper portion of the insulator 516.

Here, for the conductor 503a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom. Alternatively, it is preferable to use a conductive material having a function of inhibiting diffusion of oxygen (e.g., at least one of an oxygen atom, an oxygen molecule, and the like).

When the conductor 503a is formed using a conductive material having a function of inhibiting diffusion of hydrogen, impurities such as hydrogen contained in the conductor 503b can be prevented from diffusing into the oxide 530 through the insulator 524 and the like. When the conductor 503a is formed using a conductive material having a function of inhibiting diffusion of oxygen, the conductivity of the conductor 503b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, a single layer or a stacked layer of the above conductive material is used as the conductor 503a. For example, titanium nitride is used for the conductor 503a.

Moreover, the conductor 503b is preferably formed using a conductive material containing tungsten, copper, or aluminum as its main component. For example, tungsten is used for the conductor 503b.

The conductor 503 sometimes functions as a second gate electrode. In that case, by changing a potential applied to the conductor 503 not in conjunction with but independently of a potential applied to the conductor 560, the threshold voltage (Vth) of the transistor 500 can be controlled. In particular, Vth of the transistor 500 can be higher in the case where a negative potential is applied to the conductor 503 than in the case where the negative potential is not applied to the conductor 503, and the off-state current can be reduced. Thus, drain current at the time when a potential applied to the conductor 560 is 0 V can be lower in the case where a negative potential is applied to the conductor 503 than in the case where the negative potential is not applied to the conductor 503.

In the case where the oxide 530 is a highly purified intrinsic oxide and as many impurities as possible are eliminated from the oxide 530, the transistor 500 can be expected to become normally-off (the threshold voltage of the transistor 500 can be expected to higher than 0 V) in some cases with no potential application to the conductor 503 and/or the conductor 560. In that case, it is suitable to connect the conductor 560 and the conductor 503 to each other such that the same potential is supplied.

The electric resistivity of the conductor 503 is designed in consideration of the potential applied to the conductor 503, and the thickness of the conductor 503 is determined in accordance with the electric resistivity. The thickness of the insulator 516 is substantially equal to that of the conductor 503. The conductor 503 and the insulator 516 are preferably as thin as possible in the allowable range of the design of the conductor 503. When the thickness of the insulator 516 is reduced, the absolute amount of impurities such as hydrogen contained in the insulator 516 can be reduced, inhibiting the diffusion of the impurities into the oxide 530.

When seen from above, the conductor 503 is preferably provided to be larger than a region of the oxide 530 that does not overlap with the conductor 542a or the conductor 542b. As illustrated in FIG. 14B, it is particularly preferable that the conductor 503 extend to a region outside end portions of the oxide 530a and the oxide 530b in the channel width direction. That is, the conductor 503 and the conductor 560 preferably overlap with each other with the insulators therebetween on the outer side of the side surface of the oxide 530 in the channel width direction. With this structure, the channel formation region of the oxide 530 can be electrically surrounded by the electric field of the conductor 560 functioning as a first gate electrode and the electric field of the conductor 503 functioning as the second gate electrode. In this specification, a transistor structure in which a channel formation region is electrically surrounded by electric fields of a first gate and a second gate is referred to as a surrounded channel (s-channel) structure.

In this specification and the like, a transistor having the s-channel structure refers to a transistor having a structure in which a channel formation region is electrically surrounded by the electric fields of a pair of gate electrodes. The s-channel structure disclosed in this specification and the like is different from a Fin-type structure and a planar structure. With the s-channel structure, resistance to a short-channel effect can be enhanced, that is, a transistor in which a short-channel effect is less likely to occur can be provided.

When the transistor 500 becomes normally-off and has the above-described S-Channel structure, the channel formation region can be electrically surrounded. Accordingly, the transistor 500 can be regarded as having a GAA (Gate All Around) structure or an LGAA (Lateral Gate All Around) structure. When the transistor 500 has the S-Channel structure, the GAA structure, or the LGAA structure, the channel formation region that is formed at the interface between the oxide 530 and the gate insulating film or in the vicinity of the interface can be formed in the entire bulk of the oxide 530. In other words, the transistor 500 having the S-Channel structure, the GAA structure, or the LGAA structure can be what is called a Bulk-Flow type, in which a carrier path is used as the entire bulk. A transistor structure with a Bulk-Flow type can improve the density of current flowing in the transistor and thus can be expected to improve the on-state current of the transistor or increase the field-effect mobility of the transistor.

Furthermore, as illustrated in FIG. 14B, the conductor 503 is extended to function as a wiring as well. However, without limitation to this structure, a structure in which a conductor functioning as a wiring is provided below the conductor 503 may be employed. In addition, the conductor 503 is not necessarily provided in each transistor. For example, the conductor 503 may be shared by a plurality of transistors.

Although the transistor 500 having a structure in which the conductor 503 is a stack of the conductor 503a and the conductor 503b is illustrated, the present invention is not limited thereto. For example, the conductor 503 may be provided to have a single-layer structure or a stacked-layer structure of three or more layers.

The insulator 522 and the insulator 524 function as a gate insulator.

It is preferable that the insulator 522 have a function of inhibiting diffusion of hydrogen (e.g., at least one of a hydrogen atom, a hydrogen molecule, and the like). In addition, it is preferable that the insulator 522 have a function of inhibiting diffusion of oxygen (e.g., at least one of an oxygen atom, an oxygen molecule, and the like). For example, the insulator 522 preferably has a function of inhibiting diffusion of one or both of hydrogen and oxygen more than the insulator 524.

As the insulator 522, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. In the case where the insulator 522 is formed using such a material, the insulator 522 functions as a layer that inhibits release of oxygen from the oxide 530 to the substrate side and diffusion of impurities such as hydrogen from the periphery of the transistor 500 into the oxide 530. Thus, providing the insulator 522 can inhibit diffusion of impurities such as hydrogen into the transistor 500 and inhibit generation of oxygen vacancies in the oxide 530. Moreover, the conductor 503 can be inhibited from reacting with oxygen contained in the insulator 524 or the oxide 530.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over these insulators may be used for the insulator 522.

For example, a single layer or stacked layers of an insulator containing what is called a high-k material such as aluminum oxide, hafnium oxide, tantalum oxide, or zirconium oxide may be used for the insulator 522. As miniaturization and high integration of transistors progress, a problem such as leakage current may arise because of a thinner gate insulator. When a high-k material is used for an insulator functioning as the gate insulator, a gate potential at the time when the transistor operates can be reduced while the physical thickness is maintained. Furthermore, a substance with a high permittivity such as lead zirconate titanate (PZT), strontium titanate (SrTiO₃), or (Ba,Sr)TiO₃ (BST) may be used for the insulator 522.

Silicon oxide or silicon oxynitride, for example, can be used as appropriate for the insulator 524 that is in contact with the oxide 530.

In a manufacturing process of the transistor 500, heat treatment is preferably performed with a surface of the oxide 530 exposed. For example, the heat treatment is performed at a temperature higher than or equal to 100° C. and lower than or equal to 600° C., preferably higher than or equal to 350° C. and lower than or equal to 550° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the oxide 530 to reduce oxygen vacancies (V_{O}). The heat treatment may be performed under reduced pressure. Alternatively, the heat treatment may be performed in an atmosphere containing an oxidizing gas at 10 ppm or more, 1% or more, or 10% or more in order to compensate for released oxygen, after heat treatment in a nitrogen gas or inert gas atmosphere. Alternatively, the heat treatment may be performed in a nitrogen gas or inert gas atmosphere successively after heat treatment is performed in an atmosphere containing an oxidizing gas at 10 ppm or more, 1% or more, or 10% or more.

Note that oxygen adding treatment performed on the oxide 530 can promote a reaction in which oxygen vacancies in the oxide 530 are repaired with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

Note that the insulator 522 and the insulator 524 may each have a stacked-layer structure of two or more layers. In that case, without limitation to a stacked-layer structure formed of the same material, a stacked-layer structure formed of different materials may be employed. The insulator 524 may be formed into an island shape so as to overlap with the oxide 530a. In this case, the insulator 544 is in contact with the side surface of the insulator 524 and the top surface of the insulator 522.

The conductor 542a and the conductor 542b are provided in contact with the top surface of the oxide 530b. The conductor 542a and the conductor 542b function as a source electrode and a drain electrode of the transistor 500.

For the conductor 542 (the conductor 542a and the conductor 542b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. For another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 530b or the like diffuses into the conductor 542a or the conductor 542b in some cases. In particular, when a nitride containing tantalum is used for the conductor 542a and the conductor 542b, hydrogen contained in the oxide 530b or the like is likely to diffuse into the conductor 542a or the conductor 542b, and the diffused hydrogen is bonded to nitrogen contained in the conductor 542a or the conductor 542b in some cases. That is, hydrogen contained in the oxide 530b or the like is absorbed by the conductor 542a or the conductor 542b in some cases.

No curved surface is preferably formed between the side surface of the conductor 542 and the top surface of the conductor 542. When no curved surface is formed in the conductor 542, the conductor 542 can have a large cross-sectional area in the channel width direction. Accordingly, the conductivity of the conductor 542 is increased, so that the on-state current of the transistor 500 can be increased.

The insulator 571a is provided in contact with the top surface of the conductor 542a, and the insulator 571b is provided in contact with the top surface of the conductor 542b. The insulator 571 preferably functions as at least a barrier insulating film against oxygen. Thus, the insulator 571 preferably has a function of inhibiting oxygen diffusion. For example, the insulator 571 preferably has a function of inhibiting diffusion of oxygen more than the insulator 580. For example, a nitride containing silicon such as silicon nitride may be used for the insulator 571. The insulator 571 preferably has a function of capturing impurities such as hydrogen. In that case, for the insulator 571, a metal oxide having an amorphous structure, for example, an insulator such as aluminum oxide or magnesium oxide, may be used. It is particularly preferable to use aluminum oxide having an amorphous structure or amorphous aluminum oxide for the insulator 571 because hydrogen can be captured or fixed more effectively in some cases. Accordingly, the transistor 500 and a semiconductor device, which have favorable characteristics and high reliability, can be manufactured.

The insulator 544 is provided to cover the insulator 524, the oxide 530a, the oxide 530b, the conductor 542, and the insulator 571. The insulator 544 preferably has a function of capturing and fixing hydrogen. In that case, the insulator 544 preferably includes silicon nitride, or a metal oxide having an amorphous structure, for example, an insulator such as aluminum oxide or magnesium oxide. Alternatively, for example, a stacked-layer film of aluminum oxide and silicon nitride over the aluminum oxide may be used as the insulator 544.

When the above insulator 571 and the insulator 544 are provided, the conductor 542 can be surrounded by the insulators having a barrier property against oxygen. That is, oxygen contained in the insulator 524 and the insulator 580 can be prevented from diffusing into the conductor 542. As a result, the conductor 542 can be inhibited from being directly oxidized by oxygen contained in the insulator 524 and the insulator 580, so that an increase in resistivity and a reduction in on-state current can be inhibited.

The insulator 552 functions as part of the gate insulator. As the insulator 552, a barrier insulating film against oxygen is preferably used. As the insulator 552, an insulator that can be used as the insulator 574 described above may be used. An insulator containing an oxide of one or both of aluminum and hafnium is preferably used as the insulator 552. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used for the insulator 552. In this case, the insulator 552 is an insulator containing at least oxygen and aluminum.

As illustrated in FIG. 14B, the insulator 552 is provided in contact with the top surface and the side surface of the oxide 530b, the side surface of the oxide 530a, the side surface of the insulator 524, and the top surface of the insulator 522. That is, the regions of the oxide 530a, the oxide 530b, and the insulator 524 that overlap with the conductor 560 are covered with the insulator 552 in the cross section in the channel width direction. With this structure, the insulator 552 having a barrier property against oxygen can prevent release of oxygen from the oxide 530a and the oxide 530b at the time of heat treatment or the like. This can inhibit formation of oxygen vacancies (Vₒ) in the oxide 530a and the oxide 530b. Therefore, oxygen vacancies (Vₒ) and V_{O}H formed in the region 530bc illustrated in FIG. 16A can be reduced. Thus, the transistor 500 can have favorable electrical characteristics and higher reliability.

Even when an excess amount of oxygen is contained in the insulator 580, the insulator 550, and the like, oxygen can be inhibited from being excessively supplied to the oxide 530a and the oxide 530b. Thus, the region 530ba and the region 530bb are prevented from being excessively oxidized by oxygen through the region 530bc illustrated in FIG. 16A; a reduction in on-state current or field-effect mobility of the transistor 500 can be inhibited.

As illustrated in FIG. 14A, the insulator 552 is provided in contact with the side surfaces of the conductor 542, the insulator 571, the insulator 544, and the insulator 580. This can inhibit formation of an oxide film on the side surface of the conductor 542 by oxidization of the side surface. Accordingly, a reduction in on-state current or field-effect mobility of the transistor 500 can be inhibited.

Furthermore, the insulator 552 needs to be provided in an opening formed in the insulator 580 and the like, together with the insulator 554, the insulator 550, and the conductor 560. The thickness of the insulator 552 is preferably small for miniaturization of the transistor 500. The thickness of the insulator 552 is preferably greater than or equal to 0.1 nm, greater than or equal to 0.5 nm, or greater than or equal to 1.0 nm, and less than or equal to 1.0 nm, less than or equal to 3.0 nm, or less than or equal to 5.0 nm. Note that the above-described lower limits and upper limits can be combined with each other. In that case, at least part of the insulator 552 includes a region having the above-described thickness. The thickness of the insulator 552 is preferably smaller than that of the insulator 550. In that case, at least part of the insulator 552 includes a region having a thickness smaller than that of the insulator 550.

To form the insulator 552 having a small thickness as described above, an ALD method is preferably used for deposition. Examples of an ALD method include a thermal ALD method, in which a precursor and a reactant react with each other only by thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one using self-limiting characteristics of atoms, has advantages such as deposition of an extremely thin film, deposition on a component with a high aspect ratio, deposition of a film with a small number of defects such as pinholes, deposition with excellent coverage, and low-temperature deposition. Therefore, the insulator 552 can be formed on a side surface of the opening formed in the insulator 580 and the like to have a small thickness as described above and to have favorable coverage.

Note that some of precursors usable in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS) or X-ray photoelectron spectroscopy (XPS).

The insulator 550 functions as part of the gate insulator. The insulator 550 is preferably provided in contact with the top surface of the insulator 552. The insulator 550 can be formed using silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like. In particular, silicon oxide and silicon oxynitride, which have thermal stability, are preferable. The insulator 550 in this case is an insulator containing at least oxygen and silicon.

As in the insulator 524, the concentration of impurities such as water or hydrogen in the insulator 550 is preferably reduced. The thickness of the insulator 550 is preferably greater than or equal to 1 nm or greater than or equal to 0.5 nm and less than or equal to 15 nm or less than or equal to 20 nm. Note that the above-described lower limits and upper limits can be combined with each other. In that case, at least part of the insulator 550 includes a region having the above-described thickness.

Although FIG. 14A, FIG. 14B, and the like illustrate a single-layer structure of the insulator 550, the present invention is not limited to this structure, and a stacked-layer structure of two or more layers may be employed. For example, as illustrated in FIG. 16B, the insulator 550 may have a stacked-layer structure including two layers of an insulator 550a and an insulator 550b over the insulator 550a.

In the case where the insulator 550 has a stacked-layer structure of two layers as illustrated in FIG. 16B, it is preferable that the insulator 550a in a lower layer be formed using an insulator that is likely to transmit oxygen and the insulator 550b in an upper layer be formed using an insulator having a function of inhibiting oxygen diffusion. With such a structure, oxygen contained in the insulator 550a can be inhibited from diffusing into the conductor 560. That is, a reduction in the amount of oxygen supplied to the oxide 530 can be inhibited. In addition, oxidation of the conductor 560 due to oxygen contained in the insulator 550a can be inhibited. For example, it is preferable that the insulator 550a be provided using any of the above-described materials that can be used for the insulator 550 and the insulator 550b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used as the insulator 550b. In this case, the insulator 550b is an insulator containing at least oxygen and hafnium. The thickness of the insulator 550b is preferably greater than or equal to 0.5 nm or greater than or equal to 1.0 nm, and less than or equal to 3.0 nm or less than or equal to 5.0 nm. Note that the above-described lower limits and upper limits can be combined with each other. In that case, at least part of the insulator 550b includes a region having the above-described thickness.

In the case where silicon oxide, silicon oxynitride, or the like is used for the insulator 550a, the insulator 550b may be formed using an insulating material that is a high-k material having a high dielectric constant. The gate insulator having a stacked-layer structure of the insulator 550a and the insulator 550b can be thermally stable and can have a high dielectric constant. Thus, a gate potential that is applied during the operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 550 can be increased.

The insulator 554 functions as part of the gate insulator. As the insulator 554, a barrier insulating film against hydrogen is preferably used. This can prevent diffusion of impurities such as hydrogen contained in the conductor 560 into the insulator 550 and the oxide 530b. As the insulator 554, an insulator that can be used as the insulator 576 described above may be used. For example, silicon nitride deposited by a PEALD method may be used as the insulator 554. In this case, the insulator 554 is an insulator containing at least nitrogen and silicon.

Furthermore, the insulator 554 may have a barrier property against oxygen. Thus, diffusion of oxygen contained in the insulator 550 into the conductor 560 can be inhibited.

Furthermore, the insulator 554 needs to be provided in an opening formed in the insulator 580 and the like, together with the insulator 552, the insulator 550, and the conductor 560. The thickness of the insulator 554 is preferably small for miniaturization of the transistor 500. The thickness of the insulator 554 is preferably greater than or equal to 0.1 nm, greater than or equal to 0.5 nm, or greater than or equal to 1.0 nm, and less than or equal to 3.0 nm or less than or equal to 5.0 nm. Note that the above-described lower limits and upper limits can be combined with each other. In that case, at least part of the insulator 554 includes a region having the above-described thickness. The thickness of the insulator 554 is preferably smaller than that of the insulator 550. In that case, at least part of the insulator 554 includes a region having a thickness smaller than that of the insulator 550.

The conductor 560 functions as the first gate electrode of the transistor 500. The conductor 560 preferably includes the conductor 560a and the conductor 560b provided over the conductor 560a. For example, the conductor 560a is preferably provided to cover the bottom surface and the side surface of the conductor 560b. As illustrated in FIG. 14A and FIG. 14B, the upper portion of the conductor 560 is substantially level with the upper portion of the insulator 550. Note that although the conductor 560 has a two-layer structure of the conductor 560a and the conductor 560b in FIG. 14A and FIG. 14B, the conductor 560 can have, besides the two-layer structure, a single-layer structure or a stacked-layer structure of three or more layers.

For the conductor 560a, a conductive material having a function of inhibiting diffusion of impurities such as a hydrogen atom, a hydrogen molecule, a water molecule, a nitrogen atom, a nitrogen molecule, a nitrogen oxide molecule, or a copper atom is preferably used. Alternatively, it is preferable to use a conductive material having a function of inhibiting diffusion of oxygen (e.g., at least one of an oxygen atom, an oxygen molecule, and the like).

In addition, when the conductor 560a has a function of inhibiting diffusion of oxygen, the conductivity of the conductor 560b can be inhibited from being lowered because of oxidation due to oxygen contained in the insulator 550. As the conductive material having a function of inhibiting diffusion of oxygen, for example, titanium, titanium nitride, tantalum, tantalum nitride, ruthenium, or ruthenium oxide is preferably used.

Furthermore, the conductor 560 also functions as a wiring and thus is preferably a conductor having high conductivity. For example, a conductive material containing tungsten, copper, or aluminum as its main component can be used for the conductor 560b. The conductor 560b can have a stacked-layer structure. Specifically, for example, the conductor 560b can have a stacked-layer structure of titanium or titanium nitride and the above conductive material.

In the transistor 500, the conductor 560 is formed in a self-aligned manner to fill the opening formed in the insulator 580 and the like. The formation of the conductor 560 in this manner allows the conductor 560 to be placed properly in a region between the conductor 542a and the conductor 542b without alignment.

As illustrated in FIG. 14B, in the channel width direction of the transistor 500, with reference to the bottom surface of the insulator 522, the level of the bottom surface of the conductor 560 in a region where the conductor 560 and the oxide 530b do not overlap with each other is preferably lower than the level of the bottom surface of the oxide 530b. When the conductor 560 functioning as the gate electrode covers a side surface and the top surface of the channel formation region of the oxide 530b with the insulator 550 and the like therebetween, the electric field of the conductor 560 can easily act on the entire channel formation region of the oxide 530b. Thus, the on-state current of the transistor 500 can be increased and the frequency characteristics of the transistor 500 can be improved. The difference between the level of the bottom surface of the conductor 560 in a region where the oxide 530a and the oxide 530b do not overlap with the conductor 560 and the level of the bottom surface of the oxide 530b, with reference to the bottom surface of the insulator 522, is preferably greater than or equal to 0 nm, greater than or equal to 3 nm, or greater than or equal to 5 nm, and less than or equal to 20 nm, less than or equal to 50 nm, or less than or equal to 100 nm. Note that the above-described lower limits and upper limits can be combined with each other.

The insulator 580 is provided over the insulator 544, and the opening is formed in a region where the insulator 550 and the conductor 560 are to be provided. In addition, the top surface of the insulator 580 may be planarized.

The insulator 580 functioning as an interlayer film preferably has a low permittivity. When a material with a low permittivity is used for the interlayer film, parasitic capacitance generated between wirings can be reduced. The insulator 580 is preferably provided using a material similar to that for the insulator 516, for example. In particular, silicon oxide and silicon oxynitride, which have thermal stability, are preferable. Materials such as silicon oxide, silicon oxynitride, and porous silicon oxide are particularly preferable because a region containing oxygen to be released by heating can be easily formed.

The concentration of impurities such as water or hydrogen in the insulator 580 is preferably reduced. An oxide containing silicon, such as silicon oxide or silicon oxynitride, is used as appropriate for the insulator 580, for example.

The insulator 574 preferably functions as a barrier insulating film that inhibits impurities such as water or hydrogen from diffusing into the insulator 580 from above and preferably has a function of capturing impurities such as hydrogen. The insulator 574 preferably functions as a barrier insulating film that inhibits passage of oxygen. For the insulator 574, a metal oxide having an amorphous structure, for example, an insulator such as aluminum oxide, can be used. In this case, the insulator 574 is an insulator containing at least oxygen and aluminum. The insulator 574, which has a function of capturing impurities such as hydrogen, is provided in contact with the insulator 580 in a region sandwiched between the insulator 512 and the insulator 581, whereby impurities such as hydrogen contained in the insulator 580, for example, can be captured and the amount of hydrogen in the region can be constant. It is particularly preferable to use aluminum oxide having an amorphous structure for the insulator 574, in which case hydrogen can sometimes be captured or fixed more effectively. Accordingly, the transistor 500 and a semiconductor device, which have favorable characteristics and high reliability, can be manufactured.

The insulator 576 functions as a barrier insulating film that inhibits impurities such as water or hydrogen from diffusing into the insulator 580 from above. The insulator 576 is provided over the insulator 574. The insulator 576 is preferably formed using a nitride containing silicon such as silicon nitride or silicon nitride oxide. For example, silicon nitride deposited by a sputtering method may be used for the insulator 576. When the insulator 576 is deposited by a sputtering method, a high-density silicon nitride film can be formed. To obtain the insulator 576, silicon nitride deposited by a PEALD method or a CVD method may be stacked over silicon nitride deposited by a sputtering method.

One of a first terminal and a second terminal of the transistor 500 is electrically connected to a conductor 540a serving as a plug, and the other of the first terminal and the second terminal of the transistor 500 is electrically connected to a conductor 540b. Note that in this specification and the like, the conductor 540a and the conductor 540b are collectively referred to as the conductor 540.

The conductor 540a is provided in a region overlapping with the conductor 542a, for example. Specifically, an opening portion is formed in the insulator 571, the insulator 544, the insulator 580, the insulator 574, the insulator 576, and the insulator 581 illustrated in FIG. 14A and in an insulator 582 and an insulator 586 illustrated in FIG. 13 in the region overlapping with the conductor 542a, and the conductor 540a is provided inside the opening portion. The conductor 540b is provided in a region overlapping with the conductor 542b, for example. Specifically, an opening portion is formed in the insulator 571, the insulator 544, the insulator 580, the insulator 574, the insulator 576, and the insulator 581 illustrated in FIG. 14A and in the insulator 582 and the insulator 586 illustrated in FIG. 13 in the region overlapping with the conductor 542b, and the conductor 540b is provided inside the opening portion. Note that the insulator 582 and the insulator 586 will be described later.

As illustrated in FIG. 14A, an insulator 541a as an insulator having an impurity barrier property may be provided between the conductor 540a and the side surface of the opening portion in the region overlapping with the conductor 542a. Similarly, an insulator 541b as an insulator having an impurity barrier property may be provided between the conductor 540b and the side surface of the opening portion in the region overlapping with the conductor 542b. Note that in this specification and the like, the insulator 541a and the insulator 541b are collectively referred to as the insulator 541.

For the conductor 540a and the conductor 540b, a conductive material containing tungsten, copper, or aluminum as its main component is preferably used. The conductor 540a and the conductor 540b may each have a stacked-layer structure.

In the case where the conductor 540 has a stacked-layer structure, a conductive material having a function of inhibiting passage of impurities such as water or hydrogen is preferably used for a first conductor provided in the vicinity of the insulator 574, the insulator 576, the insulator 581, the insulator 580, the insulator 544, and the insulator 571. For example, tantalum, tantalum nitride, titanium, titanium nitride, ruthenium, ruthenium oxide, or the like is preferably used. The conductive material having a function of inhibiting passage of impurities such as water or hydrogen may be used as a single layer or stacked layers. Moreover, impurities such as water or hydrogen contained in a layer above the insulator 576 can be inhibited from entering the oxide 530 through the conductor 540a and the conductor 540b.

For the insulator 541a and the insulator 541b, a barrier insulating film that can be used for the insulator 544 or the like may be used. For the insulator 541a and the insulator 541b, for example, an insulator such as silicon nitride, aluminum oxide, or silicon nitride oxide may be used. Since the insulator 541a and the insulator 541b are provided in contact with the insulator 574, the insulator 576, and the insulator 571, impurities such as water or hydrogen contained in the insulator 580 or the like can be inhibited from entering the oxide 530 through the conductor 540a and the conductor 540b. In particular, silicon nitride is suitable because of its high blocking property against hydrogen. Furthermore, oxygen contained in the insulator 580 can be prevented from being absorbed by the conductor 540a and the conductor 540b.

When the insulator 541a and the insulator 541b each have a stacked-layer structure as illustrated in FIG. 14A, a first insulator in contact with an inner wall of the opening in the insulator 580 and the like and a second insulator inside the first insulator are preferably formed using a combination of a barrier insulating film against oxygen and a barrier insulating film against hydrogen.

For example, aluminum oxide deposited by an ALD method may be used as the first insulator and silicon nitride deposited by a PEALD method may be used as the second insulator. With this structure, oxidation of the conductor 540 can be inhibited, and hydrogen can be inhibited from entering the conductor 540.

Although the first insulator of the insulator 541 and the second conductor of the insulator 541 are stacked in the transistor 500, the present invention is not limited thereto. For example, the insulator 541 may have a single-layer structure or a stacked-layer structure of three or more layers. Although the first conductor of the conductor 540 and the second conductor of the conductor 540 are stacked in the transistor 500, the present invention is not limited thereto. For example, the conductor 540 may have a single-layer structure or a stacked-layer structure of three or more layers.

As illustrated in FIG. 13, a conductor 610, a conductor 612, and the like serving as wirings may be provided in contact with the upper portion of the conductor 540a and the upper portion of the conductor 540b. For the conductor 610 and the conductor 612, a conductive material containing tungsten, copper, or aluminum as its main component is preferably used. The conductors can each have a stacked-layer structure. Specifically, the conductors may each be a stack of titanium or a titanium nitride and any of the above conductive materials, for example. Note that the conductors may each be formed to be embedded in an opening provided in an insulator.

The structure of the transistor included in the semiconductor device of one embodiment of the present invention is not limited to that of the transistor 500 illustrated in FIG. 13, FIG. 14A, FIG. 14B, and FIG. 15. The structure of the transistor included in the semiconductor device of one embodiment of the present invention may be changed in accordance with circumstances.

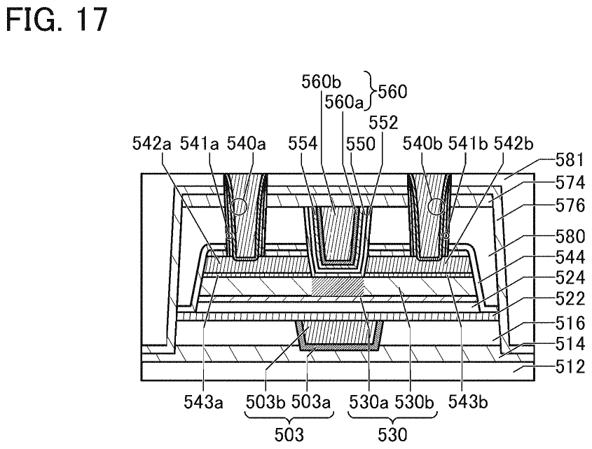

For example, the transistor 500 illustrated in FIG. 13, FIG. 14A, FIG. 14B, and FIG. 15 may have a structure illustrated in FIG. 17. The transistor in FIG. 17 is different from the transistor 500 illustrated in FIG. 13, FIG. 14A, FIG. 14B, and FIG. 15 in including an oxide 543a and an oxide 543b. Note that in this specification and the like, the oxide 543a and the oxide 543b are collectively referred to as an oxide 543. The cross section in the channel width direction of the transistor in FIG. 17 can have a structure similar to the cross section of the transistor 500 illustrated in FIG. 14B.

The oxide 543a is provided between the oxide 530b and the conductor 542a, and the oxide 543b is provided between the oxide 530b and the conductor 542b. Here, the oxide 543a is preferably in contact with the top surface of the oxide 530b and the bottom surface of the conductor 542a. The oxide 543b is preferably in contact with the top surface of the oxide 530b and the bottom surface of the conductor 542b.

The oxide 543 preferably has a function of inhibiting passage of oxygen. The oxide 543 having a function of inhibiting passage of oxygen is preferably provided between the oxide 530b and the conductor 542 functioning as the source electrode or the drain electrode, in which case the electric resistance between the conductor 542 and the oxide 530b can be reduced. Such a structure can improve the electrical characteristics, the field-effect mobility, and the reliability of the transistor 500 in some cases.

A metal oxide containing the element M may be used as the oxide 543. In particular, aluminum, gallium, yttrium, or tin is preferably used as the element M. The concentration of the element M in the oxide 543 is preferably higher than that in the oxide 530b. Furthermore, gallium oxide may be used as the oxide 543. A metal oxide such as an In-M-Zn oxide may be used as the oxide 543. Specifically, the atomic ratio of the element M to In in the metal oxide used as the oxide is preferably greater than the atomic ratio of the element M to In in the metal oxide used as the oxide 530b. The thickness of the oxide 543 is preferably greater than or equal to 0.5 nm or greater than or equal to 1 nm, and less than or equal to 2 nm, less than or equal to 3 nm, or less than or equal to 5 nm. Note that the above-described lower limits and upper limits can be combined with each other. The oxide 543 preferably has crystallinity. In the case where the oxide 543 has crystallinity, release of oxygen from the oxide 530 can be suitably inhibited. When the oxide 543 has a hexagonal crystal structure, for example, release of oxygen from the oxide 530 can sometimes be inhibited.

The insulator 582 is provided over the insulator 581, and the insulator 586 is provided over the insulator 582.

A substance having a barrier property against oxygen and hydrogen is preferably used for the insulator 582. Thus, a material similar to that for the insulator 514 can be used for the insulator 582. For the insulator 582, a metal oxide such as aluminum oxide, hafnium oxide, or tantalum oxide is preferably used, for example.

For the insulator 586, a material similar to that for the insulator 320 can be used. Furthermore, when a material with a relatively low permittivity is used for these insulators, parasitic capacitance generated between wirings can be reduced. A silicon oxide film, a silicon oxynitride film, or the like can be used for the insulator 586, for example.

Next, the capacitor 600 and a peripheral wiring or plug included in each of the semiconductor devices illustrated in FIG. 13 and FIG. 15 are described. Note that the capacitor 600 and the wiring and/or the plug are provided above the transistor 500 illustrated in FIGS. 13 and FIG. 15.

The capacitor 600 includes the conductor 610, a conductor 620, and an insulator 630, for example.

The conductor 610 is provided over one of the conductor 540a and the conductor 540b, a conductor 546, and the insulator 586. The conductor 610 has a function of one of a pair of electrodes of the capacitor 600.

The conductor 612 is provided over the insulator 586 and the other of the conductor 540a and the conductor 540b. The conductor 612 functions as a plug, a wiring, a terminal, or the like that electrically connects the transistor 500 to a circuit element, a wiring, or the like provided above the transistor 500.

Note that the conductor 612 and the conductor 610 may be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

The conductor 612 and the conductor 610 each have a single-layer structure in FIG. 13; however, the structure is not limited thereto, and a stacked-layer structure of two or more layers may be employed. For example, between a conductor having a barrier property and a conductor having high conductivity, a conductor that is highly adhesive to the conductor having a barrier property and the conductor having high conductivity may be formed.

The insulator 630 is provided over the insulator 586 and the conductor 610. The insulator 630 functions as a dielectric sandwiched between the pair of electrodes of the capacitor 600.

As the insulator 630, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or zirconium oxide can be used. The insulator 630 can be provided to have a stacked-layer structure or a single-layer structure using any of the above materials.

For another example, the insulator 630 may have a stacked-layer structure using a material with high dielectric strength, such as silicon oxynitride, and a high-permittivity (high-k) material. In the capacitor 600 having such a structure, a sufficient capacitance can be ensured owing to the high-permittivity (high-k) insulator, and the dielectric strength can be increased owing to the insulator with high dielectric strength; hence, the electrostatic breakdown of the capacitor 600 can be inhibited.

Examples of an insulator that is the high-permittivity (high-k) material (a material having a high dielectric constant) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Alternatively, for example, a single layer or stacked layers of an insulator containing a high-k material such as aluminum oxide, hafnium oxide, tantalum oxide, zirconium oxide, lead zirconate titanate (PZT), strontium titanate (SrTiO₃), or (Ba,Sr)TiO₃ (BST) may be used as the insulator 630. For the insulator 630, a compound containing hafnium and zirconium may be used, for example. As miniaturization and high integration of semiconductor devices progress, a problem such as leakage current from a transistor, a capacitor, or the like might arise because of a thinner gate insulator and a thinner dielectric used in the capacitor. When a high-k material is used for an insulator functioning as the gate insulator and the dielectric used in the capacitor, a gate potential during the operation of the transistor can be lowered and the capacitance can be ensured while the physical thicknesses of the gate insulator and the dielectric are maintained.

The conductor 620 is provided to overlap with the conductor 610 with the insulator 630 therebetween. The conductor 610 has a function of one of the pair of electrodes of the capacitor 600.

For the conductor 620, a conductive material such as a metal material, an alloy material, or a metal oxide material can be used. It is preferable to use a high-melting-point material that has both heat resistance and conductivity, such as tungsten or molybdenum, and it is particularly preferable to use tungsten. In the case where the conductor 620 is formed concurrently with another component such as a conductor, Cu (copper), Al (aluminum), or the like, which is a low-resistance metal material, is used. For example, the conductor 620 can be formed using a material that can be used for the conductor 610. The conductor 620 may have a stacked-layer structure of two or more layers instead of a single-layer structure.

An insulator 640 is provided over the conductor 620 and the insulator 630. The insulator 640 is preferably formed using a film having a barrier property that prevents hydrogen, impurities, or the like from diffusing into the region where the transistor 500 is provided, for example. Thus, a material similar to that for the insulator 324 can be used.

An insulator 650 is provided over the insulator 640. The insulator 650 can be provided using a material similar to that for the insulator 320. The insulator 650 may function as a planarization film that covers an uneven shape thereunder. Thus, the insulator 650 can be formed using any of the materials that can be used for the insulator 324, for example.

Although the capacitor 600 illustrated in FIG. 13 and FIG. 15 is a planar capacitor, the shape of the capacitor is not limited thereto. For example, the capacitor 600 may be a cylindrical capacitor instead of a planar capacitor.

A wiring layer may be provided above the capacitor 600. For example, in FIG. 13, an insulator 411, an insulator 412, an insulator 413, and an insulator 414 are provided in this order above the insulator 650. In addition, a conductor 416 serving as a plug or a wiring is provided in the insulator 411, the insulator 412, and the insulator 413. The conductor 416 can be provided, for example, in a region overlapping with a conductor 660 to be described later.

In addition, in the insulator 630, the insulator 640, and the insulator 650, an opening portion is provided in a region overlapping with the conductor 612, and the conductor 660 is provided to fill the opening portion. The conductor 660 serves as a plug or a wiring that is electrically connected to the conductor 416 included in the above-described wiring layer.

Like the insulator 324 or the like, the insulator 411 and the insulator 414 are each preferably formed using an insulator having a barrier property against impurities such as water or hydrogen, for example. Thus, the insulator 411 and the insulator 414 can be formed using any of the materials that can be used for the insulator 324 or the like, for example.

Like the insulator 326, the insulator 412 and the insulator 413 are each preferably formed using, for example, an insulator having a relatively low dielectric constant to reduce the parasitic capacitance generated between wirings.

The conductor 612 and the conductor 416 can be provided using materials similar to those for the conductor 328 and the conductor 330, for example.

### <Structure Examples of Transistor and Ferroelectric Capacitor>

Next, a structure in which a dielectric that can show ferroelectricity is provided in or in the vicinity of the transistor 500 whose channel formation region contains a metal oxide will be described.

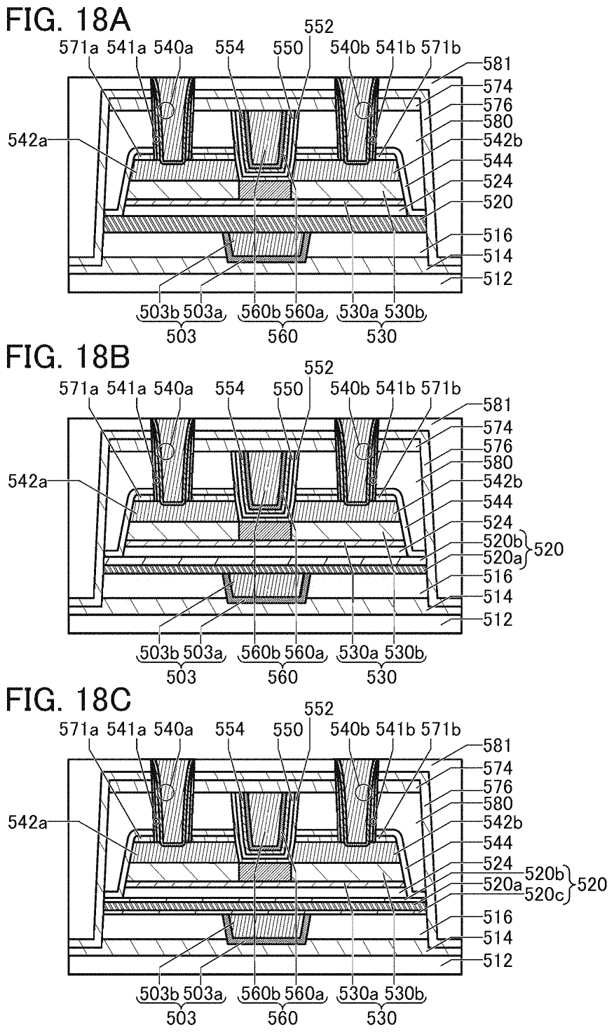

FIG. 18A illustrates a structure example of a transistor in which a dielectric that can show ferroelectricity is provided in the structure of the transistor 500 illustrated in FIG. 13, FIG. 14A, and the like.

The transistor illustrated in FIG. 18A has a structure in which the insulator 522 functioning as the second gate insulator is replaced with an insulator 520. For the insulator 520, for example, a dielectric that can show ferroelectricity can be used.

Thus, a ferroelectric capacitor can be provided in the transistor in FIG. 18A between the conductor 503 functioning as the second gate electrode and the oxide 530. In other words, the transistor in FIG. 18A can be an FeFET (Ferroelectric FET) in which a dielectric that can show ferroelectricity is provided in part of the second gate insulator.

Although the insulator 520 is illustrated as a single layer in FIG. 18A, the insulator 520 may be two or more insulating films including a dielectric that can show ferroelectricity. FIG. 18B illustrates a specific example of such a transistor. In FIG. 18B, the insulator 520 includes an insulator 520a and an insulator 520b, for example. The insulator 520a is provided on the top surfaces of the insulator 516 and the conductor 503, and the insulator 520b is provided on the top surface of the insulator 520a.

A dielectric that can show ferroelectricity can be used for the insulator 520a, for example. Furthermore, silicon oxide can be used for the insulator 520b, for example. Alternatively, silicon oxide may be used for the insulator 520a and a dielectric that can show ferroelectricity may be used for the insulator 520b, for example.

When the insulator 520 has two layers, one layer contains a dielectric that can show ferroelectricity and the other layer contains silicon oxide, as illustrated in FIG. 18B, leakage of current flowing between the conductor 503 functioning as the gate electrode and the oxide 530 can be inhibited.

FIG. 18C illustrates a structure example of a transistor in which the insulator 520 has three layers. In FIG. 18C, the insulator 520 includes the insulator 520a, the insulator 520b, and an insulator 520c, for example. The insulator 520c is provided on the top surfaces of the insulator 516 and the conductor 503, the insulator 520a is provided on the top surface of the insulator 520c, and the insulator 520b is provided on the top surface of the insulator 520a.

A dielectric that can show ferroelectricity can be used for the insulator 520a, for example. Furthermore, silicon oxide can be used for the insulator 520b and the insulator 520c, for example.

The structures of the transistors and the ferroelectric capacitors illustrated in FIG. 18A to FIG. 18B can be applied to transistors FM1 to FM3 described in Embodiment 1, for example.

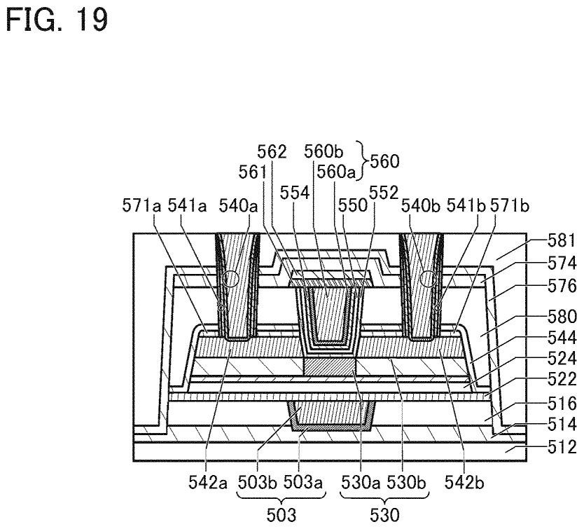

FIG. 19 illustrates a structure example of a transistor, which is different from the transistors illustrated in FIG. 18A to FIG. 18C, in which a dielectric that can show ferroelectricity is provided in the structure of the transistor 500 illustrated in FIG. 13, FIG. 14A, and the like.

FIG. 19 illustrates a structure example of a transistor in which a dielectric that can show ferroelectricity is provide over the insulator 552, the insulator 550, and the insulator 554 functioning as the first gate insulator, the conductor 560 functioning as the first gate electrode, and a region of the insulator 580.

Specifically, an insulator 561 is provided to be in contact with the insulator 552, the insulator 550, the insulator 554, the conductor 560, and a region of the insulator 580. For the insulator 561, the dielectric that can show ferroelectricity applicable to the insulator 520 in FIG. 18A can be used, for example.

A conductor 562 is provided over and in contact with the insulator 561. The conductor 562 can be provided using a material similar to those for the conductor 328 and the conductor 330, for example.

Owing to the transistor structure illustrated in FIG. 19, a ferroelectric capacitor can be provided between the conductor 503 functioning as the first gate electrode and the conductor 562.

Note that the insulator 561 may have a stacked-layer structure of two or more layers like the insulator 520 illustrated in FIG. 18B or FIG. 18C.

The structures of the transistor and the ferroelectric capacitor illustrated in FIG. 19 can be applied to the transistor M1 and the capacitor C2 described in Embodiment 1, for example.

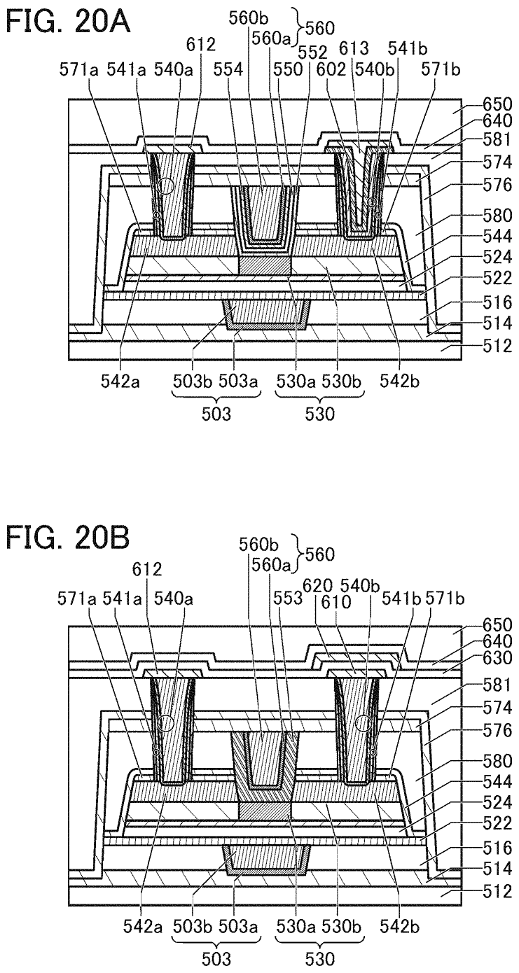

FIG. 20A illustrates a structure example of a transistor, which is different from the transistors illustrated in FIG. 18A to FIG. 18C and FIG. 19, in which a dielectric that can show ferroelectricity is provided in the structure of the transistor 500 illustrated in FIG. 13, FIG. 14A, and the like.

In the transistor illustrated in FIG. 20A, an insulator 602 is provided in an opening portion provided in the insulator 544, the insulator 571b, the insulator 580, the insulator 574, the insulator 576, and the insulator 581 in a region overlapping with the conductor 542b. Specifically, in the opening portion, the insulator 541b is provided on a side surface of the opening portion, the conductor 540b is provided over the insulator 541b and the conductor 542b which is a bottom portion of the opening portion, the insulator 602 is provided over the conductor 540b and a region of the insulator 581, and a conductor 613 is provided over the insulator 602 to fill the rest of the opening portion.

As another specific example, in the opening portion, the insulator 541b may be provided on the side surface of the opening portion; the conductor 540b may be provide over the insulator 541b; the insulator 602 may be provided over the conductor 540b, a region of the insulator 581, and the conductor 542b which is the bottom portion of the opening portion; and the conductor 613 may be provided over the insulator 602 to fill the rest of the opening portion.

For the insulator 602, the dielectric that can show ferroelectricity applicable to the insulator 520 in FIG. 18A can be used, for example.

Among dielectrics that can show ferroelectricity, a material containing hafnium oxide or hafnium oxide and zirconium oxide is preferable because the material can show ferroelectricity even when being processed into a thin film of several nanometers. Here, the thickness of the insulator 602 can be less than or equal to 100 nm, preferably less than or equal to 50 nm, further preferably less than or equal to 10 nm. The insulator 602 having a small thickness can be combined with a miniaturized transistor to fabricate a semiconductor device.

In the case of using a material containing hafnium oxide and zirconium oxide (HfZrOₓ) for the insulator 602, deposition is preferably performed by a thermal ALD method.

In the case where the insulator 602 is deposited by a thermal ALD method, it is suitable to use a material that does not contain a hydrocarbon (also referred to as Hydro Carbon or HC) for a precursor. When the insulator 602 contains one or both of hydrogen and carbon, crystallization of the insulator 602 might be hindered. Thus, the precursor that does not contain a hydrocarbon is preferably used as described above to reduce the concentration(s) of one or both of hydrogen and carbon in the insulator 602. Examples of the precursor that does not contain a hydrocarbon include a chlorine-based material. In the case where a material containing hafnium oxide and zirconium oxide (HfZrOₓ) is used for the insulator 602, HfCl₄ and/or ZrCl₄ are/is used as the precursor.

In the case where the insulator 602 is formed by a thermal ALD method, H₂O or O₃ can be used as an oxidizer. As the oxidizer in the thermal ALD method, O₃ is more suitably used than H₂O to reduce the concentration of hydrogen in the film. However, the oxidizer in the thermal ALD method is not limited thereto. For example, the oxidizer in the thermal ALD method may contain any one or more selected from O₂, O₃, N₂O, NO₂, H₂O, and H₂O₂.

The conductor 613 can be provided using a material similar to those for the conductor 328 and the conductor 330, for example.

The conductor 613 can be deposited by an ALD method, a CVD method, or the like. For example, titanium nitride can be deposited by a thermal ALD method. Here, the deposition of the conductor 613 is preferably performed by a method in which deposition is performed while a substrate is heated, like a thermal ALD method. For example, deposition is performed at a substrate temperature of higher than or equal to room temperature, preferably higher than or equal to 300° C., further preferably higher than or equal to 325° C., still further preferably higher than or equal to 350° C. Furthermore, for example, deposition is performed at a substrate temperature of lower than or equal to 500° C., preferably lower than or equal to 450° C. For example, the substrate temperature is set to approximately 400° C.

When the conductor 613 is deposited within the above temperature range, the insulator 602 can have ferroelectricity even without baking treatment at high temperatures (e.g., baking treatment at a heat treatment temperature of higher than or equal to 400° C. or higher than or equal to 500° C.) after the formation of the conductor 613. When the conductor 613 is deposited by an ALD method, which causes relatively little damage to a base, as described above, the crystal structure of the insulator 602 can be inhibited from being broken excessively, which leads to higher ferroelectricity of the insulator 602.

In the case where the conductor 613 is formed by a sputtering method, for example, a base film, i.e., the insulator 602 here might be damaged. In the case where a material containing hafnium oxide and zirconium oxide (HfZrOₓ) is used for the insulator 602 and the conductor 613 is formed by a sputtering method, for example, HfZrOₓ, which is the base film, might be damaged by the sputtering method and the crystal structure of HfZrOₓ (typified by an orthorhombic crystal structure or the like) might be broken. There is a method in which heat treatment is performed after the sputtering method to recover the damage to the crystal structure of HfZrOₓ; however, in some cases, the damage in HfZrOₓ formed by the sputtering method, for example, a dangling bond (e.g., O*) in HfZrOₓ, is bonded to hydrogen contained in HfZrOₓ, which makes it impossible to recover the damage to the crystal structure of HfZrOₓ.

Thus, a material that does not contain hydrogen or contains an extremely small amount of hydrogen is suitably used as HfZrOₓ used for the insulator 602. The use of the material that does not contain hydrogen or contains an extremely small amount of hydrogen for the insulator 602 can improve the crystallinity of the insulator 602, leading to a structure having a high ferroelectricity.

As described above, in one embodiment of the present invention, as the insulator 602, a ferroelectric material is formed by a thermal ALD method using a precursor that does not contain a hydrocarbon (typified by a chlorine-based precursor) and an oxidizer (typified by O₃), for example. After that, the conductor 613 is formed by deposition by a thermal ALD method (typified by deposition at 400° C. or higher), whereby the crystallinity or ferroelectricity of the insulator 602 can be improved without performing annealing after the deposition, in other words, with utilizing the temperature during the deposition of the conductor 613. Note that improving the crystallinity or ferroelectricity of the insulator 602 by utilizing the temperature during the deposition of the conductor 613 without performing annealing after the deposition of the conductor 613 is referred to as self-annealing, in some cases.

Owing to the transistor structure illustrated in FIG. 20A, a ferroelectric capacitor can be provided between the conductor 540b and the conductor 613 in the opening portion provided in a region overlapping with the conductor 542b.

Note that the insulator 602 may have a stacked-layer structure of two or more layers like the insulator 520 illustrated in FIG. 18B or FIG. 18C.

FIG. 20B illustrates a structure example of a transistor, which is different from the transistors illustrated in FIG. 18A to FIG. 18C, FIG. 19, and FIG. 20A, in which a dielectric that can show ferroelectricity is provided in the structure of the transistor 500 illustrated in FIG. 13, FIG. 14A, and the like.

The transistor illustrated in FIG. 20B has a structure in which the insulator 552, the insulator 550, and the insulator 554 functioning as the first gate insulator are replaced with an insulator 553. For the insulator 553, the dielectric that can show ferroelectricity applicable to the insulator 520 in FIG. 18A can be used, for example.

Thus, a ferroelectric capacitor can be provided in the transistor in FIG. 20B between the conductor 560 functioning as the first gate electrode and the oxide 530. In other words, the transistor in FIG. 20B can be an FeFET in which a dielectric that can show ferroelectricity is provided in part of the first gate insulator.

Note that the insulator 553 may have a stacked-layer structure of two or more layers like the insulator 520 illustrated in FIG. 18B or FIG. 18C.

Although FIG. 20B illustrates the structure in which the insulator 552, the insulator 550, and the insulator 554 are replaced with the insulator 553, a structure in which at least one of the insulator 552, the insulator 550, and the insulator 554 is replaced with the insulator 553 and the rest of the insulators and the insulator 553 are stacked may be employed as another structure example.

The structures of the transistors and the ferroelectric capacitors illustrated in FIG. 20A and FIG. 20B can be applied to the transistor M1, the capacitor C2, and the like described in Embodiment 1, for example.

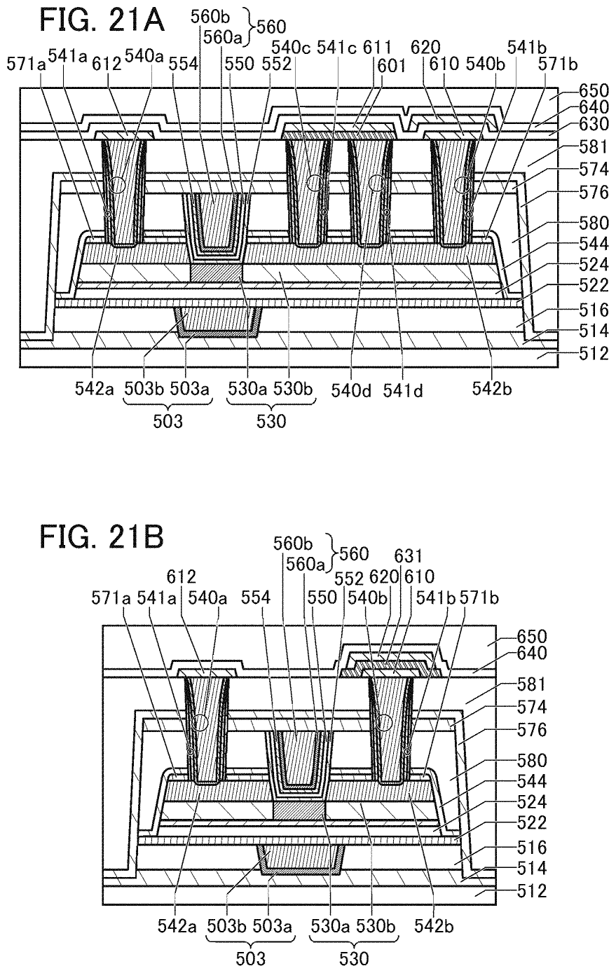

FIG. 21A illustrates a structure example of the transistor 500 and a capacitor including a dielectric that can show ferroelectricity provided in the vicinity of the transistor 500.

In the transistor illustrated in FIG. 21A, a plurality of opening portions are formed in the insulator 544, the insulator 571b, the insulator 580, the insulator 574, the insulator 576, and the insulator 581 in regions overlapping with the conductor 542b, for example. A conductor 540c functioning as a plug is provided in one of the opening portions, and an insulator 541c is provided between a side surface of the opening portion and the conductor 540c, as an insulator having a barrier property against an impurity. Furthermore, a conductor 540d functioning as a plug is provided in another one of the opening portions, and an insulator 541d is provided between a side surface of the opening portion and the conductor 540d, as an insulator having a barrier property against an impurity. Note that the material applicable to the conductor 540a and the conductor 540b can be used for the conductor 540c and the conductor 540d, for example, and the material applicable to the insulator 541a and the insulator 541b can be used for the insulator 541c and the insulator 541d, for example.

An insulator 601 is provided over and in contact with the conductor 540c and the conductor 540d. For the insulator 601, the dielectric that can show ferroelectricity applicable to the insulator 520 in FIG. 18A can be used, for example.

A conductor 611 is provided over and in contact with the insulator 601. The conductor 611 can be provided using a material similar to those for the conductor 328 and the conductor 330, for example.

Owing to the structure illustrated in FIG. 21A, a ferroelectric capacitor can be provided between the conductor 611 and each of the conductor 540c and the conductor 540d functioning as plugs.

Note that the insulator 601 may have a stacked-layer structure of two or more layers like the insulator 520 illustrated in FIG. 18B or FIG. 18C.

Although the number of plugs in contact with the insulator 601 is two (the conductor 540c and the conductor 540d) in FIG. 14A, the number of the plugs may be one, or three or more. In other words, although FIG. 15 illustrates an example where a region overlapping with the insulator 601 is provided with two opening portions in which conductors are provided as plugs, the number of opening portions provided in the region overlapping with the insulator 601 may be one, or three or more.

FIG. 21B illustrates a structure example, which is different from that in FIG. 21A, of the transistor 500 and a capacitor including a dielectric that can show ferroelectricity provided in the vicinity of the transistor 500.

In the transistor illustrated in FIG. 21B, an insulator 631 is provided on the top surface of the conductor 610 positioned over the conductor 540b functioning as a plug and the top surface of a region of the insulator 581. For the insulator 631, the dielectric that can show ferroelectricity applicable to the insulator 520 in FIG. 18A can be used, for example.

The conductor 620 is provided on the top surface of the insulator 631, and the insulator 640 and the insulator 650 are provided in this order on the top surfaces of the insulator 581, the conductor 612, the conductor 620, and a region of the insulator 631.

Owing to the structure illustrated in FIG. 21B, a ferroelectric capacitor can be provided between the conductor 610 and the conductor 620.

Note that the insulator 631 may have a stacked-layer structure of two or more layers like the insulator 520 illustrated in FIG. 18B or FIG. 18C.

The structures of the transistors and the ferroelectric capacitors illustrated in FIG. 21A and FIG. 21B can be applied to the transistor M1, the capacitor C2, and the like described in Embodiment 1, for example.

When a semiconductor device using a transistor including an oxide semiconductor has the structure described in this embodiment, a change in electrical characteristics of the transistor can be inhibited and the reliability can be improved. Alternatively, a semiconductor device using a transistor including an oxide semiconductor can be miniaturized or highly integrated.

Note that this embodiment can be combined with any of the other embodiments described in this specification as appropriate.

### Embodiment 3

Described in this embodiment is a metal oxide (hereinafter also referred to as an oxide semiconductor) that can be used in an OS transistor described in the above embodiment.

The metal oxide preferably contains at least indium or zinc. In particular, indium and zinc are preferably contained. In addition to them, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structures>

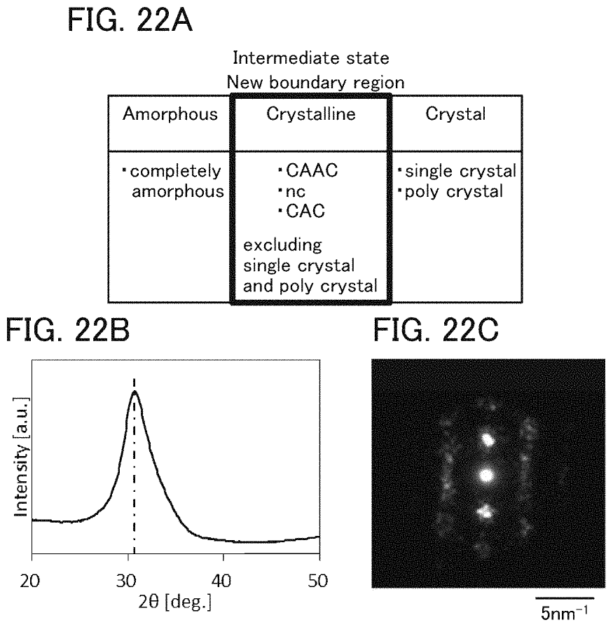

First, the classification of crystal structures of an oxide semiconductor is described with reference to FIG. 22A. FIG. 22A is a diagram showing classification of crystal structures of an oxide semiconductor, typically IGZO (a metal oxide containing In, Ga, and Zn).

As shown in FIG. 22A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (Cloud-Aligned Composite). Note that the term “Crystalline” excludes single crystal, poly crystal, and completely amorphous (excluding single crystal and poly crystal). The term “Crystal” includes single crystal and poly crystal.

Note that the structures in the thick frame in FIG. 22A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. FIG. 22B shows an XRD spectrum, which is obtained using GIXD (Grazing-Incidence XRD) measurement, of a CAAC-IGZO film classified into “Crystalline”. In FIG. 22B, the horizontal axis represents 2θ [deg.], and the vertical axis represents Intensity [a.u.]. Note that a GIXD method is also referred to as a thin film method or a Seemann-Bohlin method. The XRD spectrum that is shown in FIG. 22B and obtained by GIXD measurement is hereinafter simply referred to as an XRD spectrum. The CAAC-IGZO film in FIG. 22B has a composition in the vicinity of In:Ga:Zn=4:2:3 [atomic ratio]. The CAAC-IGZO film in FIG. 22B has a thickness of 500 nm.

As shown in FIG. 22B, a clear peak indicating crystallinity is detected in the XRD spectrum of the CAAC-IGZO film. Specifically, a peak indicating c-axis alignment is detected at or around 2θ=31° in the XRD spectrum of the CAAC-IGZO film. As shown in FIG. 22B, the peak at or around 2θ=31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 22C shows a diffraction pattern of a CAAC-IGZO film. FIG. 22C shows a diffraction pattern obtained with the NBED method in which an electron beam is incident in the direction parallel to the substrate. The CAAC-IGZO film in FIG. 22C has a composition in the vicinity of In:Ga:Zn=4:2:3 [atomic ratio]. In the nanobeam electron diffraction method, electron diffraction is performed with a probe diameter of 1 nm.

As shown in FIG. 22C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 22A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region with a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which layers containing indium (In) and oxygen (hereinafter In layers) and layers containing the element M, zinc (Zn), and oxygen (hereinafter (M,Zn) layers) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, or the like is included in the distortion in some cases. Note that a clear grain boundary cannot be observed even in the vicinity of the distortion in the CAAC-OS. That is, formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and captures carriers and thus decreases the on-state current or field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, and the like, the CAAC-OS can be regarded as an oxide semiconductor that has small amounts of impurities, defects (e.g., oxygen vacancies), and the like. Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for an OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor with some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. As another example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), high field-effect mobility (μ), and an excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained using SIMS, is set lower than or equal to 1×10¹⁸ atoms/cm³, preferably lower than or equal to 2×10¹⁶ atoms/cm³.

When the oxide semiconductor contains nitrogen, the oxide semiconductor easily becomes n-type because of generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

Note that this embodiment can be combined with any of the other embodiments described in this specification as appropriate.

### Embodiment 4

In this embodiment, examples of a semiconductor wafer where the semiconductor device or the like described in the above embodiment is formed and electronic components incorporating the semiconductor device will be described.

### <Semiconductor Wafer>

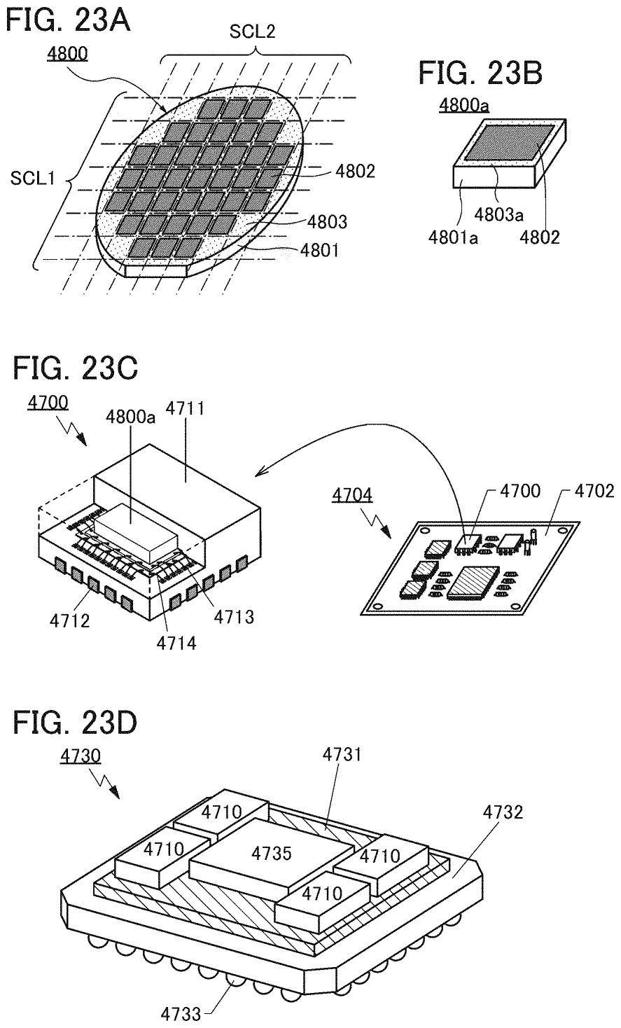

First, an example of a semiconductor wafer where a semiconductor device, for example, is formed is described using FIG. 23A.

A semiconductor wafer 4800 illustrated in FIG. 23A includes a wafer 4801 and a plurality of circuit portions 4802 provided on a top surface of the wafer 4801. Note that a portion without the circuit portion 4802 on the top surface of the wafer 4801 is a spacing 4803 that is a region for dicing.

The semiconductor wafer 4800 can be manufactured by forming the plurality of circuit portions 4802 on the surface of the wafer 4801 by a pre-process. After that, a surface of the wafer 4801 opposite to the surface provided with the plurality of circuit portions 4802 may be ground to thin the wafer 4801. Through this step, for example, warpage of the wafer 4801 is reduced and the size of the component can be reduced.

A dicing step is performed as a next step. Dicing is performed along scribe lines SCL1 and scribe lines SCL2 (referred to as dicing lines or cutting lines in some cases) indicated by dashed-dotted lines. Note that to perform the dicing step easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing step, a chip 4800a as illustrated in FIG. 23B can be cut out from the semiconductor wafer 4800. The chip 4800a includes a wafer 4801a, the circuit portion 4802, and a spacing 4803a. Note that it is preferable to make the spacing 4803a small as much as possible. In this case, the width of the spacing 4803 between adjacent circuit portions 4802 is substantially the same as a cutting allowance of the scribe line SCL1 or a cutting allowance of the scribe line SCL2.

Note that the shape of the element substrate of one embodiment of the present invention is not limited to the shape of the semiconductor wafer 4800 illustrated in FIG. 23A. The element substrate may be a rectangular semiconductor wafer, for example. The shape of the element substrate can be changed as appropriate, depending on a manufacturing process of an element and an apparatus for manufacturing the element.

### <Electronic Component>

FIG. 23C illustrates a perspective view of an electronic component 4700 and a substrate (a mounting board 4704) on which the electronic component 4700 is mounted. The electronic component 4700 illustrated in FIG. 23C includes a chip 4800a in a mold 4711. As the chip 4800a, the memory device of one embodiment of the present invention can be used, for example.

To illustrate the inside of the electronic component 4700, some portions are omitted in FIG. 23C. The electronic component 4700 includes a land 4712 outside the mold 4711. The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, so that the mounting board 4704 is completed.

FIG. 23D illustrates a perspective view of an electronic component 4730. The electronic component 4730 is an example of a SiP (System in package) or an MCM (Multi Chip Module). In the electronic component 4730, an interposer 4731 is provided on a package substrate 4732 (a printed circuit board), and a semiconductor device 4735 and a plurality of semiconductor devices 4710 are provided on the interposer 4731.

Examples of the semiconductor device 4710 include the chip 4800a, the semiconductor device described in the above embodiment, and a high bandwidth memory (HBM). In addition, an integrated circuit (a semiconductor device) such as a CPU, a GPU, an FPGA, or a memory device can be used as the semiconductor device 4735.

As the package substrate 4732, a ceramic substrate, a plastic substrate, a glass epoxy substrate, or the like can be used. As the interposer 4731, a silicon interposer, a resin interposer, or the like can be used.

The interposer 4731 includes a plurality of wirings and has a function of electrically connecting a plurality of integrated circuits with different terminal pitches. The plurality of wirings are provided in a single layer or multiple layers. In addition, the interposer 4731 has a function of electrically connecting an integrated circuit provided on the interposer 4731 to an electrode provided on the package substrate 4732. Accordingly, the interposer is referred to as a “redistribution substrate” or an “intermediate substrate” in some cases. Furthermore, a through electrode is provided in the interposer 4731 and the through electrode is used to electrically connect an integrated circuit and the package substrate 4732 in some cases. Moreover, in the case of using a silicon interposer, a TSV (Through Silicon Via) can also be used as the through electrode.

A silicon interposer is preferably used as the interposer 4731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In addition, a heat sink (a radiator plate) may be provided to overlap with the electronic component 4730. In the case of providing a heat sink, the heights of integrated circuits provided on the interposer 4731 are preferably equal to each other. For example, in the electronic component 4730 described in this embodiment, the heights of the semiconductor devices 4710 and the semiconductor device 4735 are preferably equal to each other.

To mount the electronic component 4730 on another substrate, an electrode 4733 may be provided on a bottom portion of the package substrate 4732. FIG. 23D illustrates an example in which the electrode 4733 is formed of a solder ball. Solder balls are provided in a matrix on the bottom portion of the package substrate 4732, so that BGA (Ball Grid Array) mounting can be achieved. Alternatively, the electrode 4733 may be formed of a conductive pin. When conductive pins are provided in a matrix on the bottom portion of the package substrate 4732, PGA (Pin Grid Array) mounting can be achieved.

The electronic component 4730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

Note that this embodiment can be combined with any of the other embodiments described in this specification as appropriate.

### Embodiment 5

In this embodiment, application examples of the semiconductor device of one embodiment of the present invention will be described.

The semiconductor device of one embodiment of the present invention can be applied to, for example, memory devices of a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

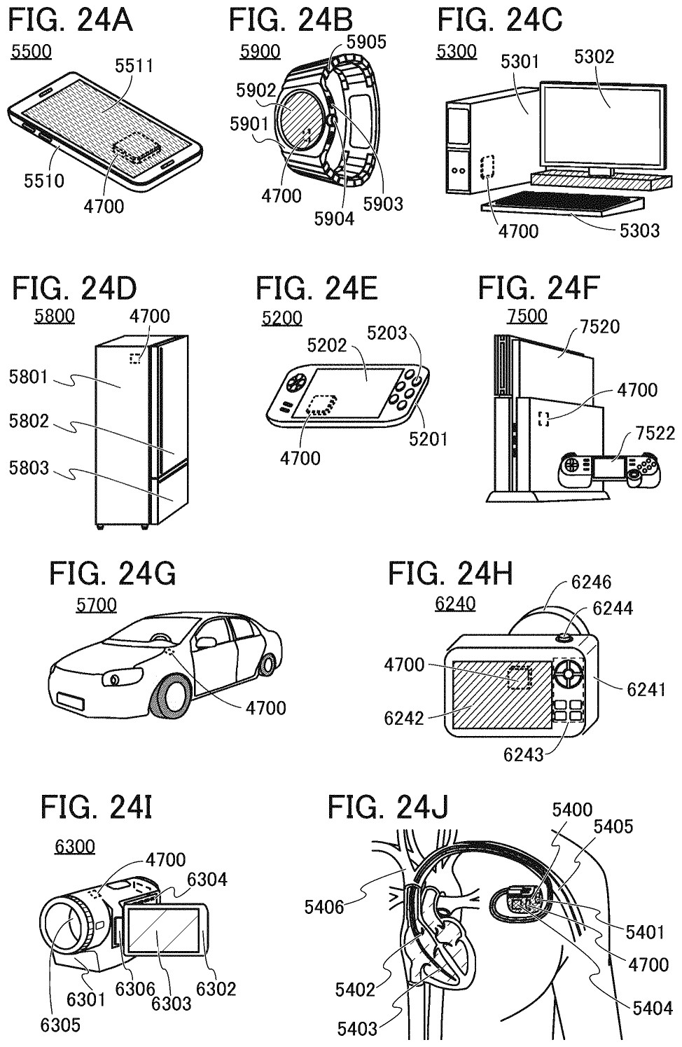

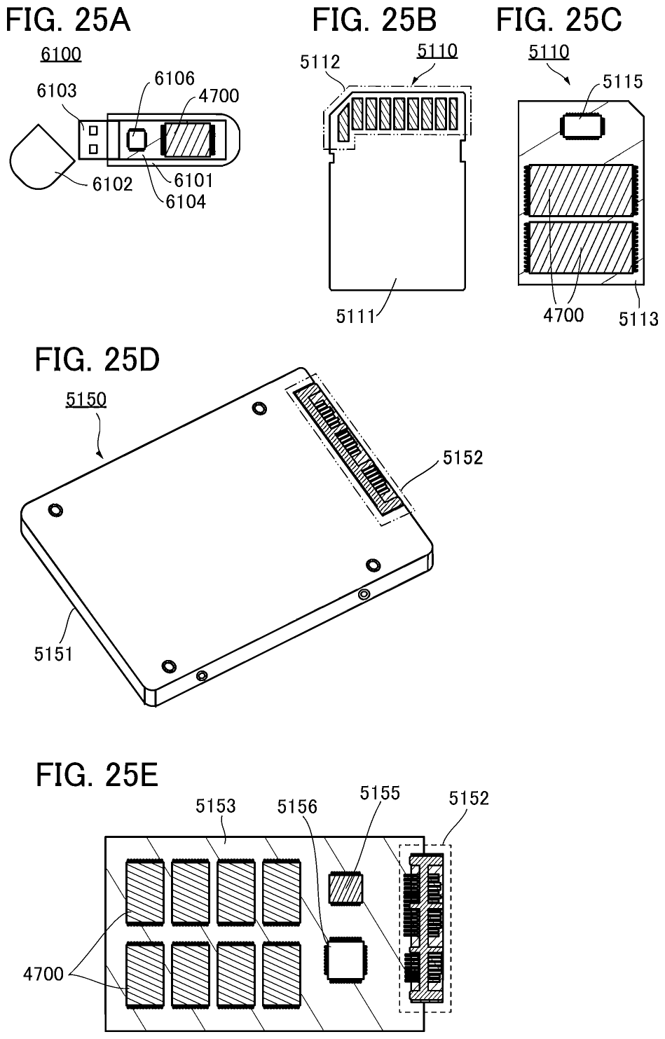

An example of an electronic device including a semiconductor device of one embodiment of the present invention is described. Note that FIG. 24A to FIG. 24J and FIG. 25A to FIG. 25E each illustrate a state where the electronic component 4700 or the electronic component 4730, each of which includes the semiconductor device, is included in an electronic device.

### [Cellular Phone]

An information terminal 5500 illustrated in FIG. 24A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By applying the semiconductor device of one embodiment of the present invention to the information terminal 5500, the information terminal 5500 can retain a temporary file generated at the time of executing an application (e.g., a web browser's cache).

### [Wearable Terminal]

In addition, FIG. 24B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by applying the semiconductor device of one embodiment of the present invention to the wearable terminal.

### [Information Terminal]

In addition, FIG. 24C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application applying the semiconductor device of one embodiment of the present invention to the desktop information terminal 5300.

Note that although the smartphone, the wearable terminal, and the desktop information terminal are respectively illustrated in FIG. 24A to FIG. 24(C) as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

In addition, FIG. 24D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be applied to the electric refrigerator-freezer 5800. The electric refrigerator-freezer 5800 can transmit and receive information on food stored in the electric refrigerator-freezer 5800 or food expiration dates, for example, to and from an information terminal and the like via the Internet. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, an audiovisual appliance, and the like.

### [Game Machine]

In addition, FIG. 24E illustrates a portable game machine 5200 as an example of a game machine. The portable game machine 5200 includes a housing 5201, a display portion 5202, a button 5203, and the like.

In addition, FIG. 24F illustrates a stationary game machine 7500 as another example of a game machine. The stationary game machine 7500 includes a main body 7520 and a controller 7522. Note that the controller 7522 can be connected to the main body 7520 with or without a wire. Furthermore, although not illustrated in FIG. 24F, the controller 7522 can include a display portion that displays a game image, and an input interface besides a button, such as a touch panel, a stick, a rotating knob, and a sliding knob, for example. Moreover, the shape of the controller 7522 is not limited to that illustrated in FIG. 24F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture and/or a voice instead of a controller.

In addition, videos displayed on the game machine can be output with a display device such as a television device, a personal computer display, a game display, or a head-mounted display.

The semiconductor device described in the above embodiment is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, the semiconductor device described in the above embodiment is employed for the portable game machine 5200 or the stationary game machine 7500, so that it is possible to retain a temporary file necessary for arithmetic operation that occurs during game play.

Note that the electronic device of one embodiment of the present invention is not limited to the portable game machine and the stationary game machine. Examples of the electronic device of one embodiment of the present invention include an arcade game machine installed in entertainment facilities (a game center, an amusement park, or the like), a throwing machine for batting practice installed in sports facilities, or the like.

### [Moving Vehicle]

The semiconductor device described in the above embodiment can be used for an automobile, which is a moving vehicle, and around the driver's seat in an automobile.

FIG. 24G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a display device showing the above information may be provided around the driver's seat.

In particular, the display device can compensate for the view obstructed by a pillar or the like, blind areas for the driver's seat, and the like by displaying a video from an imaging device (not illustrated) provided for the automobile 5700, which can increase safety. That is, display of an image from an imaging device provided on the outside of the automobile 5700 can fill in blind areas and increase safety.

The semiconductor device described in the above embodiment can temporarily retain data. Thus, the semiconductor device can be used to retain temporary data necessary in an automatic driving system for the automobile 5700 or a system for navigation or risk prediction, for example. The display device may be configured to display temporary information regarding navigation, risk prediction, or the like. Moreover, the semiconductor device may be configured to hold a video of a driving recorder provided in the automobile 5700.

Note that although an automobile is described above as an example of a moving vehicle, the moving vehicle is not limited to an automobile. Examples of moving vehicles include a train, a monorail train, a ship, a flying object (a helicopter, an unmanned aircraft (drone), an airplane, or a rocket), and the like.

### [Camera]

The semiconductor device described in the above embodiment can be employed for a camera.

FIG. 24H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, although the camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

When the semiconductor device described in the above embodiment is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The semiconductor device described in the above embodiment can be employed for a video camera.

FIG. 24I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. With the use of the above semiconductor device, the video camera 6300 can retain a temporary file generated in encoding.

### [ICD]

The semiconductor device described in the above embodiment can be employed for an implantable cardioverter-defibrillator (ICD).

FIG. 24J is a schematic cross-sectional view showing an example of an ICD. An ICD main unit 5400 includes at least a battery 5401, the electronic component 4700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing and ventricular tachycardia, ventricular fibrillation, or the like keeps occurring, treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, or the time taken for the treatment, for example, can be stored in the electronic component 4700.

In addition, the antenna 5404 can receive power, and the battery 5401 is charged with the power. Furthermore, when the ICD main unit 5400 includes a plurality of batteries, safety can be increased. Specifically, even when one of the batteries in the ICD main unit 5400 is dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking a physiological signal such as a pulse, a respiratory rate, a heart rate, or body temperature with an external monitoring device.

### [Expansion Device for PC]

The semiconductor device described in the above embodiment can be employed for a calculator such as a PC (Personal Computer) or an expansion device for an information terminal.

FIG. 25A illustrates, as an example of the expansion device, a portable expansion device 6100 that includes a chip capable of holding information and is externally provided on a PC. The expansion device 6100 can store information using the chip when connected to a PC with a USB (Universal Serial Bus), for example. Note that FIG. 25A illustrates the portable expansion device 6100; however, the expansion device of one embodiment of the present invention is not limited thereto and may be a comparatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with, for example, a circuit for driving the semiconductor device described in the above embodiment. For example, the substrate 6104 is provided with the electronic component 4700 and a controller chip 6106. The USB connector 6103 functions as an interface for connection to an external device.

### [SD Card]

The semiconductor device described in the above embodiment can be employed for an SD card that can be attached to an electronic device such as an information terminal or a digital camera.

FIG. 25B is a schematic external view of an SD card, and FIG. 25C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a semiconductor device and a circuit for driving the semiconductor device. For example, the substrate 5113 is provided with electronic components 4700 and a controller chip 5115. Note that the circuit structures of the electronic components 4700 and the controller chip 5115 are not limited to those described above, and can be changed as appropriate according to circumstances. For example, a write circuit, a row driver, a read circuit, or the like that is provided in an electronic component may be incorporated into the controller chip 5115 instead of the electronic component 4700.

When the electronic components 4700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 4700.

### [SSD]

The semiconductor device described in the above embodiment can be employed for an SSD (Solid State Drive) that can be attached to an electronic device such as an information terminal.

FIG. 25D is a schematic external view of an SSD, and FIG. 25E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a semiconductor device and a circuit for driving the semiconductor device. For example, the electronic components 4700, a memory chip 5155, and a controller chip 5156 are attached to the substrate 5153. When the electronic components 4700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, or the like is incorporated in the controller chip 5156. Note that the circuit structures of the electronic components 4700, the memory chip 5155, and the controller chip 5156 are not limited to those described above, and the circuit structures can be changed as appropriate according to circumstances. For example, a memory functioning as a work memory may also be provided in the controller chip 5156.

### [Computer]

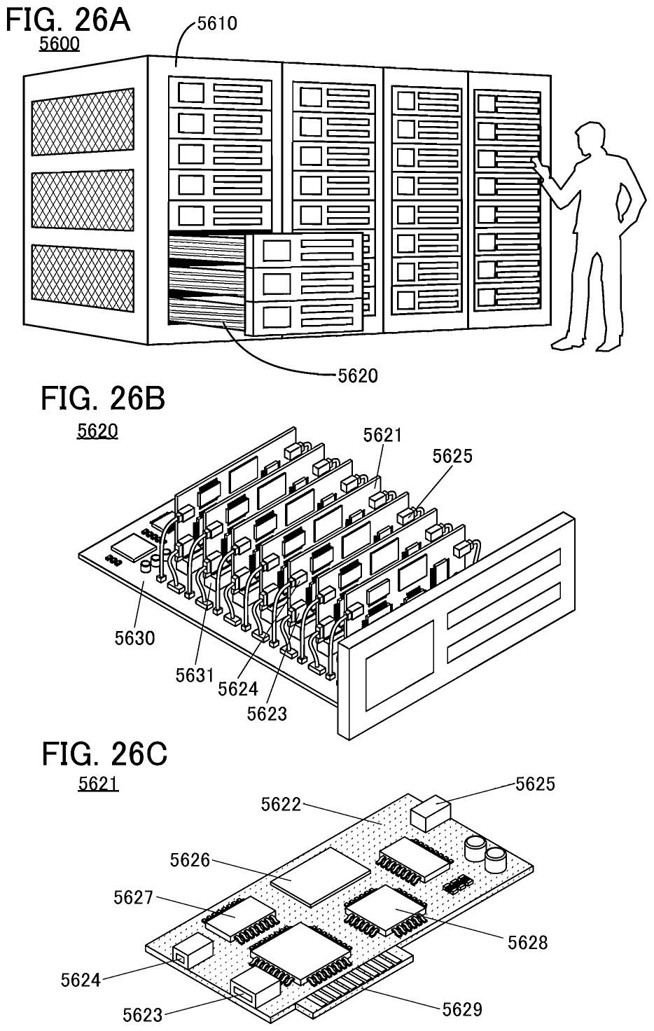

A computer 5600 illustrated in FIG. 26A is an example of a large computer. In the computer 5600, a plurality of rack mount computers 5620 are stored in a rack 5610.

The computer 5620 can have a structure in a perspective view illustrated in FIG. 26B, for example. In FIG. 26B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26C is an example of a processing board provided with a CPU, a GPU, a semiconductor device, or the like. The PC card 5621 includes a board 5622. In addition, the board 5622 includes a connection terminal 5623, a connection terminal 5624, a connection terminal 5625, a semiconductor device 5626, a semiconductor device 5627, a semiconductor device 5628, and a connection terminal 5629. Note that FIG. 26C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, or signal input to the PC card 5621. As another example, the connection terminal 5623, the connection terminal 5624, and the connection terminal 5625 can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, a CPU, and the like. As the semiconductor device 5627, the electronic component 4730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 4700 can be used, for example.

The computer 5600 can also function as a parallel computer. When the computer 5600 is used as a parallel computer, large-scale computation necessary for artificial intelligence learning and inference can be performed, for example.

When the semiconductor device of one embodiment of the present invention is used in a variety of electronic devices described above, the reliability of the electronic devices can be increased.

Note that this embodiment can be combined with any of the other embodiments described in this specification as appropriate.

### Example 1

In this example, transistors whose channel formation regions contain an oxide semiconductor (referred to as OS transistors) were fabricated and evaluated assuming high voltage driving. Since the OS transistors fabricated in this example each correspond to the transistor 500 illustrated in FIG. 14A and FIG. 14B, the description in the above embodiment can be referred to for the structures or the like of the OS transistors fabricated in this example.

Note that OS transistors (a sample 800A to a sample 800D) having different designed values of the channel length (L) and designed values of the channel width (W) were prepared in this example. Specifically, an OS transistor with L/W=30 nm/30 nm is referred to as the sample 800A, an OS transistor with L/W=40 nm/40 nm is referred to as the sample 800B, an OS transistor with L/W=50 nm/50 nm is referred to as the sample 800C, and an OS transistor with L/W=60 nm/60 nm is referred to as the sample 800D. Note that the values of L and W in the following description are designed values.

The sample 800A to the sample 800D will be described below.

The oxide 530a was formed of an In—Ga—Zn oxide deposited by a sputtering method using a target with In:Ga:Zn=1:3:4 [atomic ratio]. The oxide 530b was formed of an In—Ga—Zn oxide deposited by a sputtering method using a target with In:Ga:Zn=1:1:2 [atomic ratio]. Note that the film to be the oxide 530a and the film to be the oxide 530b were formed by successive deposition.

The conductor 542a and the conductor 542b were formed using a tantalum nitride film. The insulator 552 was formed using a silicon oxide film. The insulator 550 was formed using a hafnium oxide film. The insulator 554 is formed using a silicon nitride film. Note that the thickness of each of the insulator 552, the insulator 550, and the insulator 554 was adjusted such that the gate insulator had an equivalent oxide thickness (EOT) of 4.4 nm.

The conductor 560a was formed using a titanium nitride film. The conductor 560b was formed using a tungsten film. Note that the film to be the conductor 560a and the film to be the conductor 560b were formed by successive deposition.

The above is the description of the sample 800A to the sample 800D. Note that according to the measurement result, the gate length (Lg) of the sample 800A was 22 nm.

Furthermore, transistors whose channel formation regions contain silicon (referred to as Si transistors) were prepared as comparative examples. In this example, n-channel and p-channel Si transistors were fabricated. Hereinafter, the n-channel Si transistor is referred to as a sample 800E and the p-channel Si transistor is referred to as a sample 800F. Note that each of the sample 800E and the sample 800F has an EOT of 2.6 nm and L/W of 60 nm/120 nm.

### <Id-Vg Characteristics>

First, the drain current (Id)-gate voltage (Vg) characteristics of the sample 800A to the sample 800F were measured using a semiconductor parameter analyzer manufactured by Keysight Technologies. The Id-Vg characteristics were measured under the conditions where the drain voltage (Vd) was 0.1 V or 1.2 V, the back gate voltage (Vbg) was 0 V, and the gate voltage was swept from −4.0 V to 4.0 V in increments of 0.1 V.

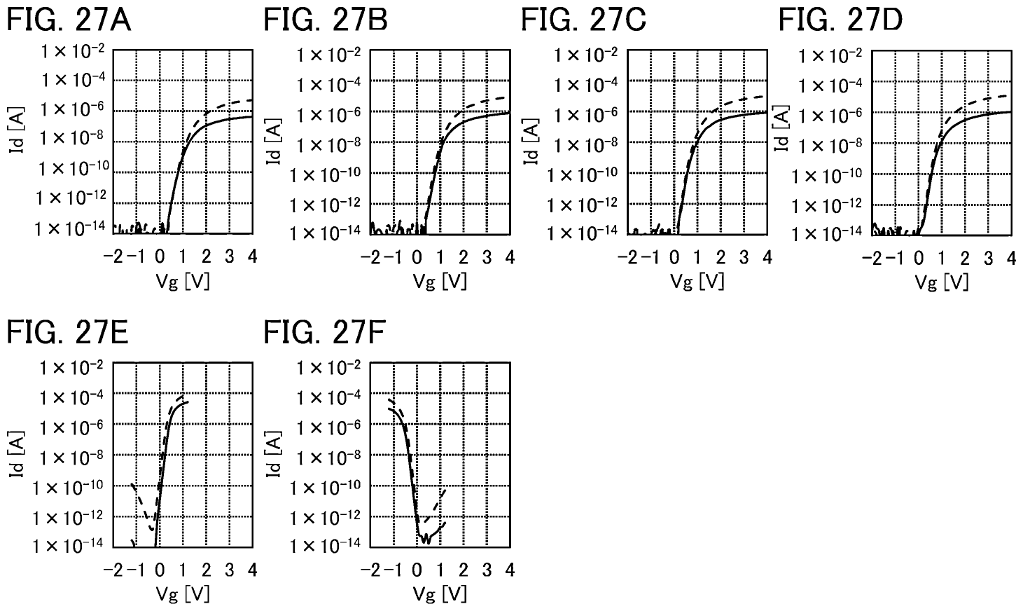

FIG. 27A to FIG. 27F show measurement results of the Id-Vg characteristics of the samples. FIG. 27A is a graph showing the Id-Vg characteristics of the sample 800A, FIG. 27B is a graph showing the Id-Vg characteristics of the sample 800B, FIG. 27C is a graph showing the Id-Vg characteristics of the sample 800C, FIG. 27D is a graph showing the Id-Vg characteristics of the sample 800D, FIG. 27E is a graph showing the Id-Vg characteristics of the sample 800E, and FIG. 27F is a graph showing the Id-Vg characteristics of the sample 800F. In each of FIG. 27A to FIG. 27F, the horizontal axis represents the gate voltage (Vg) [V] and the vertical axis represents the drain current (Id) [A]. Furthermore, the drain current at Vd=0.1 V is shown by a solid line and the drain current at Vd=1.2 V is shown by a dashed line.

As shown in FIG. 27A to FIG. 27D, the OS transistors (the sample 800A to the sample 800D) showed favorable electrical characteristics.

### <Drain Withstand Voltage Test>

Next, each of the sample 800A to the sample 800F was subjected to a drain withstand voltage test.

In the drain withstand voltage test, the gate voltage (Vg) was set to 0 V or +3.3 V. The source voltage (Vs) and the back gate voltage (Vbg) of the sample 800A to the sample 800E were set to 0 V and the source voltage (Vs) and the back gate voltage (Vbg) of the sample 800F were set to +1.2 V. The drain current (Id) was measured while the drain voltage (Vd) was increased from 0 V. The drain withstand voltage (Vds withstand voltage) was Vd at the time when the drain current (Id) sharply decreased, that is, when the transistor was broken. The maximum voltage of Vd was +10 V. The temperature at the time of measurement was room temperature.

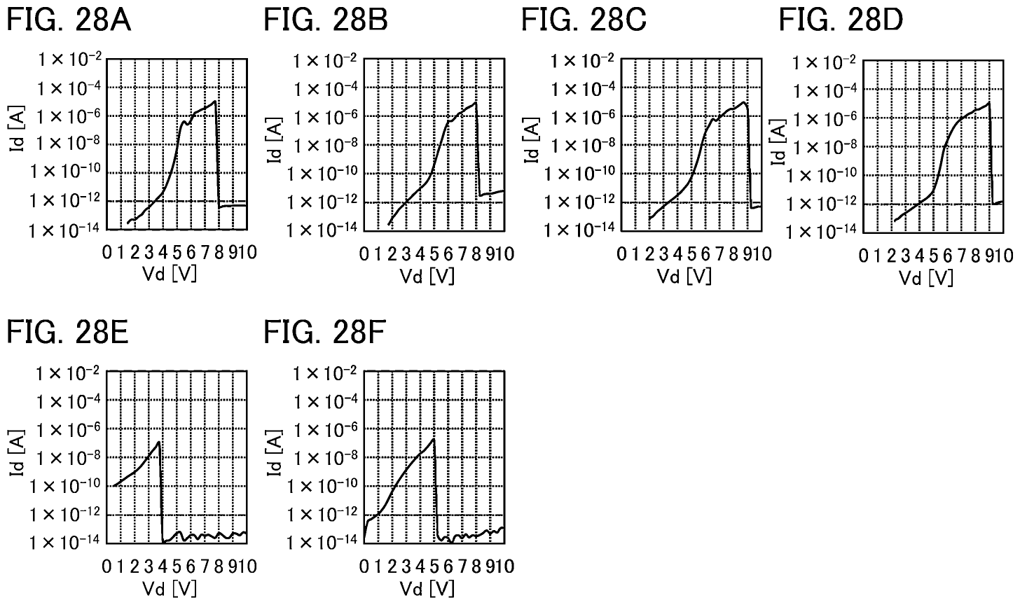

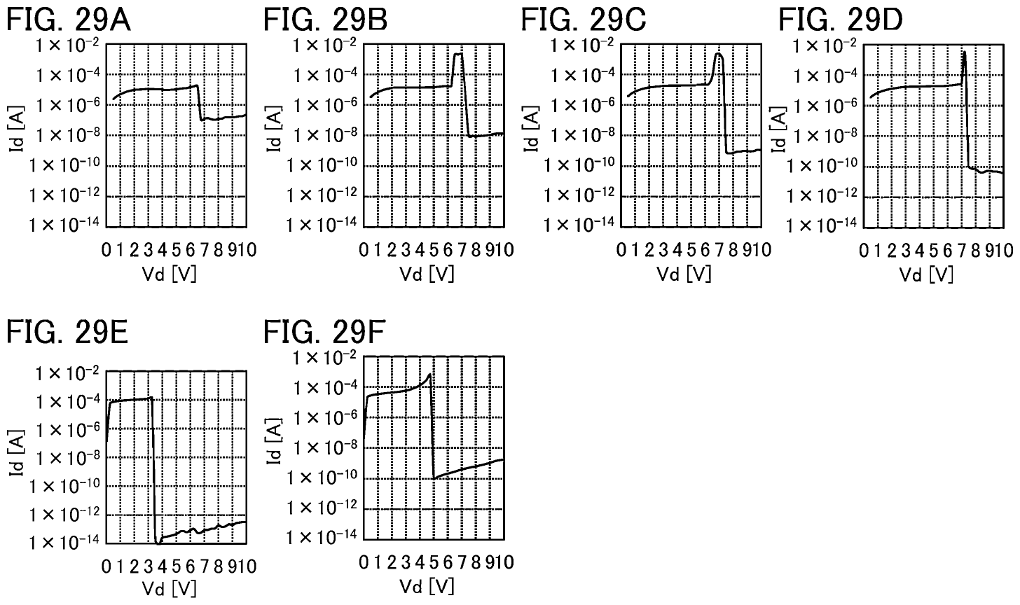

FIG. 28A to FIG. 29F show the results of the drain withstand voltage tests of the samples. FIG. 28A to FIG. 28F are graphs showing the Id-Vd characteristics of the samples in the case where the gate voltage (Vg) was set to 0 V. FIG. 29A to FIG. 29F are graphs showing the Id-Vd characteristics of the samples in the case where the gate voltage (Vg) was set to +3.3 V. In FIG. 28A to FIG. 29F, the horizontal axis represents the drain voltage (Vd) [V] and the vertical axis represents the drain current (Id) [A].

FIG. 28A is a graph showing the Id-Vd characteristics of the sample 800A, FIG. 28B is a graph showing the Id-Vd characteristics of the sample 800B, FIG. 28C is a graph showing the Id-Vd characteristics of the sample 800C, FIG. 28D is a graph showing the Id-Vd characteristics of the sample 800D, FIG. 28E is a graph showing the Id-Vd characteristics of the sample 800E, and FIG. 28F is a graph showing the Id-Vd characteristics of the sample 800F. FIG. 28A to FIG. 28F revealed that the Vds withstand voltage of the sample 800A was 7.75 V, the Vds withstand voltage of the sample 800B was 8.0 V, the Vds withstand voltage of the sample 800C was 9.0 V, and the Vds withstand voltage of the sample 800D was 9.0 V. It was also revealed that the Vds withstand voltage of the sample 800E was 3.75 V and the Vds withstand voltage of the sample 800F was 5.0 V.

FIG. 29A is a graph showing the Id-Vd characteristics of the sample 800A, FIG. 29B is a graph showing the Id-Vd characteristics of the sample 800B, FIG. 29C is a graph showing the Id-Vd characteristics of the sample 800C, FIG. 29D is a graph showing the Id-Vd characteristics of the sample 800D, FIG. 29E is a graph showing the Id-Vd characteristics of the sample 800E, and FIG. 29F is a graph showing the Id-Vd characteristics of the sample 800F. FIG. 29A to FIG. 29F revealed that the Vds withstand voltage of the sample 800A was 6.5 V, the Vds withstand voltage of the sample 800B was 6.25 V, the Vds withstand voltage of the sample 800C was 6.25 V, and the Vds withstand voltage of the sample 800D was 7.0 V. It was also revealed that the Vds withstand voltage of the sample 800E was 3.25 V and the Vds withstand voltage of the sample 800F was 4.75 V.

It was found from FIG. 28A to FIG. 29F that the OS transistors had higher drain withstand voltage than the Si transistors. It was found from FIG. 28A that the sample 800A was able to operate even at a drain voltage (Vd) of 4.5 V. It was found from FIG. 29A that the sample 800A had hot-carrier injection (HCI) resistance at room temperature.

### <Temperature Dependence of On-State Current>

Next, temperature dependence of the on-state current of an OS transistor was evaluated. Here, a TEG for measuring off-state current including the sample 800A was fabricated.

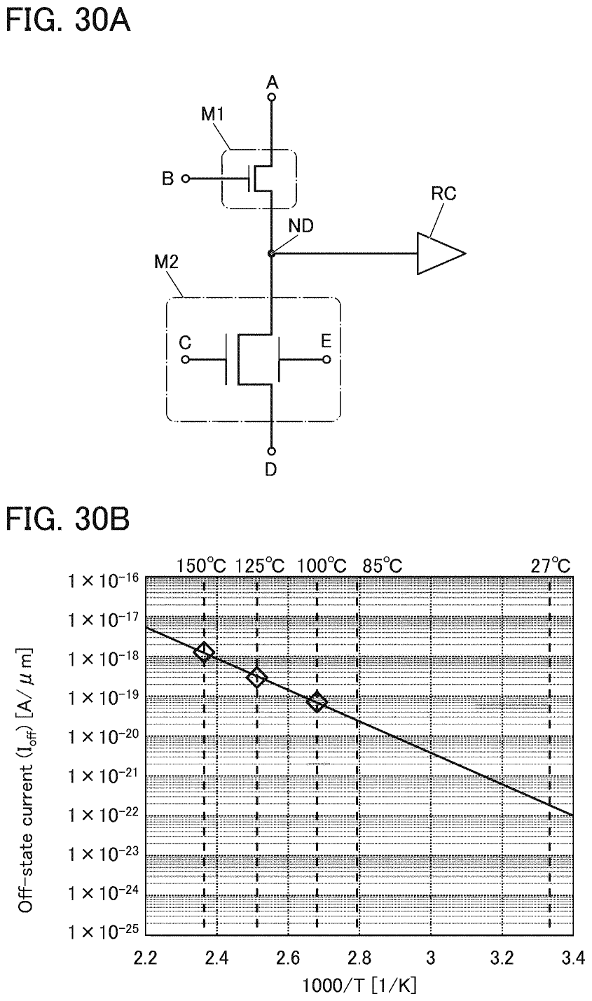

A circuit diagram schematically illustrating the TEG for measuring off-state current is illustrated in FIG. 30A. The TEG for measuring off-state current includes a terminal A to a terminal E, the transistor M1, the transistor M2, and a reading circuit RC.

One of a source and a drain of the transistor M1 is electrically connected to the terminal A. The other of the source and the drain of the transistor M1 is electrically connected to a node ND. A gate of the transistor M1 is electrically connected to the terminal B. One of a source and a drain of the transistor M2 is electrically connected to the node ND. The other of the source and the drain of the transistor M2 is electrically connected to the terminal D. A gate of the transistor M2 is electrically connected to the terminal C. A back gate of the transistor M2 is electrically connected to the terminal E. The reading circuit RC is electrically connected to the node ND.

The transistor M1 is a write transistor for supplying a potential to the node ND. The transistor M2 is a transistor which is a target of the off-state current measurement. As the transistor M2, 20000 of the samples 800A are connected in parallel. In other words, the transistor M2 has a designed channel length of 30 nm and a designed channel width of 0.6 mm (=30 nm x 20000 samples). The reading circuit RC can read the potential of the node ND constantly.

Next, a method for measuring the off-state current is described. First, a potential V11 at which the transistor M1 is brought into an on state is supplied to the terminal B to bring the transistor M1 into an on state. Then, a potential V12 is supplied to the terminal A until the potential of the node ND becomes V12. In this example, V12 was 1.2 V. Next, a potential V13 at which the transistor M1 is brought into an off state is supplied to the terminal B to bring the transistor M1 into an off state. Note that the transistor M2 is always in an off state as long as a potential of −2 V, a potential of −3 V, and a potential of 0 V are supplied to the terminal C, the terminal E, and the terminal D, respectively.

A change in the potential of the node ND over the time elapsed after the transistor M1 is brought into an off state in the above manner is read by the reading circuit RC, whereby leakage current, that is, off-state current, of the transistor M2 can be calculated. Specifically, the off-state current of the transistor M2 is calculated using I_{off}=C_{ND}×ΔV_{ND}/t, where I_{off} is the off-state current, C_{ND} is the capacitance of the node ND, ΔV_{ND} is the change in the potential of the node ND, and t is the elapsed time. Since the designed channel width of the transistor M1 is much smaller than the channel width of the transistor M2, the off-state current of the transistor M1 is negligible.

In a measurement environment at a temperature of 150° C. and a measurement environment at a temperature of 125° C., the change ΔV_{ND} in the potential of the node ND in an elapsed time of 1 hour was read. In a measurement environment at a temperature of 100° C., the change ΔV_{ND} in the potential of the node ND in an elapsed time of 2 hours was read.

FIG. 30B is a graph showing temperature dependence of the off-state current of the transistor M2. In FIG. 30B, the horizontal axis represents 1000 times the inverse of the absolute temperature T [K], and the vertical axis represents off-state current (I_{off}) per micrometer of channel width of the transistor M2 [A/μm]. The off-state currents of the transistor M2 at the temperatures are plotted as rhombi in FIG. 30B. An off-state current of 1.3×10⁻¹⁸ A was obtained at a temperature of 150° C., an off-state current of 3.0×10⁻¹⁹ A was obtained at a temperature of 125° C., and an off-state current of 7.1×10⁻²⁰ A was obtained at a temperature of 100° C. An approximate straight line is shown by a solid line. When the approximate straight line was extrapolated to room temperature (27° C.), the off-state current at room temperature was estimated to be less than or equal to 1×10⁻²¹ A/μm. According to the above, it was found that the sample 800A included in the transistor M2 had an extremely low off-state current.

Accordingly, the OS transistor is expected as a minute device with high withstand voltage.

Note that this example can be combined with any of the other embodiments described in this specification as appropriate.

### Example 2

In this example, a transistor that can be used as any of the transistors included in the memory cell MC was prototyped.

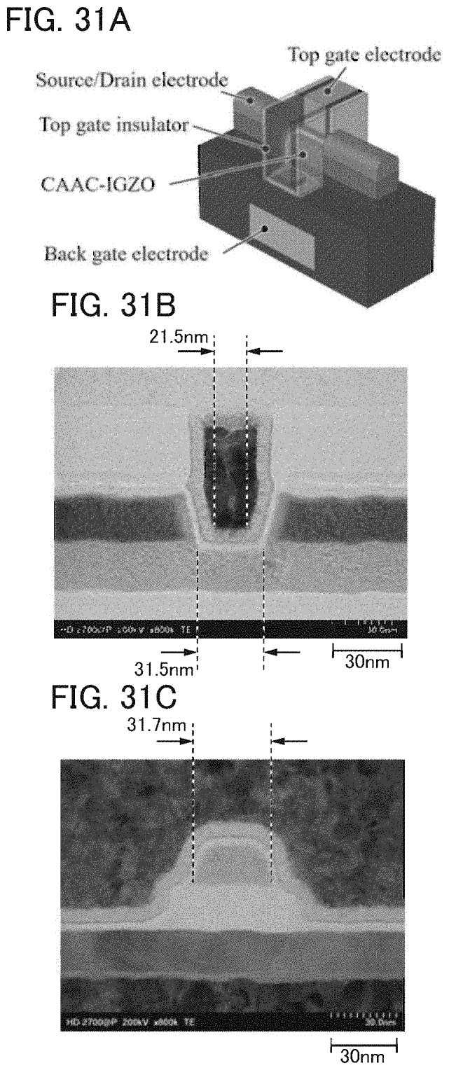

FIG. 31A is a schematic diagram illustrating a structure of the prototyped transistor. The prototyped transistor is an OS transistor. The prototyped transistor has, specifically, a structure similar to that of the transistor 500 described in the above embodiment and includes a top gate electrode (Top gate electrode), a gate insulating layer on the top gate electrode side (Top gate insulator), a back gate electrode (Back gate electrode), an electrode functioning as a source or a drain (Source/Drain electrode), and the like. Here, the channel length and the channel width were each designed to be 30 nm. The EOT of the gate insulating layer on the top gate electrode side was 4.4 nm. The prototyped transistor contains an In—Ga—Zn oxide having a CAAC structure (CAAC-IGZO) in its channel formation region.

FIG. 31B is a cross-sectional STEM (Scanning Transmission Electron Microscope) image of the prototyped transistor in the channel length direction. It was found from FIG. 31B that the measured value of the gate length and the measured value of the channel length of the prototyped transistor were 21.5 nm and 31.5 nm, respectively.

FIG. 31C is a cross-sectional STEM image of the prototyped transistor in the channel width direction. It was found from FIG. 31C that the measured value of the gate width of the prototyped transistor was 31.7 nm and the measured value of the channel width of the prototyped transistor was 31.7 nm.

FIG. 31B and FIG. 31C demonstrated that the transistor having the structure illustrated in FIG. 31A was able to be fabricated. Furthermore, since the measured value of the channel length was 31.5 nm and the measured value of the channel width was 31.7 nm while the designed channel length and channel width were 30 nm as described above, it was demonstrated that the transistor was able to be fabricated as designed.

Note that this example can be combined with any of the other embodiments described in this specification as appropriate.

### Example 3

In this example, transistors whose channel formation regions contain an oxide semiconductor (referred to as OS transistors) were fabricated, and the electrical characteristics of the prototyped transistors were measured. Since the OS transistors fabricated in this example each correspond to the transistor 500 illustrated in FIG. 14A and FIG. 14B, the description in the above embodiment can be referred to for the structures or the like of the OS transistors fabricated in this example.

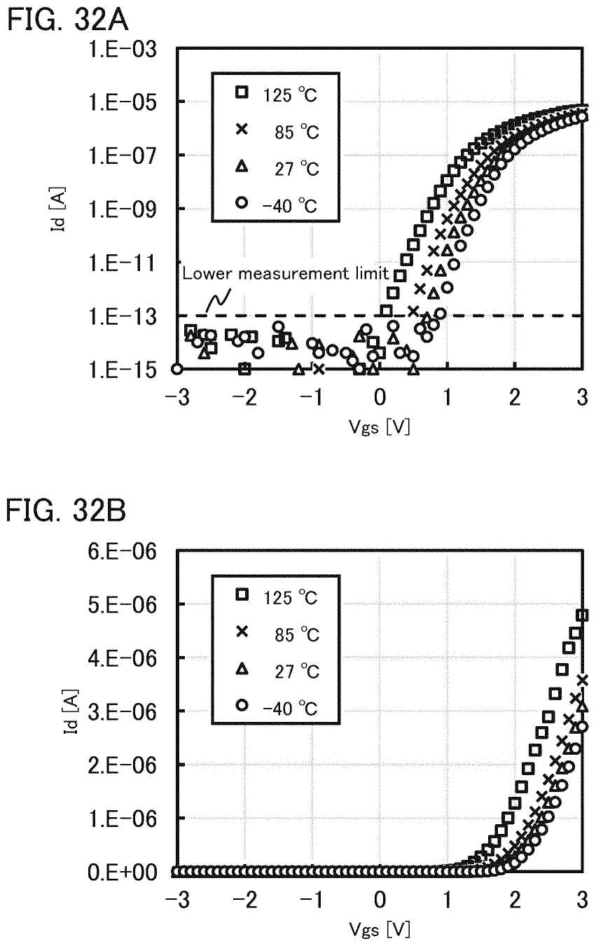

FIG. 32A and FIG. 32B show top gate voltage (denoted as “Vgs” in the diagrams)-drain current (denoted as “Id” in the diagrams) characteristics of a transistor prototyped to have a gate length of 22 nm. The vertical axis of FIG. 32A represents Id on a logarithmic scale and the vertical axis of FIG. 32B represents Id on a linear scale.

FIG. 32A shows the measurement results of the top gate voltage-drain current characteristics under the conditions where the drain voltage with respect to a source was 1.2 V and the back gate voltage with respect to the source was 0 V at measurement environment temperatures of −40° C., 27° C., 85° C., and 125° C.

The top gate voltage-drain current characteristics shown in FIG. 32A show that the off-state current was lower than or equal to the lower measurement limit (1×10⁻¹³ A) of measuring equipment at any of the measurement environment temperatures of −40° C., 27° C., 85° C., and 125° C.

As shown in FIG. 32B, driving current of the prototyped transistor did not decrease even when the measurement environment temperature was increased.

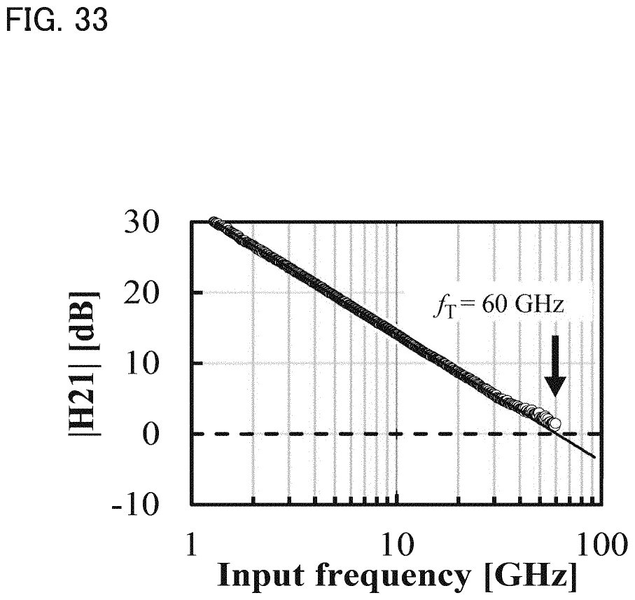

FIG. 33 is a diagram showing the maximum current gain of a transistor prototyped to have a gate length of 13 nm.

FIG. 33 shows the measurement results of the current gain with respect to input frequency (denoted as “Input frequency” in the diagram) under the conditions where the drain voltage with respect to a source was 2.5 V, the top gate voltage was 2.5 V, and the back gate voltage with respect to the source was 0 V at a measurement environment temperature of 27° C. FIG. 33 shows that the cutoff frequency (denoted as “f_{T}” in the diagram) is 60 GHz.

Note that this example can be combined with any of the other embodiments described in this specification as appropriate.

(Notes on Description of this Specification and the Like)

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified by their functions and illustrated as independent blocks in block diagrams. However, in an actual circuit or the like, it is difficult to divide components according to their functions, and there is such a case where one circuit relates to a plurality of functions or a case where a plurality of circuits relate to one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, the expressions “one of a source and a drain” (or a first electrode or a first terminal) and “the other of the source and the drain” (or a second electrode or a second terminal), which is for the other of the source and the drain, are used to describe the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, voltage and potential can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential supplied to a wiring or the like is sometimes changed depending on the reference potential, for example.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, when A and B are connected, it means the case where A and B are electrically connected to each other as well as the case where A and B are directly connected to each other. Here, when A and B are electrically connected, it means the case where electric signals can be sent and received between A and B when an object having any electric action exists between A and B.

### REFERENCE NUMERALS

10: semiconductor device, 11: layer, 13: layer, 15: layer, 25: power line, 25_1: power line, 25_2: power line, 25_3: power line, 25_4: power line, 300: transistor, 310: substrate, 310A: substrate, 312: element isolation layer, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 411: insulator, 412: insulator, 413: insulator, 414: insulator, 416: conductor, 500: transistor, 503: conductor, 503a: conductor, 503b: conductor, 510: insulator, 512: insulator, 514: insulator, 516: insulator, 518: conductor, 520: insulator, 520a: insulator, 520b: insulator, 520c: insulator, 522: insulator, 524: insulator, 530: oxide, 530a: oxide, 530b: oxide, 530ba: region, 530bb: region, 530bc: region, 540: conductor, 540a: conductor, 540b: conductor, 540c: conductor, 540d: conductor, 541: insulator, 541a: insulator, 541b: insulator, 541c: insulator, 541d: insulator, 542: conductor, 542a: conductor, 542b: conductor, 543: oxide, 543a: oxide, 543b: oxide, 544: insulator, 546: conductor, 550: insulator, 550a: insulator, 550b: insulator, 552: insulator, 553: insulator, 554: insulator, 560: conductor, 560a: conductor, 560b: conductor, 561: insulator, 562: conductor, 571: insulator, 571a: insulator, 571b: insulator, 574: insulator, 576: insulator, 580: insulator, 581: insulator, 582: insulator, 586: insulator, 600: capacitor, 601: insulator, 602: insulator, 610: conductor, 611: conductor, 612: conductor, 613: conductor, 620: conductor, 630: insulator, 631: insulator, 640: insulator, 650: insulator, 660: conductor, 4700: electronic component, 4702: printed circuit board, 4704: mounting substrate, 4710: semiconductor device, 4711: mold, 4712: land, 4713: electrode pad, 4714: wire, 4730: electronic component, 4731: interposer, 4732: package substrate, 4733: electrode, 4735: semiconductor device, 4800: semiconductor wafer, 4800a: chip, 4801: wafer, 4801a: wafer, 4802: circuit portion, 4803: spacing, 4803a: spacing, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main body, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: housing, 6302: housing, 6303: display portion, 6304: operation switch, 6305: lens, 6306: connection portion, 7500: type game machine, 7520: main body, 7522: controller

1. A semiconductor device comprising a first memory cell, a second memory cell, and a switch,
wherein the first memory cell comprises a first transistor, a second transistor, and a first capacitor,
wherein the second memory cell comprises a third transistor, a fourth transistor, and a second capacitor,
wherein the first capacitor and the second capacitor each comprise a ferroelectric layer between a pair of electrodes,
wherein one of a source and a drain of the first transistor is electrically connected to a gate of the second transistor,
wherein the gate of the second transistor is electrically connected to one of the pair of electrodes of the first capacitor,
wherein one of a source and a drain of the third transistor is electrically connected to a gate of the fourth transistor,
wherein the gate of the fourth transistor is electrically connected to one of the pair of electrodes of the second capacitor, and
wherein the other of the source and the drain of the first transistor is electrically connected to the other of the source and the drain of the third transistor via the switch.

2. The semiconductor device according to claim 1, further comprising a first driver circuit,
wherein the first driver circuit is configured to bring the first transistor into an on state when data is read from the first memory cell, and
wherein the first driver circuit is configured to bring the third transistor into an on state when data is read from the second memory cell.

3. The semiconductor device according to claim 1, further comprising a second driver circuit,
wherein the second driver circuit is configured to read data from the first memory cell on the basis of a potential of one of a source and a drain of the second transistor, and
wherein the second driver circuit is configured to read data from the second memory cell on the basis of a potential of one of a source and a drain of the fourth transistor.

4. The semiconductor device according to claim 1,
wherein each of the first transistor, the second transistor, the third transistor, and the fourth transistor comprises a metal oxide in a channel formation region.

5. The semiconductor device according to claim 1,
wherein the first memory cell comprises a fifth transistor,
wherein the second memory cell comprises a sixth transistor,
wherein one of a source and a drain of the fifth transistor is electrically connected to one of a source and a drain of the second transistor, and
wherein one of a source and a drain of the sixth transistor is electrically connected to one of a source and a drain of the fourth transistor.

6. The semiconductor device according to claim 5, further comprising a third driver circuit,
wherein the third driver circuit is configured to bring the fifth transistor into an on state when data is read from the first memory cell, and
wherein the third driver circuit is configured to bring the sixth transistor into an on state when data is read from the second memory cell.

7. The semiconductor device according to claim 5,
wherein each of the fifth transistor and the sixth transistor comprises a metal oxide in a channel formation region.

8. A semiconductor device comprising a memory cell, a first driver circuit, and a switch,
wherein the memory cell comprises a first transistor, a second transistor, and a capacitor,
wherein the capacitor comprises a ferroelectric layer between a pair of electrodes,
wherein one of a source and a drain of the first transistor is electrically connected to a gate of the second transistor,
wherein the gate of the second transistor is electrically connected to one of the pair of electrodes of the capacitor,
wherein the other of the source and the drain of the first transistor is electrically connected to the first driver circuit via the switch, and
wherein the first driver circuit is configured to generate data to be written to the memory cell.

9. The semiconductor device according to claim 8, further comprising a second driver circuit,
wherein the second driver circuit is configured to bring the first transistor into an on state when data is read from the memory cell.

10. The semiconductor device according to claim 8, further comprising a third driver circuit,
wherein the third driver circuit is configured to read data from the memory cell on the basis of a potential of one of a source and a drain of the second transistor.

11. The semiconductor device according to claim 8,
wherein each of the first transistor and the second transistor comprises a metal oxide in a channel formation region.

12. The semiconductor device according to claim 8,
wherein the memory cell comprises a third transistor, and
wherein one of a source and a drain of the third transistor is electrically connected to one of a source and a drain of the second transistor.

13. The semiconductor device according to claim 12, further comprising a fourth driver circuit,
wherein the fourth driver circuit is configured to bring the third transistor into an on state when data is read from the memory cell.

14. The semiconductor device according to claim 12,
wherein the third transistor comprises a metal oxide in a channel formation region.

15. A semiconductor device comprising a first layer and a second layer comprising a region overlapping with the first layer,
wherein the first layer comprises a first memory cell, a second memory cell, and a switch,
wherein the first memory cell comprises a first transistor, a second transistor, and a first capacitor,
wherein the second memory cell comprises a third transistor, a fourth transistor, and a second capacitor,
wherein the first capacitor and the second capacitor each comprise a ferroelectric layer between a pair of electrodes,
wherein the second layer comprises a first arithmetic portion and a second arithmetic portion,
wherein one of a source and a drain of the first transistor is electrically connected to a gate of the second transistor,
wherein the gate of the second transistor is electrically connected to one of the pair of electrodes of the first capacitor,
wherein one of a source and a drain of the third transistor is electrically connected to a gate of the fourth transistor,
wherein the gate of the fourth transistor is electrically connected to one of the pair of electrodes of the second capacitor,
wherein the other of the source and the drain of the first transistor is electrically connected to the other of the source and the drain of the third transistor via the switch,
wherein the first arithmetic portion is electrically connected to a first power line, and
wherein the second arithmetic portion is electrically connected to a second power line.

16. The semiconductor device according to claim 15,
wherein the first power line is not electrically connected to the second power line.

17. The semiconductor device according to claim 15, further comprising a third layer,
wherein the third layer comprises a region overlapping with the first layer and the second layer,
wherein the third layer comprises a first driver circuit,
wherein the first driver circuit is configured to bring the first transistor into an on state when data is read from the first memory cell, and
wherein the first driver circuit is configured to bring the third transistor into an on state when data is read from the second memory cell.

18. The semiconductor device according to claim 17,
wherein the third layer comprises a second driver circuit,
wherein the second driver circuit is configured to read data from the first memory cell on the basis of a potential of one of a source and a drain of the second transistor, and
wherein the second driver circuit is configured to read data from the second memory cell on the basis of a potential of one of a source and a drain of the fourth transistor.

19. The semiconductor device according to claim 1,
wherein the ferroelectric layer comprises hafnium oxide and/or zirconium oxide.

20. An electronic device comprising the semiconductor device according to claim 1 and a housing.
